(19) United States
(12) Patent Application Publication
(10) Pub. No.: US 2007/0111027 A1
(43) Pub. Date: May 17, 2007

(54) Light-emitting organic materials

(76) Inventors: Shaw H. Chen, Rochester, NY (US); Andrew Chien-An Chen, Rochester, NY (US); Jason U. Wallace, Rochester, NY (US); Lichang Zeng, Rochester, NY (US)

Correspondence Address: NEEDLE & ROSENBERG, P.C., SUITE 1000, 999 PEACHTREE STREET, ATLANTA, GA, 30309-3915, US

(21) Appl. No.: 11/494,854

(22) Filed: Jul. 28, 2006

Related U.S. Application Data
(60) Provisional application No. 60/703,908, filed on Jul. 29, 2005.

(51) Int. Cl. H01L 51/54; C09K 11/06

(52) U.S. Cl. 428/690; 428/917; 257/E51.049; 257/40; 313/504; 564/433; 564/434; 544/180; 548/143; 548/262.2

(57) ABSTRACT

The subject matter disclosed herein generally relates to organic light-emitting materials and methods for their preparation and use. Also, devices involve organic light emitting materials are disclosed.

### CROSS REFERENCE TO RELATED APPLICATIONS

This application claims the benefit of priority to U.S. Provisional Application No. 60/703,908, filed Jul. 29, 2005. U.S. Provisional Application No. 60/703,908 is hereby incorporated by reference in its entirety.

### ACKNOWLEDGEMENTS

This work was supported by grant CTS0204827 from the National Science Foundation. The U.S. Government has certain rights in this invention.

### FIELD

The subject matter disclosed herein generally relates to organic light-emitting materials and methods for their preparation and use. Also, devices that involve organic light emitting materials are disclosed.

### BACKGROUND

Since the discovery of efficient electroluminescence at a relatively low voltage using organic materials, including low-molar-mass fluorescent dyes (Tang and VanSlyke, Appl. Phys. Lett. 1987, 51:913-915) and π-conjugated polymers (Burroughes et al., Nature 1990, 347:539-541), intensive efforts have been devoted to improving the efficiency and lifetime of organic light-emitting diodes (OLEDs). While low-molar-mass materials can be deposited as thin films by sublimation, conjugated polymers can be readily processed into large-area thin films by spin-coating from dilute solutions. In principle, electrons and holes are injected from the cathode and anode, respectively, for the formation of excitons in the emissive layer where radiative decay takes place.

To achieve a high quantum yield with long device lifetime, charge injection and transport should be balanced and the recombination zone should be spread out in space. For this, four strategies have been reported in the literature: (i) using a low work function metal as the cathode, such as Ca or Ba capped with Al or Ag (see e.g., Gustafsson et al., Nature 1992, 357:477-479; Cao et al., J. Appl. Phys. 2000, 3618-3623; Ego et al., Adv. Mater. 2002, 809-811; and Martens et al., Appl. Phys. Lett. 2000, 77:1852-1854), (ii) adding an injection, a buffer, and/or a charge-transport layer (see e.g., Adachi et al., Jpn. J. Appl. Phys. 1988, 27:L269-L271; Adachi et al., Appl. Phys. Lett. 1989, 55:1489-1491; Brown et al., Appl. Phys. Lett. 1992, 61:2793-2795; Yang and Pei, J. Appl. Phys. 1995, 77:4807-4809; Strukelj et al., J. Am. Chem. Soc. 1995, 117:11976-11983; Buchwald et al., Adv. Mater. 1995, 7:839-842; Fukuda et al., Appl. Phys. Lett. 1996, 68:2346-2348; Kim et al., Chem. Mater. 2004, 16:5051-5057; Liew et al., Appl. Phys. Lett. 2004, 85:4511-4513; Liao et al., Appl. Phys. Lett. 2005, 86:203507-1-203507-3; and Yi et al., Appl. Phys. Lett. 2005, 86:213502-1-213502-3), (iii) physical blending of an emissive material with a charge-transporting material (see e.g., Chwang et al., Appl. Phys. Lett. 2002, 80:725-727; Aziz et al., Appl. Phys. Lett. 2002, 81: 370-372; Aziz et al., Science 1999, 283:1900-1902; Cimrova et al., Adv. Mater. 1998, 10:676-680; Naka et al., Jpn. J. Appl. Phys. 1994, 33:L1772-L1774; Cao et al., Nature 1999, 397:414-417; Vaeth et al., J. Appl. Phys. 2002, 92:3447-3453; Gong et al., Adv. Mater. 2002, 14:581-585; Niu et al., Appl. Phys. Lett. 2004, 85:5433-5435; Yan et al., Appl. Phys. Lett. 2004, 84:3873-3875; Choong et al., Appl. Phys. Lett. 1999, 75:172-174; Yan et al., Adv. Mater. 2004, 16:1948-1953; Uchida et al., Jpn. J. Appl. Phys. 1993, 32:L921-L924; Ahn et al., Appl. Phys. Lett. 2004, 85:1283-1285; and Lee et al., Appl. Phys. Lett. 2005, 86:103506-1-103506-3), and (iv) chemical modification of an emissive material with charge-transporting moieties (see e.g., Li et al., Adv. Mater. 1995, 7:898-900; Boyd et al., Macromolecules 1997, 30:3553-3559; Grice et al., Adv. Mater. 1997, 9:1174-1178; Tamoto et al., Chem. Mater. 1997, 9:1077-1085; Chan et al., J. Am. Chem. Soc. 2002, 124:6469-6479; Danel et al., Chem. Mater. 2002, 14:3860-3865; Doi et al., Chem. Mater. 2003, 15:1080-1089; Thomas et al., Adv. Funct. Mater. 2004, 14:83-90; Wong et al., Org. Lett. 2005, 7:1979-1982; Bao et al., Chem. Mater. 1998, 10:1201-1204; Chung et al., Adv. Mater. 1998, 10:1112-1116; Peng et al., Adv. Mater. 1998, 10:680-684; Ding et al., Macromolecules, 2002, 35:3474-3483; Huang et al., Adv. Mater. 1998, 10:593-596; Peng et al., Chem. Mater. 1999, 11:1138-1143; Redecker et al., Adv. Mater. 1999, 11:241-246; Lee et al., J. Am. Chem. Soc. 2001, 123:2296-2307; Miteva et al., Adv. Mater. 2001, 13:565-570; Liu et al., Chem. Mater. 2001, 13:3820-3822; Wu et al., Chem. Mater. 2003, 15:269-274; Gong et al., Adv. Funct. Mater. 2004, 14:393-397; Jin et al., J. Am. Chem. Soc. 2004, 126:2474-2480; Yu and Chen, Adv. Mater. 2004, 16:744-748; Aldred et al., Chem. Mater. 2004, 16:4928-4936; and Kwon et al., Chem. Mater. 2004, 16:4657-4666). Of the four strategies, chemical modification appears to be the most versatile, and hence has been the most intensively pursued.

Low-molar-mass evaporable materials have been constructed by bonding electron- or hole-conducting moieties to light-emitting conjugated molecules through π-conjugation, thus affecting individual functionalities (see e.g., Tamoto et al., Chem. Mater. 1997, 9:1077-1085; Chan et al., J. Am. Chem. Soc. 2002, 124:6469-6479; Danel et al., Chem. Mater. 2002, 14:3860-3865; Doi et al., Chem. Mater. 2003, 15:1080-1089; and Thomas et al., Adv. Funct. Mater. 2004, 14:83-90). In most conjugated polymers, holes are preferentially transported over electrons. Electron transport has been improved by incorporating 1-electron-deficient moieties, such as oxadiazole, triazole, triazine, and quinoxaline, in the polymer backbone, as the pendant, or as the end-cap. In the case of blue OLEDs, hole injection is also a limiting factor because of the high ionization potentials of most blue-emitting materials. This difficulty can be overcome in part by adding a layer of poly(3,4-ethylenedioxythiophene):poly(styrene sulfonate), PEDOT:PSS, between the indium tin oxide, ITO, anode and the emissive polymer layer (Brown et al., Appl. Phys. Lett. 1999, 75:1679-1681). Because of its acidic nature, PEDOT:PSS was found to etch ITO, causing device instability (de Jong et al., Appl. Phys. Lett. 2000, 77:2255-2257). This problem has been addressed using an alternative hole-injection material (Gong et al., Appl. Phys. Lett. 2003, 83:183-185) or a self-assembled monolayer on the ITO anode (Yan et al., Adv. Mater. 2003, 15:835-838).

In light of the intense interest around organic light emitting materials, new materials and methods of making and using such materials are needed. Disclosed herein are materials and methods that address these needs.

### SUMMARY

In accordance with the purposes of the disclosed materials, compounds, compositions, articles, devices, and methods, as embodied and broadly described herein, the disclosed subject matter, in one aspect, relates to compounds and compositions and methods for preparing and using such compounds and compositions. In a further aspect, the disclosed subject matter relates to organic light-emitting materials, methods for their preparation and use, and devices involving such materials.

Additional advantages will be set forth in part in the description that follows, and in part will be obvious from the description, or may be learned by practice of the aspects described below. The advantages described below will be realized and attained by means of the elements and combinations particularly pointed out in the appended claims. It is to be understood that both the foregoing general description and the following detailed description are exemplary and explanatory only and are not restrictive.

### BRIEF DESCRIPTION OF THE FIGURES

The accompanying figures, which are incorporated in and constitute a part of this specification, illustrate several aspects described below.

FIG. 1 is a graph showing DSC thermograms at ±20° C./min of samples preheated to 260° C. followed by cooling to −30° C. In the figure, G is glassy, Nm is nematic, Sₓ is smectic x, and I is isotropic.

FIG. 2 is a graph showing UV-Vis absorption (dashed curve) and fluorescence (solid curve) spectra of a 50-nm-thick isotropic film of TRZ-F(MB)3.

FIG. 3 is a pair of graphs showing polarized absorption and fluorescence spectra of a uniaxially aligned glassy-nematic film of TRZ-F(MB)5.

FIG. 4 is a pair of graphs showing polarized absorption and fluorescence spectra of a uniaxially aligned glassy-nematic film of TPD-F(MB)5.

FIG. 5 is a set of four graphs showing cyclic voltammetric scans of TRZ-F(MB)3, TRZ-F(MB)5, TPD-F(MB)3, TPD-F(MB)5 in dilute solutions. Reduction scans of 2.5×10⁻⁴ M solutions in anhydrous THF with 0.1 M tetrabutylammonium perchlorate (nBU₄NClO₄) as the supporting electrolyte, and oxidation scans of 2.5×10⁻⁴ M solutions in anhydrous CH₂Cl₂ with 0.1 M tetraethylammonium tetrafluoroborate (Et₄NBF₄) as the supporting electrolyte.

FIG. 6 is a reaction scheme for the synthesis of light-emitting glassy amorphous (n=1) and liquid crystalline (n=3) materials with an electron-conducting core, TRZ-F(MB)3 and TRZ-F(MB)5.

FIG. 7 is a reaction scheme for the synthesis of light-emitting glassy liquid crystal with a hole-conducting core, TPD-F(MB)5.

FIG. 8 is a reaction scheme for the synthesis of light-emitting glassy amorphous material with a hole-conducting core, TPD-F(MB)3.

FIG. 9 is a reaction scheme for the synthesis of light-emitting glassy amorphous (n=1) and liquid crystalline (n=3) materials with a nonconducting core.

FIG. 10 is a reaction scheme for the synthesis of a hole-conducting core for the preparation of glassy amorphous and liquid crystalline materials with a variable number of light-emitting pendants.

FIG. 11 is a graph showing UV-Vis absorption (dashed curve) and fluorescence (solid curve) spectra of a 34.4-nm-thick film of TPA-F(MB)3.

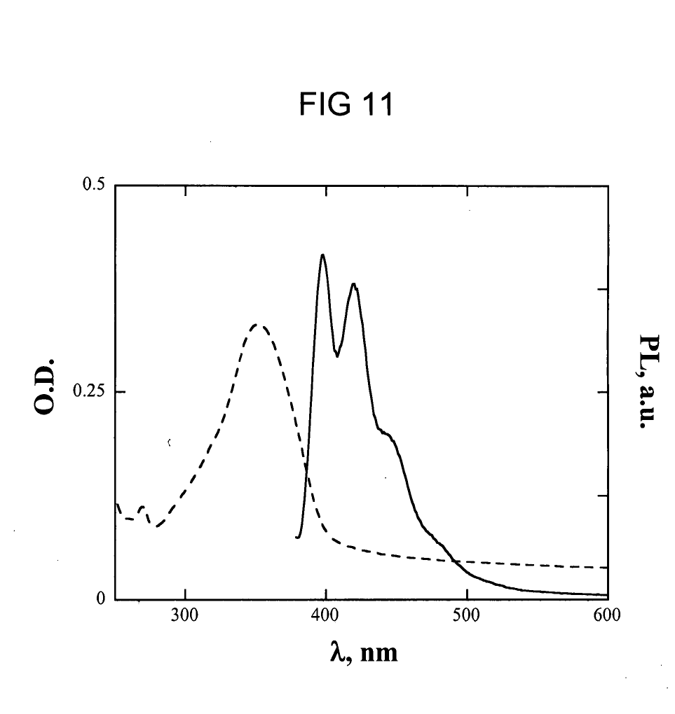

FIG. 12 is a pair of reaction schemes: one for the synthesis of light-emitting material with a non-conducting core, TPB-F(MB)3, and the other for the synthesis of light-emitting material with an electron-conducting core TRZ(1)-F(MB)3.

FIG. 13 is a reaction scheme for the synthesis of light-emitting material with a hole-conducting core, TPA-F(MB)3.

FIG. 14 is a reaction scheme for the synthesis of light-emitting glassy with a non-conducting core, TPB-F(MB)4.

### DETAILED DESCRIPTION

The materials, compounds, compositions, articles, devices, and methods described herein may be understood more readily by reference to the following detailed description of specific aspects of the disclosed subject matter and the Examples included therein and to the Figures.

Before the present materials, compounds, compositions, articles, devices, and methods are disclosed and described, it is to be understood that the aspects described below are not limited to specific synthetic methods or specific reagents, as such may, of course, vary. It is also to be understood that the terminology used herein is for the purpose of describing particular aspects only and, unless a particular term is specifically defined herein, is not intended to be limiting.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

General Definitions

In this specification and in the claims that follow, reference will be made to a number of terms, which shall be defined to have the following meanings:

Throughout the description and claims of this specification the word “comprise” and other forms of the word, such as “comprising” and “comprises,” means including but not limited to, and is not intended to exclude, for example, other additives, components, integers, or steps.

As used in the description and the appended claims, the singular forms “a,” “an,” and “the” include plural referents unless the context clearly dictates otherwise. Thus, for example, reference to “a composition” includes mixtures of two or more such compositions, reference to “an agent” includes mixtures of two or more such agents, reference to “the component” includes mixtures of two or more such component, and the like.

“Optional” or “optionally” means that the subsequently described event or circumstance can or cannot occur, and that the description includes instances where the event or circumstance occurs and instances where it does not.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that when a value is disclosed that “less than or equal to” the value, “greater than or equal to the value,” and possible ranges between values are also disclosed, as appropriately understood by the skilled artisan. For example, if the value “10” is disclosed, then “less than or equal to 10” as well as “greater than or equal to 10” is also disclosed. It is also understood that throughout the application data are provided in a number of different formats and that this data represent endpoints and starting points and ranges for any combination of the data points. For example, if a particular data point “10” and a particular data point “15” are disclosed, it is understood that greater than, greater than or equal to, less than, less than or equal to, and equal to 10 and 15 are considered disclosed as well as between 10 and 15. It is also understood that each unit between two particular units are also disclosed. For example, if 10 and 15 are disclosed, then 11, 12, 13, and 14 are also disclosed.

Chemical Definitions

As used herein, the term “substituted” is contemplated to include all permissible substituents of organic compounds. In a broad aspect, the permissible substituents include acyclic and cyclic, branched and unbranched, carbocyclic and heterocyclic, and aromatic and nonaromatic substituents of organic compounds. Illustrative substituents include, for example, those described below. The permissible substituents can be one or more and the same or different for appropriate organic compounds. For purposes of this disclosure, the heteroatoms, such as nitrogen, can have hydrogen substituents and/or any permissible substituents of organic compounds described herein which satisfy the valencies of the heteroatoms. This disclosure is not intended to be limited in any manner by the permissible substituents of organic compounds. Also, the terms “substitution” or “substituted with” include the implicit proviso that such substitution is in accordance with permitted valence of the substituted atom and the substituent, and that the substitution results in a stable compound, e.g., a compound that does not spontaneously undergo transformation such as by rearrangement, cyclization, elimination, etc.

“A¹,” “A²,” “A³,” and “A⁴” are used herein as generic symbols to represent various specific substituents. These symbols can be any substituent, not limited to those disclosed herein, and when they are defined to be certain substituents in one instance, they can, in another instance, be defined as some other substituents.

The term “alkyl” as used herein is a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can also be substituted or unsubstituted. The alkyl group can be substituted with one or more groups including, but not limited to, alkyl, halogenated alkyl, alkoxy, alkenyl, alkynyl, aryl, heteroaryl, aldehyde, amino, carboxylic acid, ester, ether, halide, hydroxy, ketone, nitro, silyl, sulfo-oxo, sulfonyl, sulfone, sulfoxide, or thiol, as described below.

The term “cycloalkyl” is included within the meaning of “alkyl” and is a non-aromatic carbon-based ring composed of at least three carbon atoms. Examples of cycloalkyl groups include, but are not limited to, cyclopropyl, cyclobutyl, cyclopentyl, cyclohexyl, etc. The term “heterocycloalkyl” is a type of cycloalkyl group as defined above, and is included within the meaning of the terms “cycloalkyl” and “alkyl,” where at least one of the carbon atoms of the ring is substituted with a heteroatom such as, but not limited to, nitrogen, oxygen, sulfur, or phosphorus. The cycloalkyl group and heterocycloalkyl group can be substituted or unsubstituted. The cycloalkyl group and heterocycloalkyl group can be substituted with one or more groups including, but not limited to, alkyl, alkoxy, alkenyl, alkynyl, aryl, heteroaryl, aldehyde, amino, carboxylic acid, ester, ether, halide, hydroxy, ketone, nitro, silyl, sulfo-oxo, sulfonyl, sulfone, sulfoxide, or thiol as described herein.

The term “alkoxy” as used herein is an alkyl group bound through an ether linkage; that is, an “alkoxy” group can be defined as —OA¹ where A¹ is alkyl as defined above. “Alkoxy” also includes polymers of alkoxy groups as just described; that is, an alkoxy can be a polyether such as —OA¹-OA² or —OA¹-(OA²)ₐ-OA³, where a is some integer and A¹, A², and A³ are alkyl groups.

The term “alkenyl” as used herein is a hydrocarbon group of from 2 to 24 carbon atoms with a structural formula containing at least one carbon-carbon double bond. Asymmetric structures such as (A¹A²)C═C(A³A⁴) are intended to include both the E and Z isomers. This can be presumed in structural formulae herein wherein an asymmetric alkene is present, or it can be explicitly indicated by the bond symbol C═C. The alkenyl group can be substituted with one or more groups including, but not limited to, alkyl, halogenated alkyl, alkoxy, alkenyl, alkynyl, aryl, heteroaryl, aldehyde, amino, carboxylic acid, ester, ether, halide, hydroxy, ketone, nitro, silyl, sulfo-oxo, sulfonyl, sulfone, sulfoxide, or thiol, as described below.

The term “cycloalkenyl” is included within the meaning of “alkenyl” and is a non-aromatic carbon-based ring composed of at least three carbon atoms and containing at least one double bound, i.e., C═C. Examples of cycloalkenyl groups include, but are not limited to, cyclopropenyl, cyclobutenyl, cyclopentenyl, cyclopentadienyl, cyclohexenyl, cyclohexadienyl, and the like. The term “heterocycloalkenyl” is a type of cycloalkenyl group as defined above, and is included within the meaning of the terms “cycloalkenyl” and “alkenyl,” where at least one of the carbon atoms of the ring is substituted with a heteroatom such as, but not limited to, nitrogen, oxygen, sulfur, or phosphorus. The cycloalkenyl group and heterocycloalkenyl group can be substituted or unsubstituted. The cycloalkenyl group and heterocycloalkenyl group can be substituted with one or more groups including, but not limited to, alkyl, alkoxy, alkenyl, alkynyl, aryl, heteroaryl, aldehyde, amino, carboxylic acid, ester, ether, halide, hydroxy, ketone, nitro, silyl, sulfo-oxo, sulfonyl, sulfone, sulfoxide, or thiol as described herein.

The term “alkynyl” as used herein is a hydrocarbon group of 2 to 24 carbon atoms with a structural formula containing at least one carbon-carbon triple bond. The alkynyl group can be substituted with one or more groups including, but not limited to, alkyl, halogenated alkyl, alkoxy, alkenyl, alkynyl, aryl, heteroaryl, aldehyde, amino, carboxylic acid, ester, ether, halide, hydroxy, ketone, nitro, silyl, sulfo-oxo, sulfonyl, sulfone, sulfoxide, or thiol, as described below.

The term “aliphatic” refers to a non-aromatic hydrocarbon and can be an alkyl, alkenyl, alkynyl, cycloalkyl, heterocycloalkyl, cycloalkenyl, or heterocycloalkenyl group as disclosed herein.

The term “aryl” as used herein is a group that contains any carbon-based aromatic group including, but not limited to, benzene, naphthalene, phenyl, biphenyl, phenoxybenzene, and the like. The term “aryl” also includes “heteroaryl,” which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term “non-heteroaryl,” which is also included in the term “aryl,” defines a group that contains an aromatic group that does not contain a heteroatom. The aryl group can be substituted or unsubstituted. The aryl group can be substituted with one or more groups including, but not limited to, alkyl, halogenated alkyl, alkoxy, alkenyl, alkynyl, aryl, heteroaryl, aldehyde, amino, carboxylic acid, ester, ether, halide, hydroxy, ketone, nitro, silyl, sulfo-oxo, sulfonyl, sulfone, sulfoxide, or thiol as described herein. The term “biaryl” is a specific type of aryl group and is included in the definition of aryl. Biaryl refers to two aryl groups that are bound together via a fused ring structure, as in naphthalene, or are attached via one or more carbon-carbon bonds, as in biphenyl.

The term “aldehyde” as used herein is represented by the formula —C(O)H. Throughout this specification “C(O)” is a short hand notation for C═O.

The terms “amine” or “amino” as used herein are represented by the formula NA¹A²A³, where A¹, A², and A³ can be, independently, hydrogen, an alkyl, halogenated alkyl, alkenyl, alkynyl, aryl, heteroaryl, cycloalkyl, cycloalkenyl, heterocycloalkyl, or heterocycloalkenyl group described above.

The term “carboxylic acid” as used herein is represented by the formula —C(O)OH. A “carboxylate” as used herein is represented by the formula —C(O)O⁻.

The term “ester” as used herein is represented by the formula —OC(O)A¹ or —C(O)OA¹, where A¹ can be an alkyl, halogenated alkyl, alkenyl, alkynyl, aryl, heteroaryl, cycloalkyl, cycloalkenyl, heterocycloalkyl, or heterocycloalkenyl group described above.

The term “ether” as used herein is represented by the formula A¹ OA², where A¹ and A² can be, independently, an alkyl, halogenated alkyl, alkenyl, alkynyl, aryl, heteroaryl, cycloalkyl, cycloalkenyl, heterocycloalkyl, or heterocycloalkenyl group described above.

The term “ketone” as used herein is represented by the formula A¹C(O)A², where A¹ and A² can be, independently, an alkyl, halogenated alkyl, alkenyl, alkynyl, aryl, heteroaryl, cycloalkyl, cycloalkenyl, heterocycloalkyl, or heterocycloalkenyl group described above.

The term “halide” as used herein refers to the halogens fluorine, chlorine, bromine, and iodine.

The term “hydroxyl” as used herein is represented by the formula —OH.

The term “nitro” as used herein is represented by the formula —NO₂.

The term “nitrile” as used herein in represented by the formula —CN.

The term “silyl” as used herein is represented by the formula —SiA¹A²A³, where A¹, A², and A³ can be, independently, hydrogen, alkyl, halogenated alkyl, alkoxy, alkenyl, alkynyl, aryl, heteroaryl, cycloalkyl, cycloalkenyl, heterocycloalkyl, or heterocycloalkenyl group described above.

The term “sulfo-oxo” as used herein is represented by the formulas —S(O)A¹, —S(O)₂A¹, —OS(O)₂A¹, or —OS(O)₂OA¹, where A¹ can be hydrogen, an alkyl, halogenated alkyl, alkenyl, alkynyl, aryl, heteroaryl, cycloalkyl, cycloalkenyl, heterocycloalkyl, or heterocycloalkenyl group described above. Throughout this specification “S(O)” is a short hand notation for S═O. The term “sulfonyl” is used herein to refer to the sulfo-oxo group represented by the formula —S(O)₂A¹, where A¹ can be hydrogen, an alkyl, halogenated alkyl, alkenyl, alkynyl, aryl, heteroaryl, cycloalkyl, cycloalkenyl, heterocycloalkyl, or heterocycloalkenyl group described above. The term “sulfone” as used herein is represented by the formula A¹S(O)₂A², where A¹ and A² can be, independently, an alkyl, halogenated alkyl, alkenyl, alkynyl, aryl, heteroaryl, cycloalkyl, cycloalkenyl, heterocycloalkyl, or heterocycloalkenyl group described above. The term “sulfoxide” as used herein is represented by the formula A¹S(O)A², where A¹ and A² can be, independently, an alkyl, halogenated alkyl, alkenyl, alkynyl, aryl, heteroaryl, cycloalkyl, cycloalkenyl, heterocycloalkyl, or heterocycloalkenyl group described above.

The term “sulfonylamino” or “sulfonamide” as used herein is represented by the formula —S(O)₂NH—.

The term “thiol” as used herein is represented by the formula —SH.

“A,” “G,” “J,” “L,” “Og,” “X,” “Y,” “Z,” “R¹,” “R²,” “R³,” “Rⁿ,” where n is an integer, as used herein can, independently, possess one or more of the groups listed above. For example, if R¹ is a straight chain alkyl group, one of the hydrogen atoms of the alkyl group can optionally be substituted with a hydroxyl group, an alkoxy group, an alkyl group, a halide, and the like. Depending upon the groups that are selected, a first group can be incorporated within second group or, alternatively, the first group can be pendant (i.e., attached) to the second group. For example, with the phrase “an alkyl group comprising an amino group,” the amino group can be incorporated within the backbone of the alkyl group. Alternatively, the amino group can be attached to the backbone of the alkyl group. The nature of the group(s) that is (are) selected will determine if the first group is embedded or attached to the second group.

Unless stated to the contrary, a formula with chemical bonds shown only as solid lines and not as wedges or dashed lines contemplates each possible isomer, e.g., each enantiomer and diastereomer, and a mixture of isomers, such as a racemic or scalemic mixture.

Reference will now be made in detail to specific aspects of the disclosed materials, compounds, compositions, articles, and methods, examples of which are illustrated in the accompanying Examples and Figures.

Materials and Compositions

Disclosed herein are materials, compounds, compositions, and components that can be used for, can be used in conjunction with, can be used in preparation for, or are products of the disclosed methods and compositions. These and other materials are disclosed herein, and it is understood that when combinations, subsets, interactions, groups, etc. of these materials are disclosed that while specific reference of each various individual and collective combinations and permutation of these compounds may not be explicitly disclosed, each is specifically contemplated and described herein. For example, if a composition is disclosed and a number of modifications that can be made to a number of components of the composition are discussed, each and every combination and permutation that are possible are specifically contemplated unless specifically indicated to the contrary. Thus, if a class of components or moieties A, B, and C are disclosed as well as a class of components or moieties D, E, and F and an example of a composition A-D is disclosed, then even if each is not individually recited, each is individually and collectively contemplated. Thus, in this example, each of the combinations A-E, A-F, B-D, B-E, B-F, C-D, C-E, and C-F are specifically contemplated and should be considered disclosed from disclosure of A, B, and C; D, E, and F; and the example combination A-D. Likewise, any subset or combination of these is also specifically contemplated and disclosed. Thus, for example, the sub-group of A-E, B-F, and C-E are specifically contemplated and should be considered disclosed from disclosure of A, B, and C; D, E, and F; and the example combination A-D. This concept applies to all aspects of this disclosure including, but not limited to, steps in methods of making and using the disclosed compositions. Thus, if there are a variety of additional steps that can be performed it is understood that each of these additional steps can be performed with any specific aspect or combination of aspects of the disclosed methods, and that each such combination is specifically contemplated and should be considered disclosed.

In one aspect, disclosed herein are amorphous and liquid crystalline light-emitting organic materials that comprise a core moiety to which one or more conjugated oligomers are attached through one or more flexible linkers or spacers. In a general aspect, the organic light-emitting materials disclosed herein can comprise the general formula: 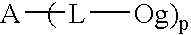
wherein Og is a conjugated oligomer, as described herein; A is a core moiety, such as a non-conducting core, a hole-conducting core, or an electron-conducting core, also described herein; and L is a linker (e.g., aliphatic group) that connects A to Og. The core moiety A can be linked to a number of conjugated oligomers Og; as such, p can be from 1 to 25 (e.g., p can be 1, 2, 3, 4, 5, 6, 7, 8, 9, 10, 11, 12, 13, 14, 15, 16, 17, 18, 19, 20, 21, 22, 23, 24, or 25, where any of the stated values can form an upper and/or lower endpoint). In some other examples, p can be from 1 to 10 or p can be greater than 25. In many of the examples, herein p is 1, 2, or 3.

Also, the same linker L or one or more different kinds of linkers L can be attached to the core moiety A. In further examples, the same conjugated oligomer Og or one or more different kinds of conjugated oligomers Og can be attached to the core moiety A. Thus, contemplated herein are materials where a core moiety is coupled to one or more of the same conjugated oligomers by one or more different linkers, where a core moiety is coupled to one or more different conjugated oligomers by one or more of the same linkers, where the core moiety is coupled to one or more different conjugated oligomers by one or more different linkers, and where the core moiety is coupled to the one or more of the same conjugated oligomers by one or more of the same linkers. Because a conjugated oligomer Og is linked to the core moiety A, it is also referred to herein as a pendant.

In certain examples described herein, the disclosed materials can be characterized by one or more of the following properties: (1) an electron-conducting core, a hole-conducting core, or a non-conducting core, (2) one or more terfluorene and pentafluorene pendants for light emission (e.g., blue light emission), (3) a flexible linker attaching the pendant(s) to the core, thereby enabling independent functions of the two structural elements, (4) tunability of charge injection and transport properties while emitting unpolarized and polarized light, (5) ability to form glassy isotropic and liquid-crystal films by solution processing, and (6) potential use in highly efficient light-emitting diodes with long-term stability.

In other examples, the disclosed materials can exhibit a glass transition temperature and/or a clearing point from about 60 to about 360, from about 80 to about 340, from about 100 to about 320, from about 120 to about 300, from about 140 to about 280° C., from about 160 to about 260° C., or from about 180 to about 240° C. Certain materials disclosed herein can have a glass transition temperature of about 60, 65, 70, 75, 80, 85, 90, 95, 100, 105, 110, 115, 120, 125, 130, 135, 140, 145, 150, 155, 160, 165, 170, 175, 180, 185, 190, 195, 200, 205, 210, 215, 220, 225, 230, 235, 240, 245, 250, 255, 260, 265, 270, 275, 280, 285, 290, 295, 300, 305, 310, 315, 320, 325, 330, 335, 340, 345, 350, 355, 360° C., where any of the stated values can form an upper and/or lower endpoint. Film morphology and thermal transition temperatures can be characterized by methods known in the art, such as by polarized optical microscopy and differential scanning calorimetry.

In still other examples, the disclosed materials can have an orientational order parameter of about 0.75 (e.g., about 0.70, 0.71, 0.72, 0.73, 0.74, 0.75, 0.76, 0.77, 0.78, 0.79, or 0.80, where any of the stated values can form an upper and/or lower endpoint). Orientational order parameters can be determined by methods known in the art, such as by UV-Vis absorption dichroism.

In further examples, the disclosed materials can have a photoluminescence quantum yield up to about 51% (e.g., less than about 51%, 50%, 49%, 48%, 47%, 46%, 45%, 44%, 43%, 42%, 41%, or 40%). Photoluminescence quantum yield can be determined by methods known in the art, such as by spectrofluorimetry, as reported in Geng et al., Chem. Mater. 2003, 15:542-549.

These materials disclosed herein can be used, for example, in organic light-emitting devices (OLEDs) such as monitors, displays, LCDs, and the like. They can be backlight for liquid-crystal displays and as electroluminescent displays. In many examples described herein, the disclosed materials can be solution-processable; for example, they can be processed into large-area thin films by spin coating-from dilute solutions.

The disclosed materials are, in many examples, multifunctional materials that can form glassy amorphous or liquid crystalline films using light-emitting conjugated oligomers and charge injection and transport moieties as the building blocks. The flexible linker, such as an alkyl chain, connecting the two building blocks (i.e., the core moiety and the conjugated oligomers) can serve to permit light emission and charge injection/transport to be incorporated without mutual interference and to prevent crystallization while encouraging glass formation of the hybrid system. Although the merits of a multilayer device structure are well documented (Adachi et al., Jpn. J. Appl. Phys. 1988, 27:L269-L271; Adachi et al., Appl. Phys. Lett. 1989, 55:1489-1491; Brown et al., Appl. Phys. Lett. 1992, 61:2793-2795; Yang and Pei, J. Appl. Phys. 1995, 77:4807-4809; Strukelj et al., J. Am. Chem. Soc. 1995, 117:11976-11983; Buchwald et al., Adv. Mater. 1995, 7:839-842; Fukuda et al., Appl. Phys. Lett. 1996, 68:2346-2348; Kim et al., Chem. Mater. 2004, 16:5051-5057; Liew et al., Appl. Phys. Lett. 2004, 85:4511-4513; Liao et al., Appl. Phys. Lett. 2005, 86:203507-1-203507-3; Yi et al., Appl. Phys. Lett. 2005, 86:213502-1-213502-3), multifunctional materials such as those disclosed herein can offer devices comprising fewer layers, thus reducing fabrication costs and operating voltages while improving device performance.

Conjugated Oligomers/Pendants

The disclosed materials can comprise one or more conjugated oligomers (e.g., “Og” in the general formula above), which are described herein. In some examples the same oligomers can be connected to the core via the linker, whereas in other examples, different oligomers can be connected to the core via the linker. The disclosed conjugated oligomers can have any number of monomeric units (e.g., fluorene units) linked together. For example, the disclosed conjugated oligomers can have from 2, 3, 4, 5, 6, 7, 8, 9, 10, 11, 12, 13, 14, 15, 16, 17, 18, 19, 20, 21, 22, 23, 24, or 25 monomeric units, where any of the stated values can form an upper and/or lower endpoint. The monomeric units can be the same or different, as are described herein. For example, a core can be connected to one or more conjugated oligomers with, e.g., 3 monomeric units and one or more conjugated oligomers with, e.g., 5 monomeric units.

Such conjugated oligomers can be monodisperse with a relatively low molecular weight. Monodisperse conjugated oligomers are typically characterized by a well-defined and uniform molecular structure as well as chemical purity acquired through, for example, recrystallization and/or column chromatography. The relatively short and uniform chains of the oligomers can also be conducive to the formation of monodomain glassy-nematic films without grain boundaries through thermal annealing under mild conditions. These merits can furnish fundamental insight into structure-property relationships and to improving OLED performance, as traces of impurities could result in exciton quenching and device failure.

In contrast to many types of polymers, the disclosed oligomers can be less likely to undergo glass transition to form a morphologically stable glassy film. Moreover, few monodisperse conjugated oligomers are known to exhibit thermotropic liquid crystalline mesomorphism. Recently, the first examples of monodisperse glassy-nematic conjugated oligomers were reported for the demonstration of linearly polarized, full-color and white-light OLEDs using 1,3,5-tri(phenyl-2-benz-imidazolyl)benzene as the electron-transporting and hole/exciton blocking layer (see Geng et al., Chem. Mater. 2003, 15:542-549; Culligan et al., Adv. Mater. 2003, 15:1176-1180; Geng et al., Chem. Mater. 2003, 15:4352-4360; Chen et al., Adv. Mater. 2004, 16:783-788, which are incorporated by reference herein for at least their teaching of conjugated oligomers). Both the luminance efficiency and polarization ratio are the best of all polarized OLEDs reported to date. It was also recognized that charge injection and transport can be varied as desired to further improve device performance.

Nematic conjugated oligomers have been demonstrated for polarized OLEDs (see e.g., Geng et al., Chem. Mater. 2003, 15:542-549; Culligan et al., Adv. Mater. 2003, 15:1176-1180; Geng et al., Chem. Mater. 2003, 15:4352-4360; and Chen et al., Adv. Mater. 2004, 16:783-788, which are incorporated by reference herein for at least their teaching of conjugated oligomers), which are potentially useful as an efficient light source for liquid crystal displays, electroluminescent displays with improved viewing quality, projection displays, stereoscopic imaging systems, and low threshold solid-state organic lasers with an added advantage of high polarization. Nematic oligomeric pendants can be chemically bonded to a volume-excluding core to form morphologically stable glassy liquid crystals for polarized OLEDs following a core-pendant approach (see e.g., Chen et al., Adv. Mater. 1996, 8:998-1001; Chen et al., Nature 1999, 397:506-508; Fan et al., Chem. Mater. 2001, 13:4584-4594; Katsis et al., Chem. Mater. 1999, 11:1590-1596; Chen et al., Adv. Mater. 2000, 12:1283-1286; Chen et al., Chem. Mater. 2003, 15:2534-2542; Chen et al., Adv. Mater. 1999, 11:1183-1186; and Chen et al., Adv. Mater. 2003, 15:1061-1065, which are incorporated by reference herein for at least their teaching of core-pendant structures and methods for their preparation). Moreover, shorter oligomeric pendants can be used to yield glassy amorphous materials for unpolarized OLEDs.

Shown below are representative monodisperse, conjugated oligomers, LE-1 and LE-2, which can be used in the disclosed organic light-emitting materials. 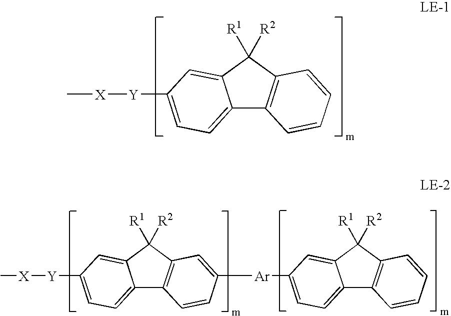
wherein X and Y are, independently of one another, alkyl, alkoxy, alkenyl, alkynyl, aryl, or heteroaryl; R¹ and R² are, independently of one another, hydrogen, alkyl, alkoxy, alkenyl, alkynyl, aryl, heteroaryl, hydroxy, ketone, nitro, or silyl; m is from 1 to 25 (e.g., 1, 2, 3, 4, 5, 6, 7, 8, 9, 10, 11, 12, 13, 14, 15, 16, 17, 18, 19, 20, 21, 22, 23, 24, or 25, where any of the stated values can form an upper and/or lower endpoint) and Ar is aryl. The substituents R¹ and R² one each fluorene unit can vary within a conjugated segment.

Specific examples of Ar include, but are not limited to, the following: 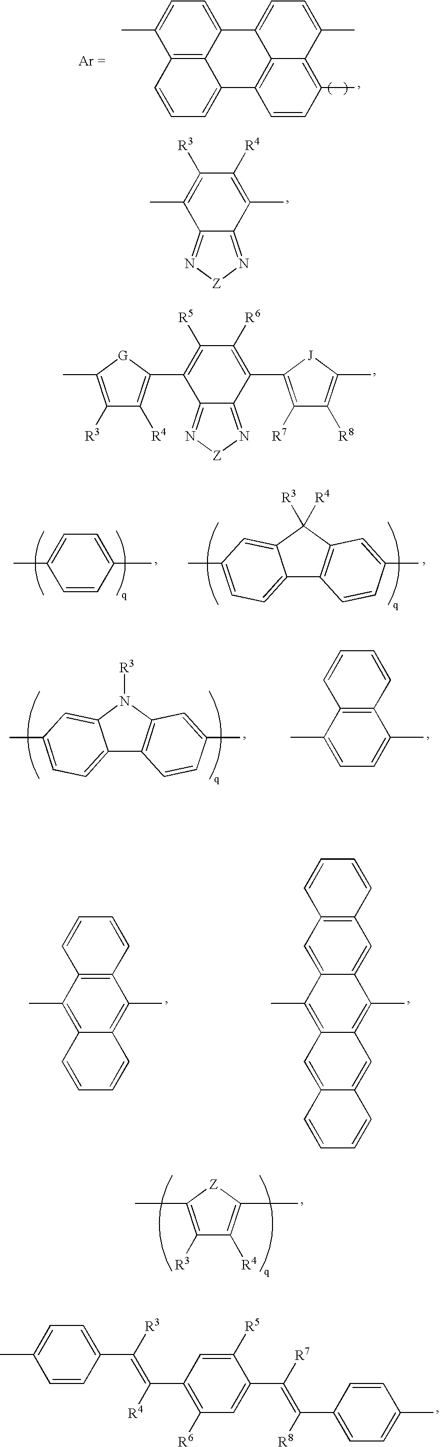 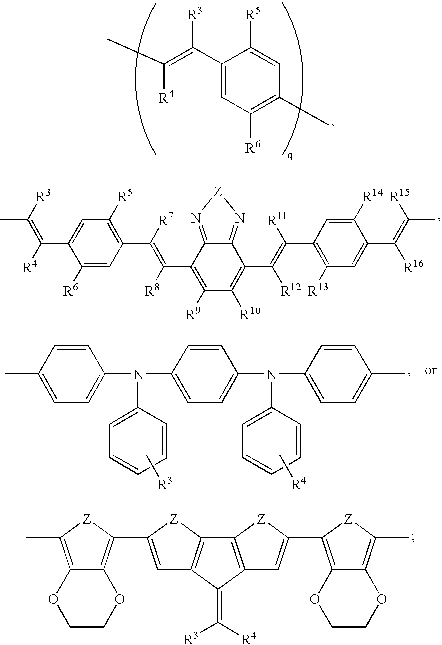
where R³, R⁴, R⁵, R⁶, R⁷, R⁸, R⁹, R¹⁰, R¹¹, R¹², R¹³, R¹⁴, R¹⁵, and R¹⁶ are, independently of one another, hydrogen, alkyl, alkoxy, alkenyl, alkynyl, aryl, heteroaryl, or CN; Z, G, and J are, independently of one another, O, S, or N; and q is from 1 to 10 (e.g., 1, 2, 3, 4, 5, 6, 7, 8, 9, or 10, where any of the stated valued can form an upper and/or lower endpoint).

In some specific examples, X is —CH₂—, or —O—, —C(O)O—, and Y is —(CH₂)ₙ—, or —CH₂O)ₙ—, where n is from 1 to 25 (e.g., 1, 2, 3, 4, 5, 6, 7, 8, 9, 10, 11, 12, 13, 14, 15, 16, 17, 18, 19, 20, 21, 22, 23, 24, or 25, where any of the stated values can form an upper and/or lower endpoint). In other examples, R¹ and R² are both sec-pentyl. In still other examples, R¹ and R² are both propyl or both 2-ethyl-hexyl. In still other specific examples, R³, R⁴, R⁵, R⁶, R⁷, R⁸, R⁹, R¹⁰, R¹¹, R¹², R¹³, R¹⁴, and R¹⁵ are, H, CₖH₂ₖ₊₁, —OCₖH₂ₖ₊₁, or —O(CH₂CH₂)ₖCH₃, where k is from 1 to 25 (e.g., 1, 2, 3, 4, 5, 6, 7, 8, 9, 10, 11, 12, 13, 14, 15, 16, 17, 18, 19, 20, 21, 22, 23, 24, or 25, where any of the stated values can form an upper and/or lower endpoint). In yet other examples, R³, R⁴, R⁷, R⁸ R⁹, R¹⁰, R¹¹, R¹⁴, and R¹⁵ are, independently of one another, H or CN, and R⁵, R⁶, R¹², and R¹³, are, independently of one another, H, CN, CₖH₂ₖ₊₁, —OCₖH₂ₖ₊₁, where k is from 1 to 10 (e.g., 1, 2, 3, 4, 5, 6, 7, 8, 9, or 10, where any of the stated values can form an upper and/or lower endpoint). In still other examples, m is 3, 4, or 5. In yet further examples, m is 1 or 2.

These representative monodisperse conjugated oligomers used for the construction of the disclosed organic light-emitting materials can, in certain situations, perform better than the previously reported monodisperse conjugated oligomers (Geng et al., Chem. Mater. 2003, 15:42-549; Geng et al., Chem. Mater. 2003, 15:4352-4360) in terms of morphological stability, luminance yield, and device lifetime. Further, these conjugated oligomers can be bound to a core, as previously noted, for light-emitting glassy liquid crystalline and amorphous materials with tunable charge injection and transport properties.

Still further examples of conjugated oligomers that are suitable for use in the disclosed materials are 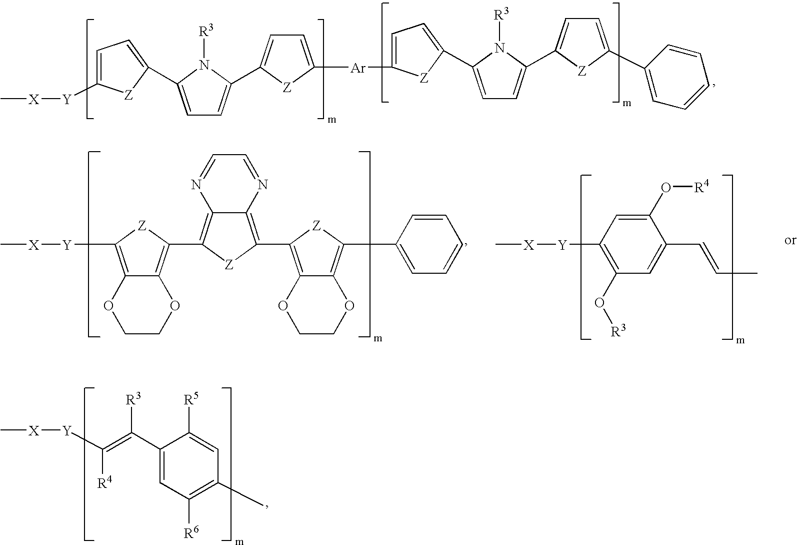
where R³, R⁴, R⁵, R⁶, X, Y, Z, Ar, and m are as defined herein. For example, R³ can be sec-pentyl and R⁴ can be methyl. In other examples, R³⁻⁵ can be hydrogen and R⁶ can be hydrogen or CN. Still further, R³⁻⁶ can be hydrogen, or R³ and R⁶ can be hydrogen, R⁴ can be CN, R⁵ can be methoxy.

Some specific Ar moieties that are suitable for the disclosed conjugated oligomer pendants are shown below:

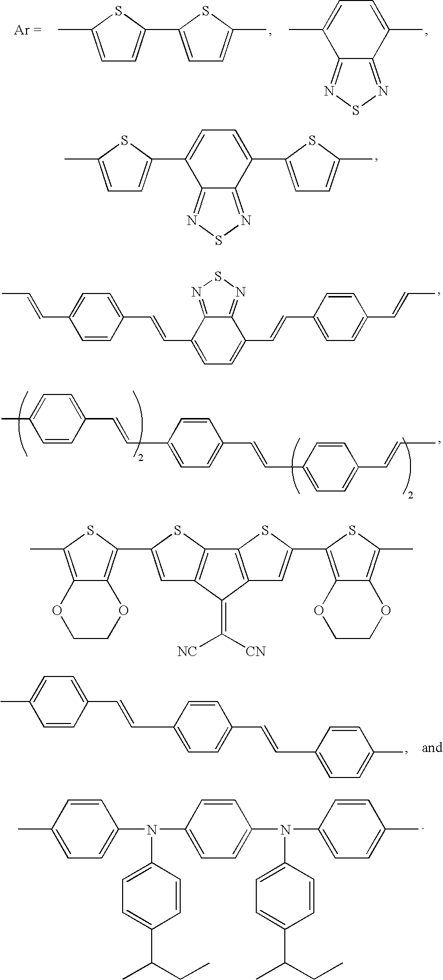

Core Moiety

The disclosed materials can comprise a core moiety (e.g., “A” in the general formula above), which are described herein. Depicted below are examples of suitable non-conducting cores, electron-conducting cores, and hole-conducting cores designated by prefixes NC-, EC-, and HC-, respectively.

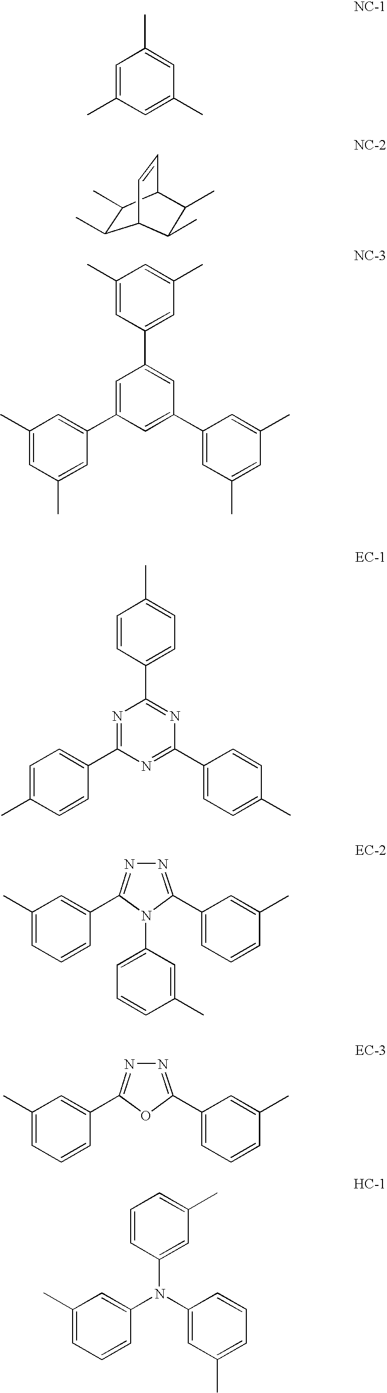

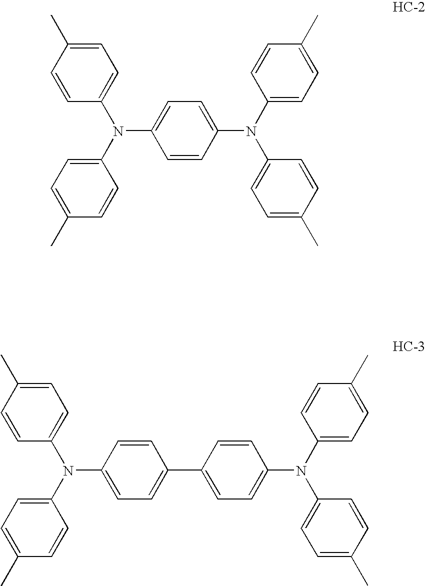

In some specific examples the core can be a triphenyl triazine (“TRZ”), i.e., EC-1 above. In other examples the core can be triphenyl diamine (“TPD”), i.e., HC-3 above.

The selection of a hole-conducting and an electron-conducting core is dictated by the HOMO and LUMO energy levels as well as the charge-carrier mobility (Strohriegl and Grazulevicius, Adv. Mater. 2002, 14:1439-1452; Getautis et al., J Photochem. Photobiol. A 2002, 151:39-43; Yasuda et al., Jpn. J. Appl. Phys. 2002, 41:5626-5629; Ishi-I et al., Chem. Lett. 2004, 33:1244-1246; Kido et al., Jpn. J. Appl. Phys. 1993, 32:L917-L920; Sainova et al., Appl. Phys. Lett. 2000, 76:1810-1812; Tao et al., Chem. Phys. Lett. 2004, 397:1-4; Kulkarni et al., Chem. Mater. 2004, 16:4556-4573). As shown herein, charge injection and transport properties can be fine-tuned by mixing materials with different cores carrying the same pendants without encountering phase separation.

Hole-Conducting Cores

Suitable hole-conducting cores are electron-rich and electron-donating with relatively low ionization potentials with HOMO energy levels suitable for efficient injection of holes into them from common anodes.

Further examples of hole-conducting cores that can be used in the disclosed materials include, but are not limited to, polypyrrole, polyaniline, poly(phenylene vinylene), polythiophene, polyarylamine, porphyrin derivatives such as 1,10,15,20-tetraphenyl-21H,23H-p-porphyrin copper (II), copper phthalocyanine, copper tetramethyl phthalocyanine, zinc phthalocyanine, titanium oxide phthalocyanine; magnesium phthalocyanine, and the like. Other examples of suitable hole-conducting cores are the aromatic tertiary amines such as those disclosed in U.S. Pat. No. 4,539,507, which is incorporated herein by reference in its entirety. Exemplary aromatic tertiary amines include, but are not limited to, bis(4-dimethylamino-2-methylpheny-1)phenylmethane, N,N,N-tri(p-tolyl)amine, 1,1-bis(4-di-p-tolylaminophenyl)-cyclohexane, 1,1-bis(4-di-p-tolylaminophenyl)-4-phenylcyclohexane, N,N′-diphenyl-N,N′-bis(3-methylphenyl)-1,1′-biphenyl-4,4′-diamine, N,N′-diphenyl-N,N′-bis(3-methylphenyl)-1,1′-biphenyl-4,4′-diamine, N,N′-diphenyl-N,N′-bis(4-methoxyphenyl)-1,1′-biphenyl-4,4′-diamine, N,N,N′,N′-tetra-p-tolyl-1,1′-biphenyl-4,4′-diamine, N,N′-di-1-naphthyl-N,N′-diphenyl-1,1′-biphenyl-4,4′-diamine, N,N′-bis(p-biphenyl)-N,N′-diphenyl benzidine(biphenyl TPD), mixtures thereof and the like. Other suitable tertiary aromatic amines that can be used are the naphtyl-substituted benzidine derivatives, such as, N,N′-di(naphthalene-1-yl)-N,N′-diphenyl-benzidine (NPB). Another class of aromatic tertiary amines are polynuclear aromatic amines such as, but not limited to, N,N-bis-[4′-(N-phenyl-N-m-tolylamino)-4-biphenylyllaniline; N,N-bis-[4′-(N-phenyl-N-m-tolylamino)-4-biphenylyl]-m-toluidine-; N,N-bis-[4′-(N-phenyl-N-m-tolylamino)-4-biphenylyl]-p-toluidine; N,N-bis-[4′-(N-phenyl-N-p-tolylamino)-4-biphenylyl]aniline; N,N-bis-[4′-(N-phenyl-N-p-tolylamino)-4-biphenylyl]-m-toluidine; N,N-bis-[4′-(N-phenyl-N-p-tolylamino)-4-biphenylyl]-p-toluidine; N,N-bis-[4′-(N-phenyl-N-p-chlorophenylamino)-4-biphenylyl]-m-toluidine; N,N-bis-[4′-(N-phenyl-N-m-chlorophenylamino)-4-biphenylyl]-m-toluidine; N,N-bis-[4′-(N-phenyl-N-m-chlorophenylamino)-4-biphenylyl]-p-toluidine; N,N-bis-[4′-(N-phenyl-N-m-tolylamino)-4-biphenylyl]-p-chloroaniline; N,N-bis-[4′-(N-phenyl-N-p-tolylamino)-4-biphenylyl]-m-chloroaniline; N,N-bis-[4′-(N-phenyl-N-m-tolylamino)-4-biphenylyl]-1-aminonaphthalene, mixtures thereof and the like; 4,4′-bis(9-carbazolyl)-1,1′-biphenyl compounds, such as 4,4′-bis(9-carbazolyl)-1,1′-biphenyl and 4,4′-bis(3-methyl-9-carbazolyl)-1,1′-biphenyl, and the like.

Still further examples of hole-conducting cores that can be used in the disclosed materials are the indolo-carabazoles, such as those disclosed in U.S. Pat. Nos. 5,942,340 and 5,952,115, each incorporated herein by reference in its entirety, such as 5,11-di-naphthyl-5,11-dihydroindolo[3,2-b]carbazole, and 2,8-dimethyl-5,11-di-naphthyl-5,11-dihydroindolo[3,2-b]carbazole; N,N,N′N′-tetraarylbenzidines, wherein aryl can be selected from phenyl, m-tolyl, p-tolyl, m-methoxyphenyl, p-methoxyphenyl, 1-naphthyl, 2-naphthyl and the like. Illustrative examples of N,N,N′N′-tetraarylbenzidine are N,N′-di-1-naphthyl-N,N′-diphenyl-1,1′-biphenyl-4,4′-diamine; N,N′-bis(3-methylphenyl)-N,N′-diphenyl-1,1′-biphenyl-4,4′-diamine; N,N′-bis(3-methoxyphenyl)-N,N′-diphenyl-1,1′-biphenyl-4,4′-diamine, and the like.

More examples of hole-conducting cores include, but are not limited to, polyfluorenes such as poly(9,9-di-n-octylfluorene-2,7-diyl), poly2,8-(6,7,12,12-tetraalkylindenofluorene), and copolymers containing fluorenes such as fluorene-amine copolymers, as disclosed in Bernius et al., Proceedings of SPIE Conference on Organic Light Emitting Materials and Devices III, Denver, Colo., July 1999, Volume 3797, p. 129, which is incorporated by reference in its entirety.

Additional examples of suitable hole-conducting cores are triphenylenes, such as 2-hydroxy-3,6,7,10,11,-pentakis(alkyloxy)triphenylenes; and 2,3,6,7,10,11-hexakis(alkyloxy)triphenylene. Such compounds and methods for making them are disclosed in Schultz et al., J. Chem. Soc. Perkin Trans. 1, 2000, 3356-3361, which is incorporated by reference herein for its teachings of triphenylenes.

Hexabenzocoronenes are still further examples of suitable hole-conducting cores. The discotic liquid crystal hexa-peri-hexabenzocoronene can be used with a perylene dye to produce thin films with vertically segregated perylene and hexabenzocoronene, see e.g., Schmidt-Mende et al., Science 2001, 293:1119-1122, which is incorporated by reference herein for its teaching of hexabenzocoronene. A specific example of includes N,N′bis(1-ethylpropyl)-3,4,9,10-perylenebis (dicarboximide) (perylene) and a discotic, LC, hexaphenyl-substituted hexabenzocoronene (HBC-PhCl₂). The chemical structure of HBC-PhC₁₂ is shown below. HBC has the same structure as shown below without the six—Ph-C₁₂H₂₅ substituents.

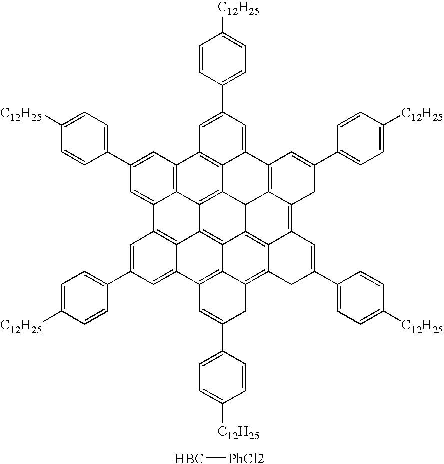

Electron-Conducting Cores

Suitable electron-conducting cores are electron-deficient and electron-accepting due to their relatively high electron affinities with LUMO levels appropriate for injection of electrons from common cathodes.

Further examples of electron-conducting cores that can be used in the disclosed materials include, but are not limited to, the metal chelates of 8-hydroxyquinoline as disclosed in U.S. Pat. Nos. 4,539,507; 5,151,629; 5,150,006 and 5,141,671, each incorporated herein by reference in its entirety. Other examples include stilbene derivatives, such as 4,4′-bis(2,2-diphenylvinyl)biphenyl.

Another class of electron-conducting cores are the metal thioxinoid compounds illustrated in U.S. Pat. No. 5,846,666, which is incorporated herein by reference in its entirety. These materials include metal thioxinoid compounds of bis(8-quinolinethiolato)zinc; bis(8-quinolinethiolato)cadmium; tris(8-quinolinethiolato)gallium; tris(8-quinolinethiolato)indium; bis(5-methylquinolinethiolato)zinc; tris(5-methylquinolinethiolato)gallium; tris(5-methylquinolinethiolato)indium; bis(5-methylquinolinethiolato)cadmium; bis(3-methylquinolinethiolato)cadmium; bis(5-methylquinolinethiolato)zinc; bis[benzo {μ}-8-quinolinethiolato]zinc; bis[3-methylbenzo {μ}-8-quinolinethiolato]zinc; bis[3,7-dimethylbenzo {μ}-8-quinolinethiolato]zinc; and the like, including mixtures thereof.

Another class of suitable electron-conducting cores are the oxadiazole metal chelates such as bis[2-(2-hydroxyphenyl)-5-phenyl-1,3,4-oxadiazolato]zinc; bis[2-(2-hydroxyphenyl)-5-phenyl-1,3,4-oxadiazolato]beryllium; bis[2-(2-hydroxyphenyl)-5-(1-naphthyl)-1,3,4-oxadiazolato]zinc; bis[2-(2-hydroxyphenyl)-5-(1-naphthyl)-1,3,4-oxadiazolato]beryllium; bis[5-biphenyl-2-(2-hydroxyphenyl)-1,3,4-oxadiazolato]zinc; bis[5-biphenyl-2-(2-hydroxyphenyl)-1,3,4-oxadiazolato]beryllium; bis(2-hydroxyphenyl)-5-phenyl-1,3,4-oxadiazolato]lithium; bis[2-(2-hydroxyphenyl)-5-p-tolyl-1,3,4-oxadiazolato]zinc; bis[2-(2-hydroxyphenyl)-5-p-tolyl-1,3,4-oxadiazolato]beryllium; bis[5-(p-tert-butylphenyl)-2-(2-hydroxyphenyl)-1,3,4-oxadiazolato]zinc; bis[5-(p-tert-butylphenyl)-2-(2-hydroxyphenyl)-1,3,4-oxadiazolato]beryllium; bis[2-(2-hydroxyphenyl)-5-(3-fluorophenyl)-1,3,4-oxadiazolato]zinc; bis[2-(2-hydroxyphenyl)-5-(4-fluorophenyl)-1,3,4-oxadiazolato]zinc; bis[2-(2-hydroxyphenyl)-5-(4-fluorophenyl)-1,3,4-oxadiazolato]beryllium; bis[5-(4-chlorophenyl)-2-(2-hydroxyphenyl)-1,3,4-oxadiazolato]zinc; bis[2-(2-hydroxyphenyl)-5-(4-methoxyphenyl)-1,3,4-oxadiazolato]zinc; bis[2-(2-hydroxy-4-methylphenyl)-5-phenyl-1,3,4-oxadiazolato]zinc; bis[2-a-(2-hydroxynaphthyl)-5-phenyl-1,3,4-oxadiazolato]zinc; bis[2-(2-hydroxyphenyl)-5-p-pyridyl-1,3,4-oxadiazolato]zinc; bis[2-(2hydroxyphenyl)-5-p-pyridyl-1,3,4-oxadiazolato]beryllium; bis[2-(2-hydroxyphenyl)-5-(2-thiophenyl)-1,3,4-oxadiazolato]zinc; bis[2-(2-hydroxyphenyl)-5-phenyl-1,3,4-thiadiazolato]zinc; bis[2-(2-hydroxyphenyl)-5-phenyl-1,3,4-thiadiazolato]beryllium; bis[2-(2-hydroxyphenyl)-5-(1-naphthyl)-1,3,4-thiadiazolato]zinc; and bis[2-(2-hydroxyphenyl)-5-(1-naphthyl)-1,3,4-thiadiazolato]beryllium, and the like, including mixtures thereof.

Other examples of electron-conducting cores are hexaazatrinaphthylenes including, but not limited to, the 5,6,11,12,17,18-hexaazatrinaphthylenes (HAT-NA) disclosed in Kaafarani et al., J. Am. Chem. Soc. 2005, 127:16358-16359, which is incorporated by reference herein for its teachings of hexaazatrinaphthylenes. Specific examples of these cores are shown below, where R¹⁷ is H, —CO₂R¹⁸ where R¹⁸ is substituted alkyl, aryl, or CH₂C₆F₅. 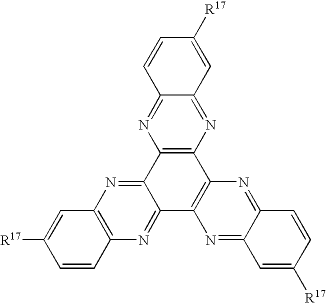
Similarly, hexaazatriphenylene-hexacarboxy triamides are also suitable. A specific example includes tris[N-(3,4,5-tridodecyloxyphenyl)]-1,4,5,8,9,12-hexaazatriphenylene-2,3,6,7,10,11-hexacarboxy triamide disclosed in Pieterse et al., Chem. Mater. 2001, 13:2675-2679, which is incorporated by reference herein for its teaching of various hexaazatriphenylenes.

Still further examples of electron-conducting cores are azole based derivatives such as imidazoles, 1,2,4-triazoles, thiazoles, thiadiazoles, oxazoles, and oxadiazoles such as 2-(4-biphenyl)-5-(4-tert-butylphenyl)-1,3,4-oxadiazole (PBD) and 2,5-bis(4-naphthyl)-1,3,4-oxadiazole (BND). Other examples include dendritic molecules of 1,3,5-tris(N-phenyl-benzimidizol-2-yl)benzene (TPBI). Quinoline-based materials and quinoxaline-based materials like bis(phenylquinoxaline) and starburst tris(phenylquinoxaline) are also suitable cores. Still further, diphenylanthrazoline are suitable electron-conducting cores for the disclosed materials. Phenanthrolines have deep HOMO levels and are rigid planar structures, which make them suitable hole-blocking cores for the disclosed materials. Siloles like 2,5-diarylsiloles, have low LUMO levels and are also suitable. Dimesitylboryl are still further examples of suitable electron-conducting cores. 1,3,5-triazines, which have good thermal stability and include examples such as triaryl-1,3,5-triazine derivatives are also acceptable cores. Additional examples are pyrimidine containing spirobifluorenes and they pyrimidine containing compounds shown below: 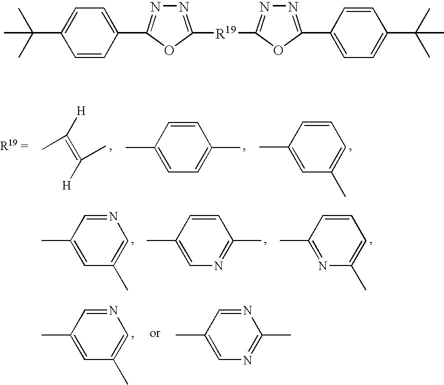
These and other examples are disclosed in Kulkarni et al., Chem. Mater. 2004, 16:4556-4573 and Hughes and Bryce, J Material Chem. 2005, 15:94-107, which are incorporated by reference herein in their entireties.

Perylene, as shown below, is yet another example of a suitable electron-conducting core that can be used in the materials disclosed herein. 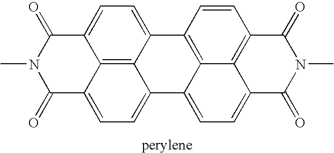
Still further examples of suitable cores that can be used in the disclosed methods are shown below.

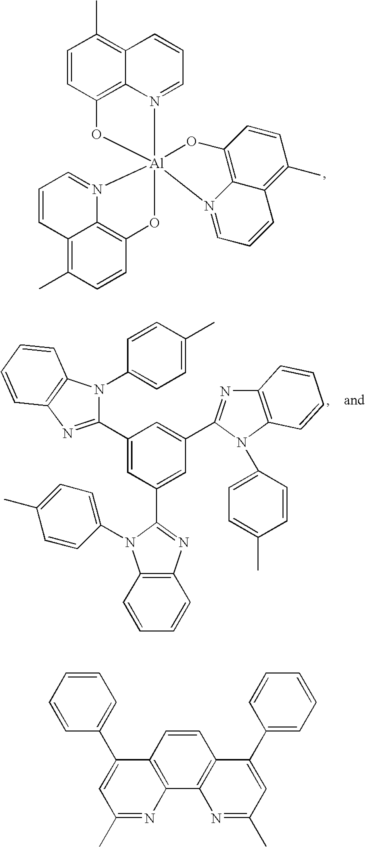

Linker

The disclosed materials can comprise one or more linkers (e.g., “L” in the general formula above or the combination of X-Y in other formulae herein), which are described herein. The linker component of the disclosed organic light-emitting materials can be any moiety that can connect the core moiety and the conjugated oligomer(s). Thus a linker initially contains at least two functional groups, e.g., one functional group that can be used to form a bond with the core and another functional group that can be used to form a bond with the conjugated oligomer(s). Typically, though not necessarily, the functional group on the linker that is used to form a bond with the core is at one end of the linker and the functional group that is used to form a bond with the conjugated oligomer(s) is at the other end of the linker.

The attachment of the linker to the core and the linker to the conjugated oligomer can be via a covalent bond by reaction methods known in the art. When the core and conjugated oligomer(s) are attached via the linker, the core can be first coupled to the linker, which is then attached to the conjugated oligomer(s). Alternatively, the linker can be first coupled to the conjugated oligomer(s) and then be attached to the core. Still further the linker can be simultaneously coupled to the core and the conjugated oligomer(s).

The linker can be of varying lengths, such as from 1 to 20 atoms in length. For example, the linker can be from 1, 2, 3, 4, 5, 6, 7, 8, 9, 10, 11, 12, 13, 14, 15, 16, 17, 18, 19, or 20 atoms in length, where any of the stated values can form an upper and/or lower end point. Also, the longer the linker, the greater freedom of movement the conjugated oligomer(s) can have. Further, the linker can be substituted or unsubstituted. When substituted, the linker can contain substituents attached to the backbone of the linker or substituents embedded in the backbone of the linker. For example, an amine substituted linker can contain an amine group attached to the backbone of the linker or a nitrogen in the backbone of the linker. Suitable moieties for the linker include, but are not limited to, substituted or unsubstituted, branched or unbranched, alkyl, alkenyl, or alkynyl groups, ethers, esters, polyethers, polyesters, polyalkylenes, polyamines, heteroatom substituted alkyl, alkenyl, or alkynyl groups, cycloalkyl groups, cycloalkenyl groups, heterocycloalkyl groups, heterocycloalkenyl groups, and the like, and derivatives thereof.

In one aspect, the linker can comprise a C₁-C₆ branched or straight-chain alkyl, such as methyl, ethyl, n-propyl, isopropyl, n-butyl, isobutyl, sec-butyl, tert-butyl, n-pentyl, isopentyl, neopentyl, sec-pentyl, or hexyl. In a specific example, the linker can comprise —(CH₂)ₙ—, wherein n is from 1 to 5, from 1 to 4, from 1 to 3, or from 1 to 2. In a particular example, the linker can be propyl.

In another example, the linker can comprise a C₁-C₆ branched or straight-chain alkoxy such as a methoxy, ethoxy, n-propoxy, isopropoxy, n-butoxy, isobutoxy, sec-butoxy, tert-butoxy, n-pentoxy, isopentoxy, neopentoxy, sec-pentoxy, or hexoxy. In still another aspect, the linker can comprise a C₂-C₆ branched or straight-chain alkyl, wherein one or more of the carbon atoms are substituted with oxygen (e.g., an ether) or nitrogen (e.g., an amino group). For example, suitable linkers can include, but are not limited to, a methoxymethyl, methoxyethyl, methoxypropyl, methoxybutyl, ethoxymethyl, ethoxyethyl, ethoxypropyl, propoxymethyl, propoxyethyl, methylaminomethyl, methylaminoethyl, methylaminopropyl, methylaminobutyl, ethylaminomethyl, ethylaminoethyl, ethylaminopropyl, propylaminomethyl, propylaminoethyl, methoxymethoxymethyl, ethoxymethoxymethyl, methoxyethoxymethyl, methoxymethoxyethyl, and the like, and derivatives thereof. In one specific example, the linker can comprise a methoxymethyl (i.e., —CH₂—O—CH₂—).

The reaction between the linker and the core and conjugated oligomer(s) results in a chemical bond that links the conjugated oligomer(s) to the core. As noted previously, such reactions can occur as a result of a coupling reaction, such as a Suzuki coupling or a Heck coupling, which are well known in the art. In other examples, the linker and the core and/or conjugated oligomer(s) can be attached via a direct nucleophilic or electrophilic interaction between the linker and the core and/or conjugated oligomer(s). For example, a linker comprising a nucleophilic functional group can directly react with an electrophilic substituent on a core and/or conjugated oligomer(s) and form a bond that links the linker to the core and/or conjugated oligomer(s). Alternatively, an electrophilic substituent on the linker can directly react with a nucleophilic functional group on a core and/or conjugated oligomer(s) and form a bond that links the linker to the core and/or conjugated oligomer(s). Also, the core and/or conjugated oligomer(s) can be covalently attached to the linker by an indirect interaction where a reagent initiates, mediates, or facilitates the reaction between the linker and the core and/or conjugated oligomer(s). For example, the bond-forming reaction between the linker and a core and/or conjugated oligomer(s) can be facilitated by the use of a coupling reagent (e.g., carbodiimides, which are used in carbodiimide-mediated couplings) or enzymes (e.g., glutamine transferase).

Suitable linkers are readily commercially available and/or can be synthesized by those of ordinary skill in the art. And the particular linker that can be used in the disclosed composites can be chosen by one of ordinary skill in the art based on factors such as cost, convenience, availability, compatibility with various reaction conditions, the type of core moiety and/or conjugated oligomer(s) with which the linker is to interact, and the like.

Exemplary Materials

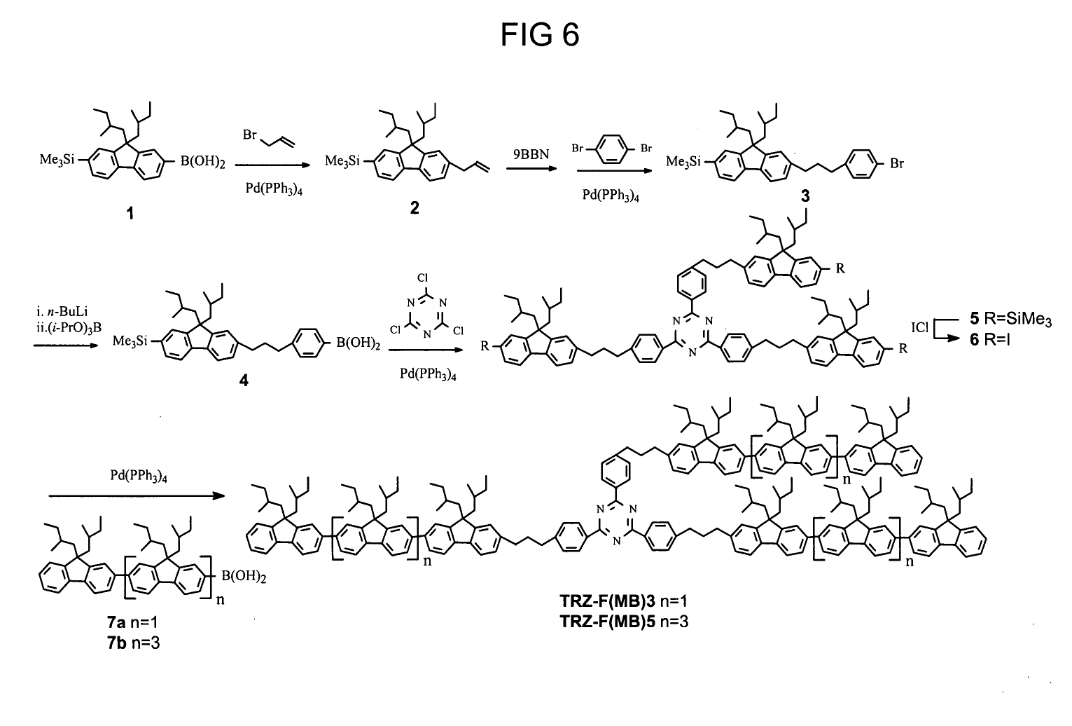

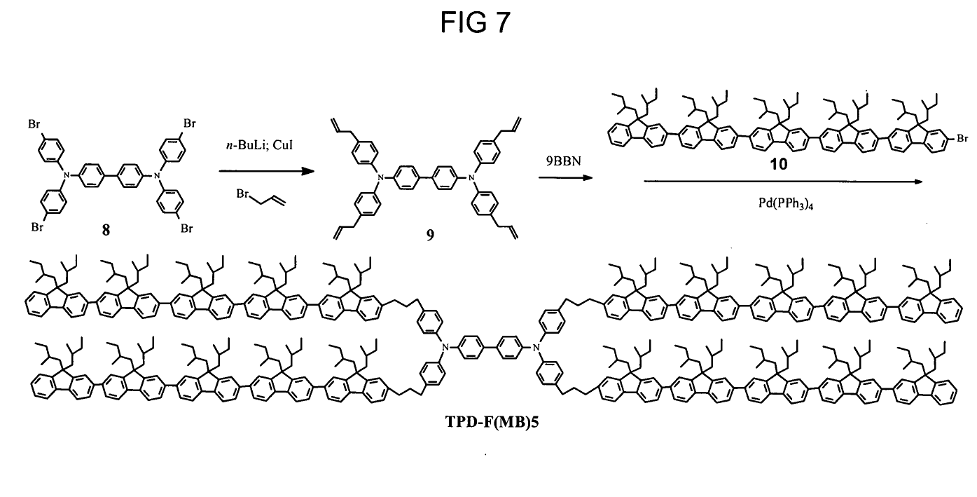

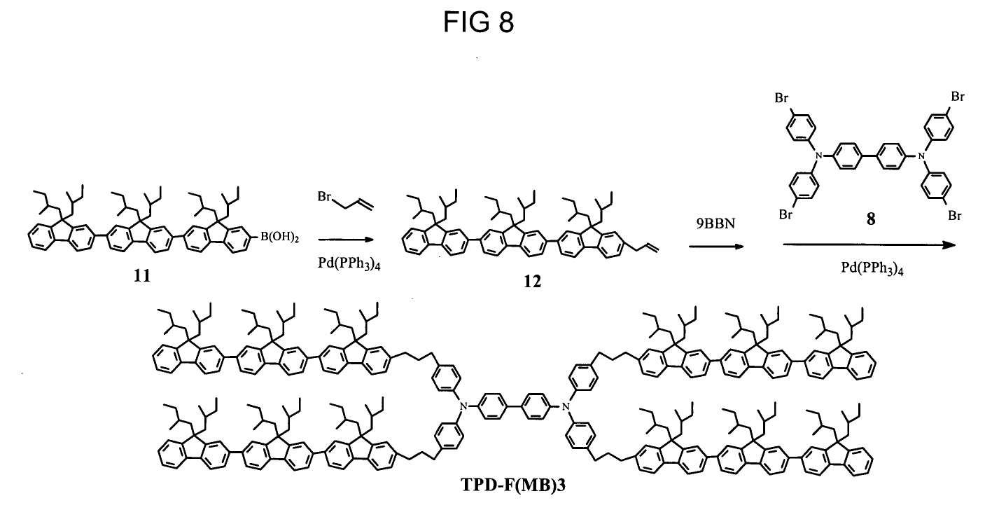

Specific examples of the disclosed materials include light-emitting glassy amorphous and liquid crystalline materials with variable charge injection and transport capabilities. Such compounds have been synthesized following the reaction schemes in FIGS. 6-8 and as set forth in the Examples. Representative light-emitting glassy amorphous and liquid crystalline materials are shown below. The phase transition temperatures for these representative examples were determined by heating scans from differential scanning calorimetry at a heating rate of 20° C./min (G, glassy; Nm, nematic; Sₓ, smectic x; I, isotropic).

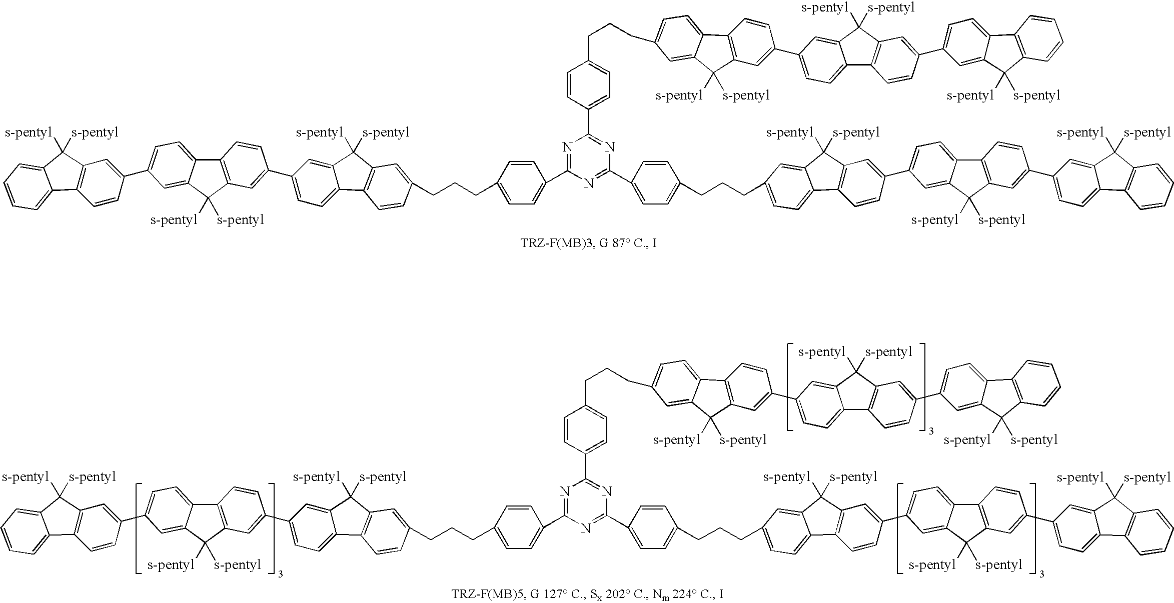

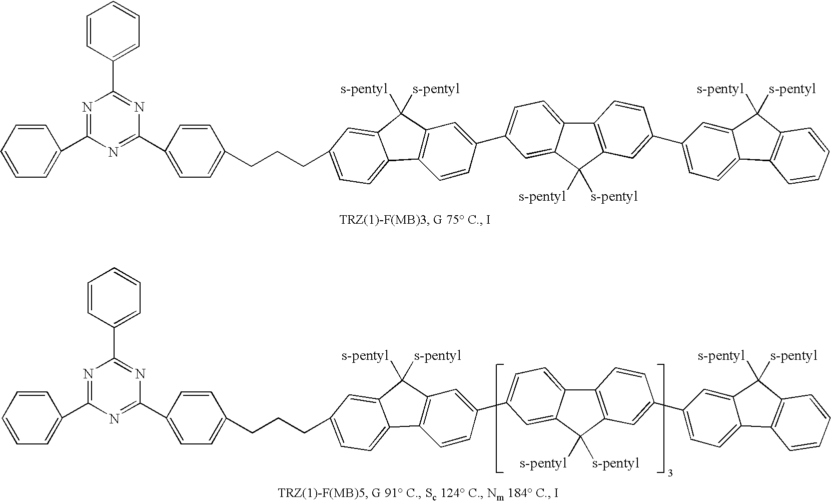

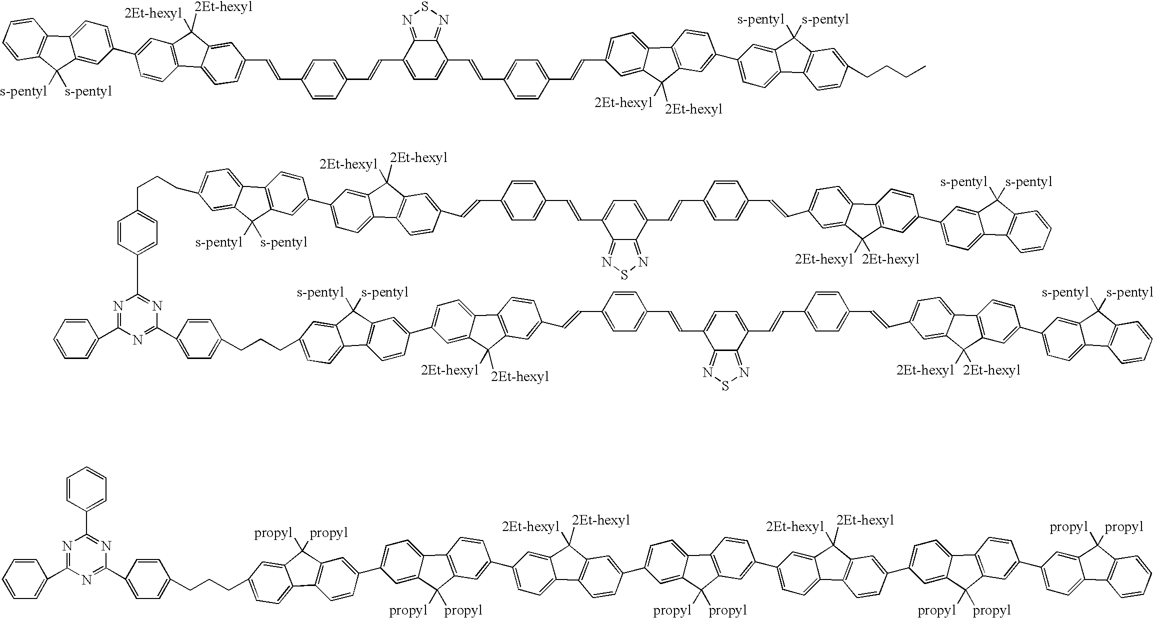

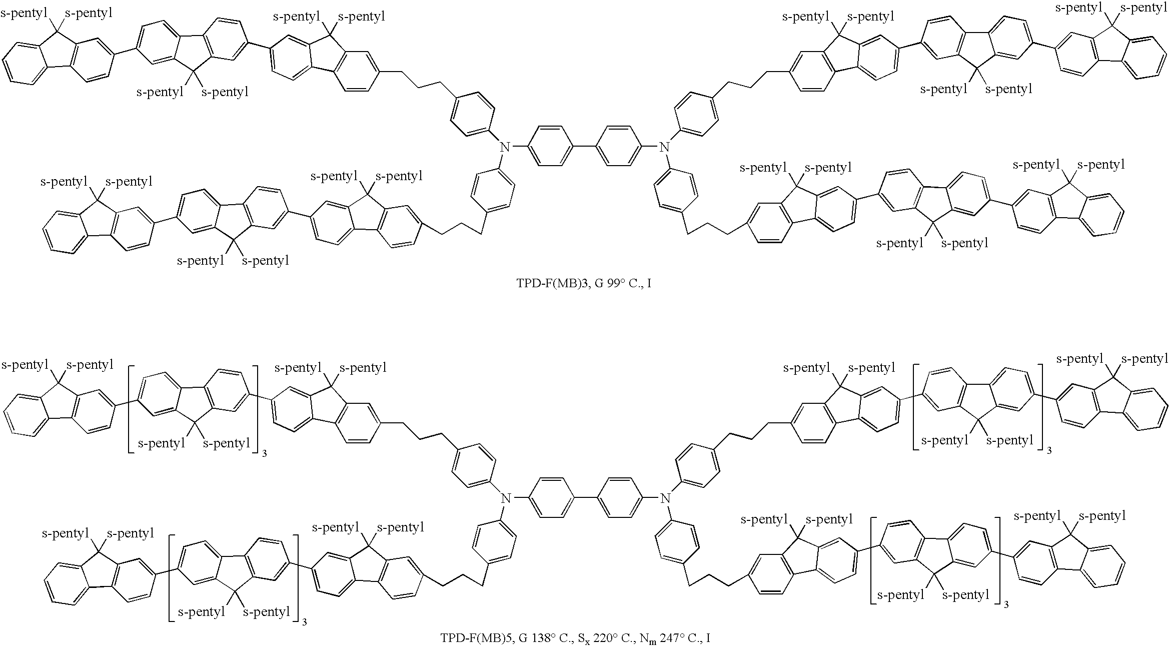

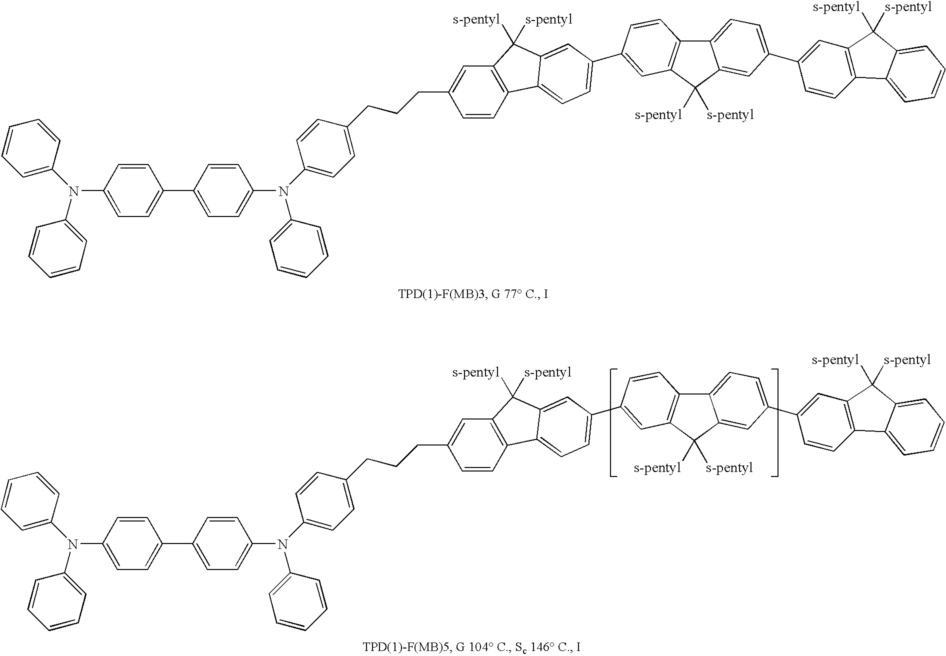

Still further examples of specific materials include the following:

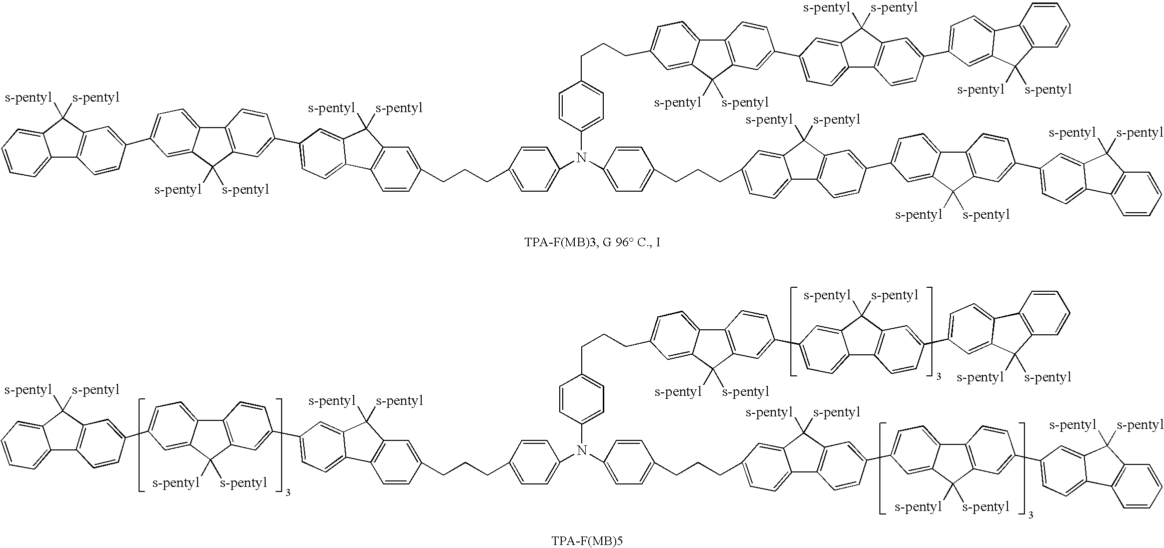

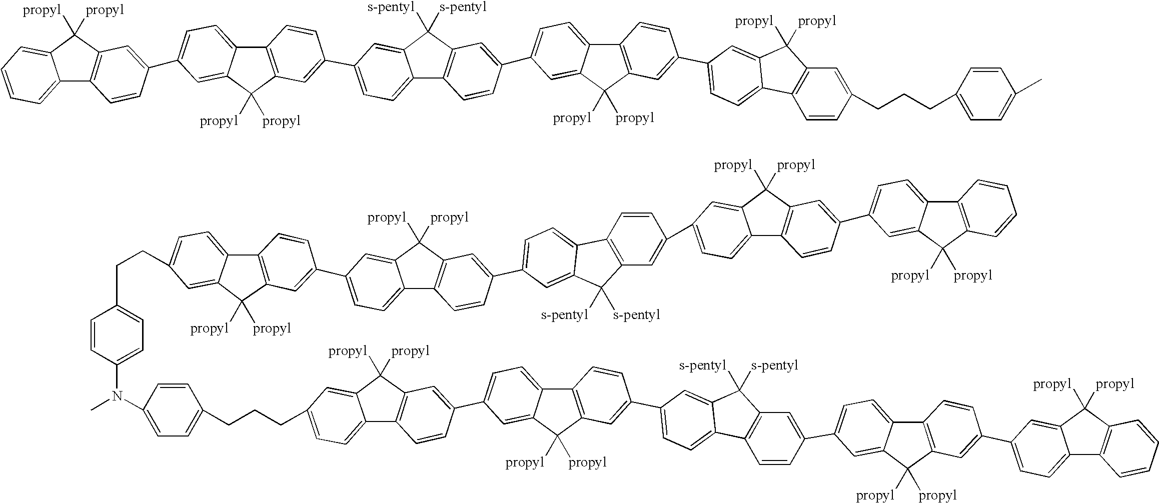

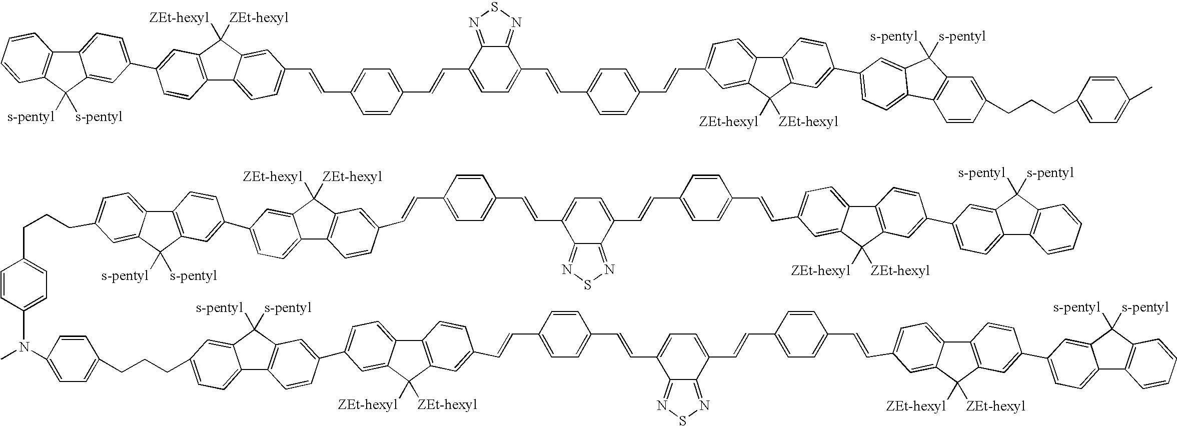

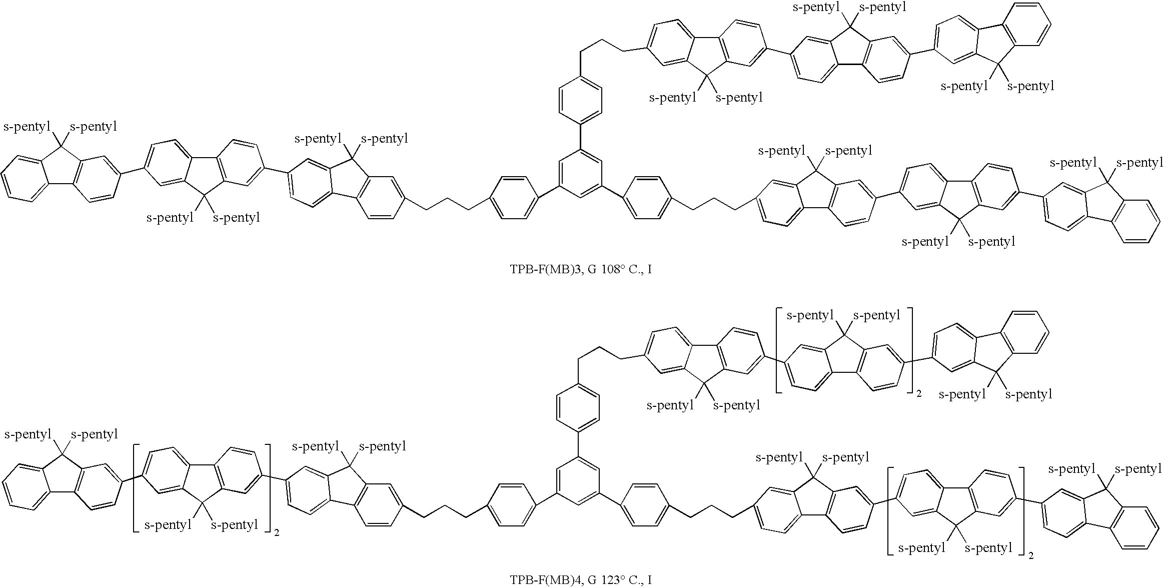

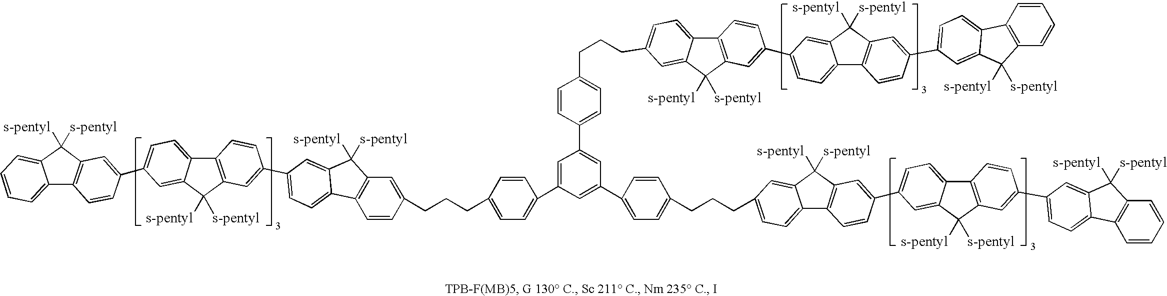

Still further examples are shown below.

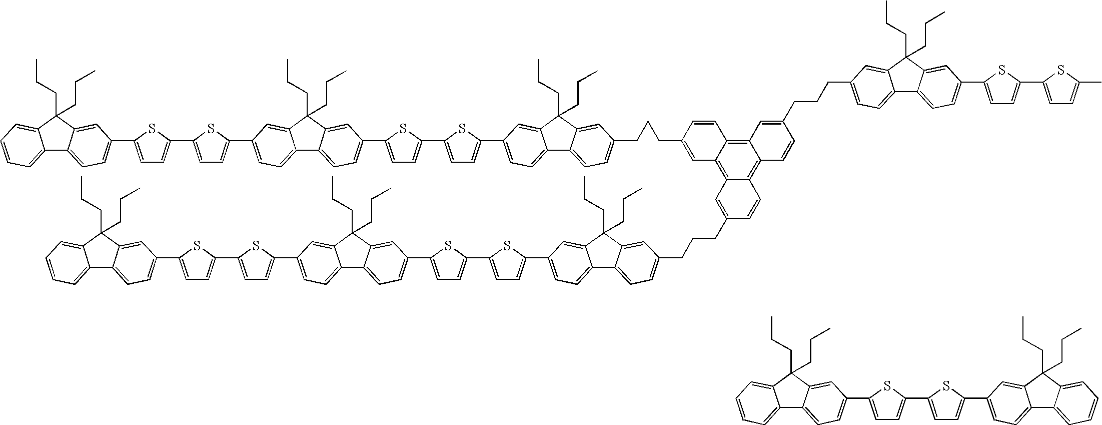

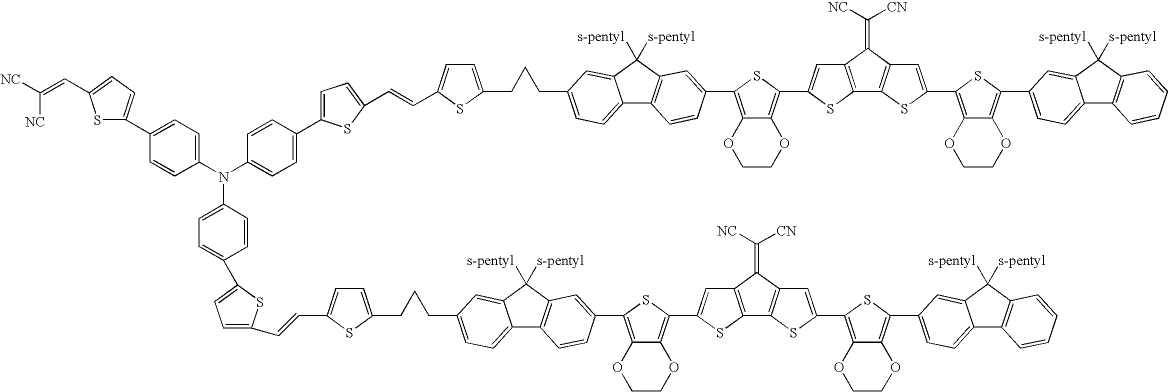

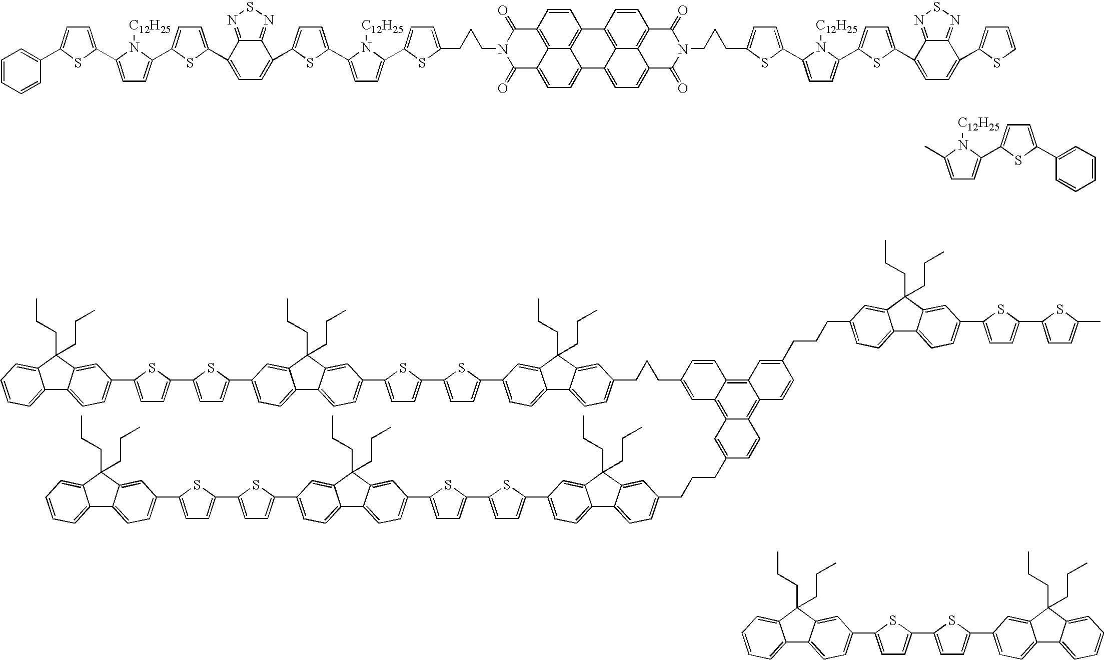

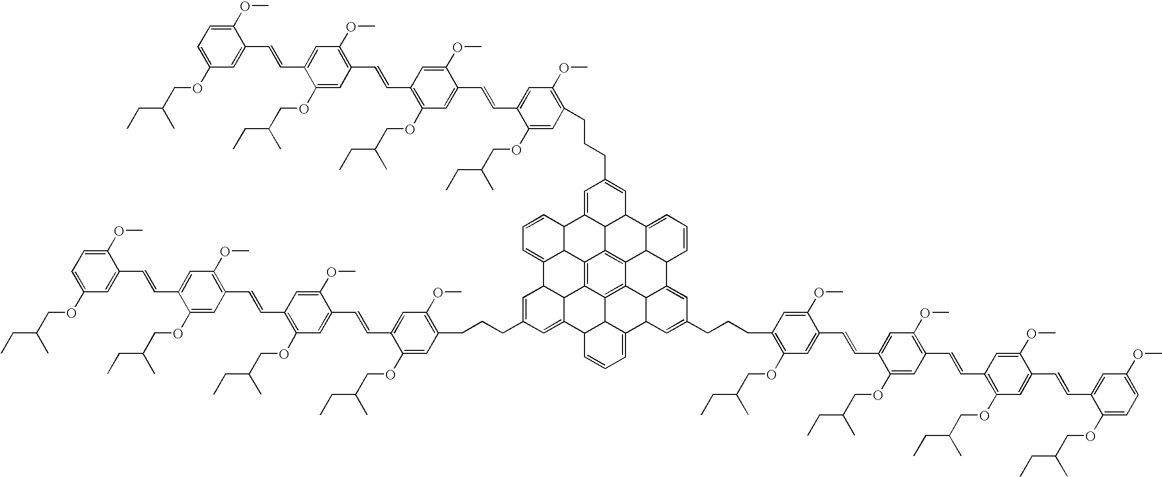

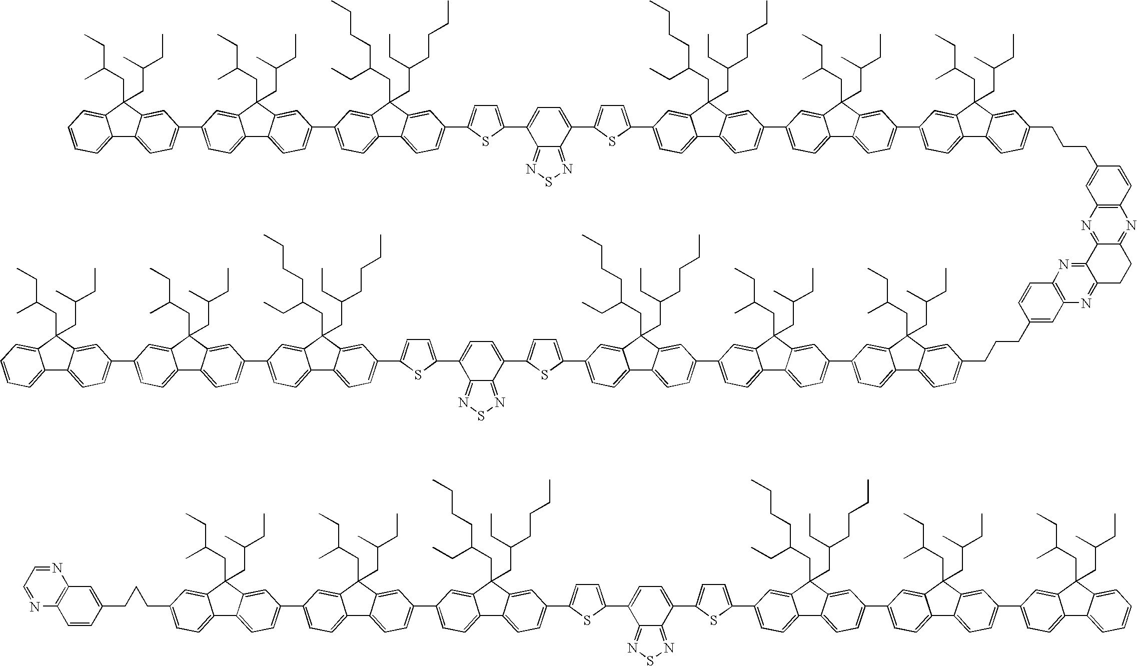

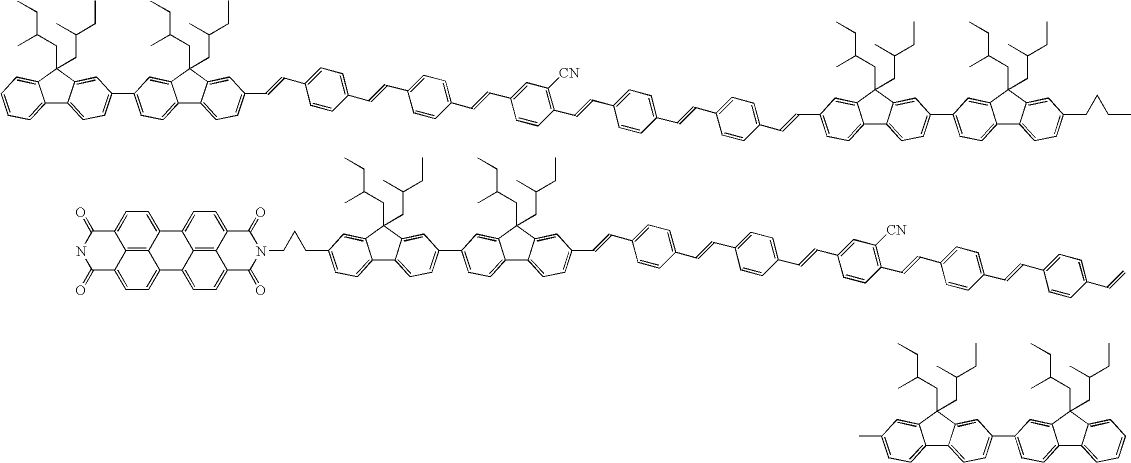

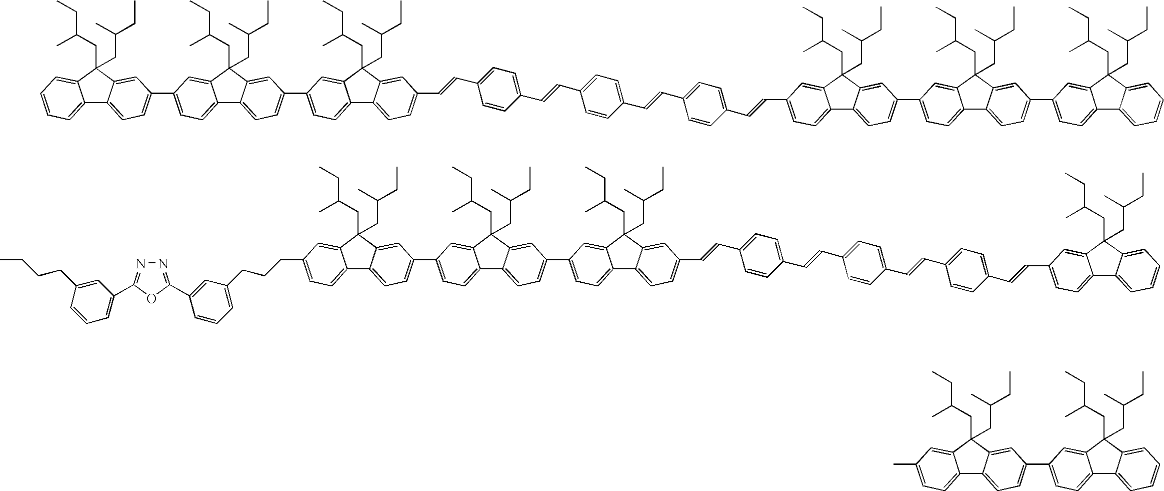

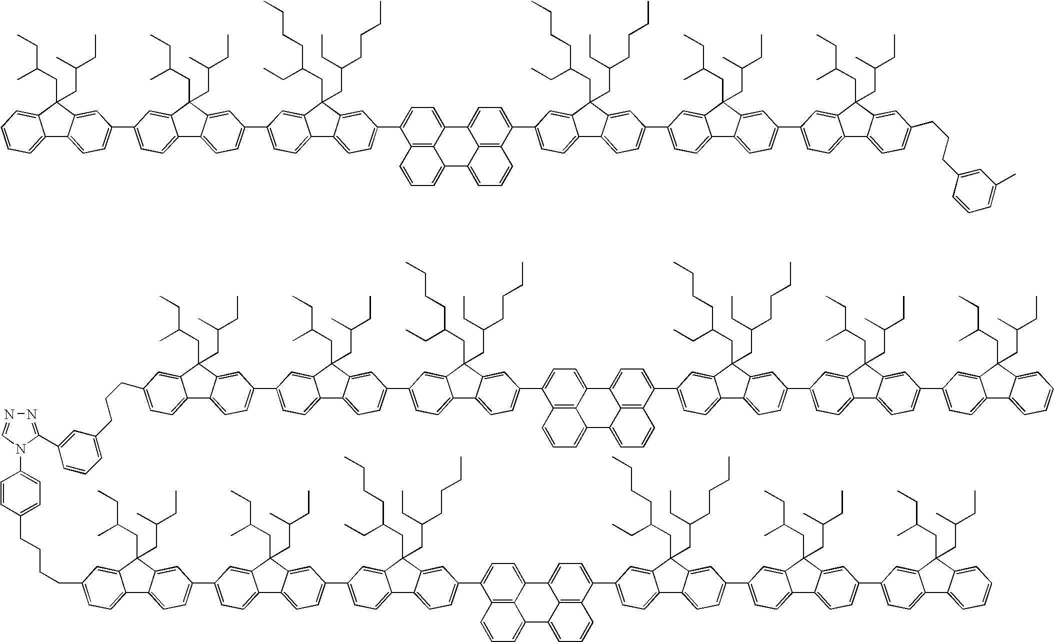

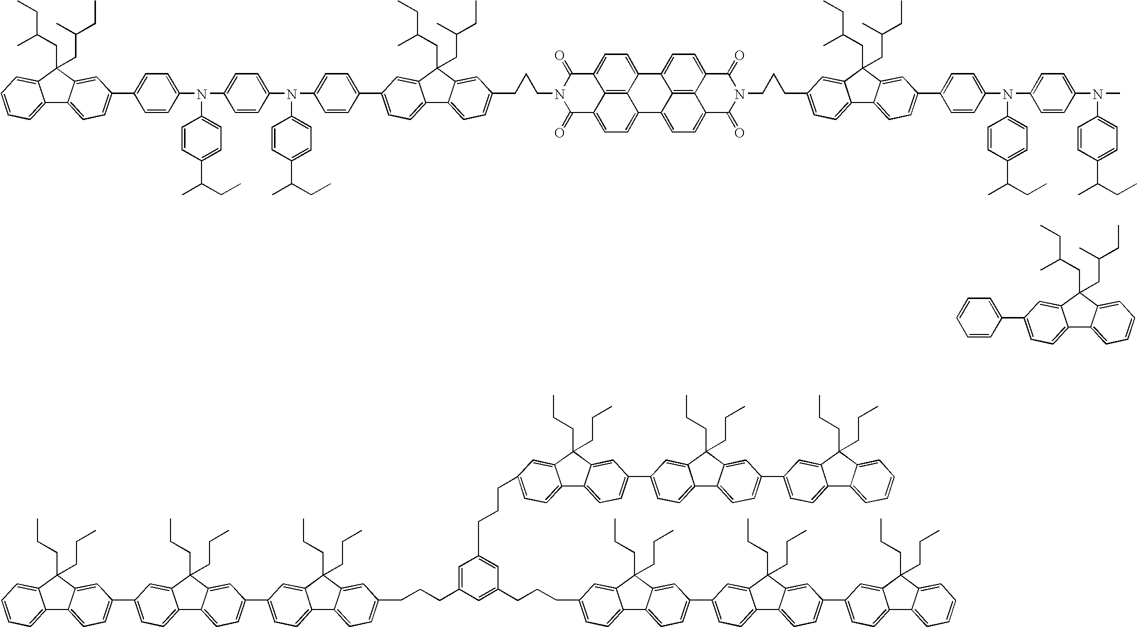

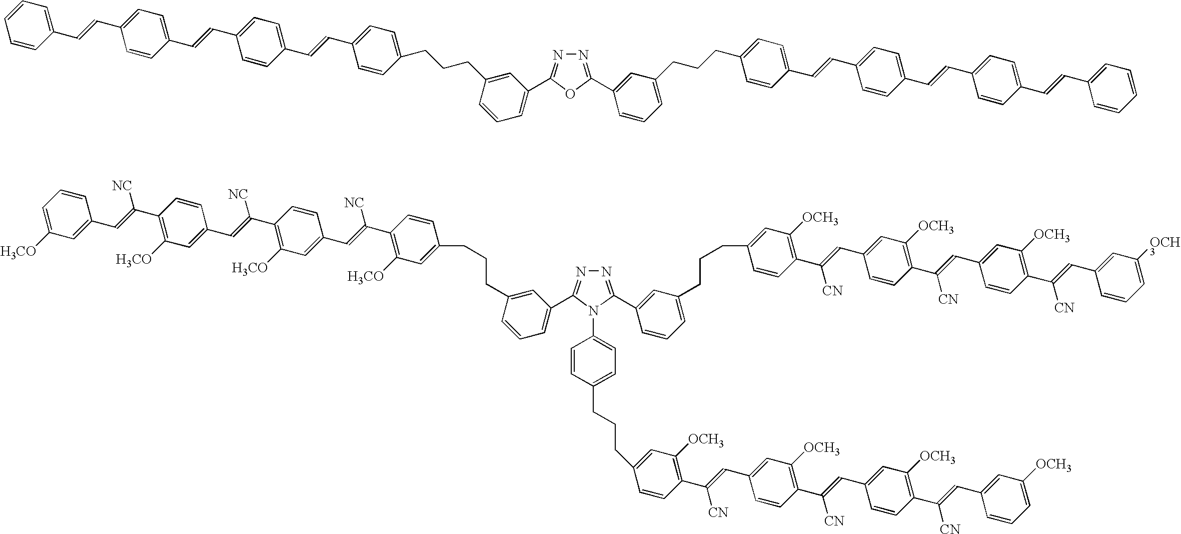

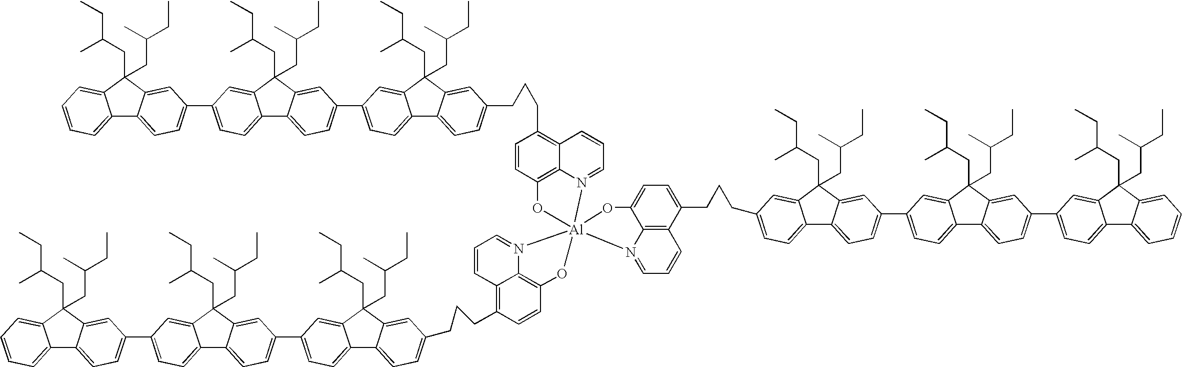

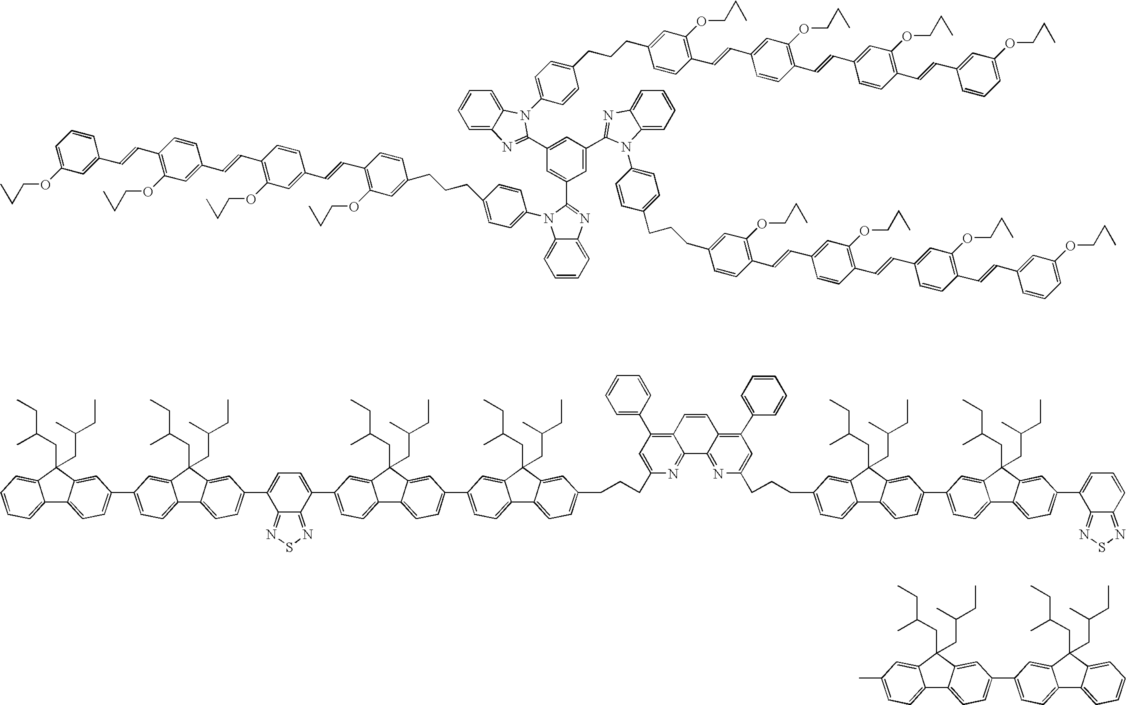

Shown below are phase transition temperatures of terfluorene and pentafluorene as pendants in glassy amorphous and liquid crystalline light-emitting materials shown in above (G, glassy; Nm, nematic; I, isotropic).

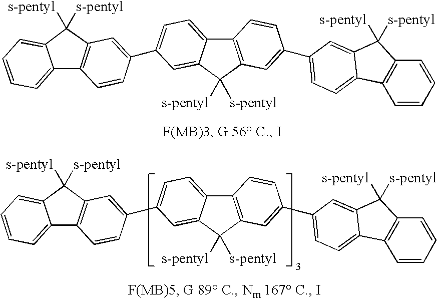

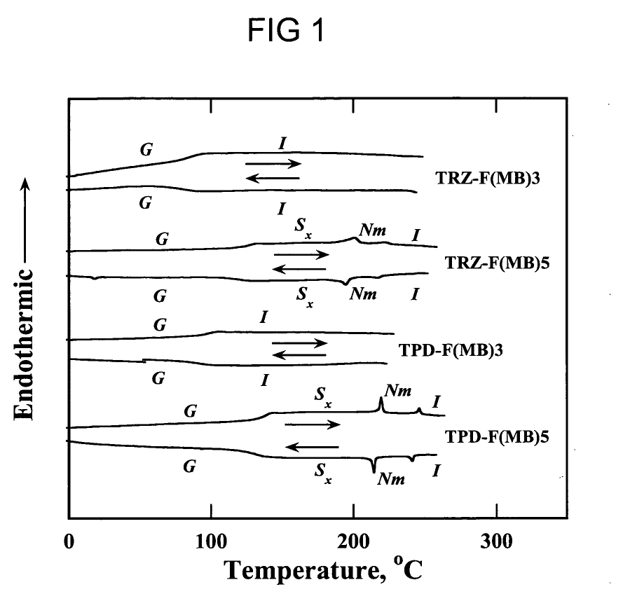

A comparison of the phase transition temperatures indicates that chemical bonding of terfluorene and pentafluorene to a hole-conducting core and an electron-conducting core results in an elevation in T_{g} over 30° C. and in Tᵢ by at least 55° C. in comparison to the stand-alone oligofluorene pendants. The absence of crystalline melting or crystallization in the heating and cooling scans, as shown in FIG. 1, and after extended thermal annealing at temperatures above T_{g} observed by polarizing optical microcopy is evidence of the morphological stability against thermally activated crystallization of the glassy amorphous and liquid crystalline materials disclosed herein.

Methods of Preparation

Certain materials, compounds, compositions, and components disclosed herein can be obtained commercially or readily synthesized using techniques generally known to those of skill in the art. For example, the starting materials and reagents used in preparing the disclosed compounds and compositions are either available from commercial suppliers such as Aldrich Chemical Co., (Milwaukee, Wis.), Acros Organics (Morris Plains, N.J.), Fisher Scientific (Pittsburgh, Pa.), or Sigma (St. Louis, Mo.) or are prepared by methods known to those skilled in the art following procedures set forth in references such as Fieser and Fieser's Reagents for Organic Synthesis, Volumes 1-17 (John Wiley and Sons, 1991); Rodd's Chemistry of Carbon Compounds, Volumes 1-5 and Supplementals (Elsevier Science Publishers, 1989); Organic Reactions, Volumes 1-40 (John Wiley and Sons, 1991); March's Advanced Organic Chemistry, (John Wiley and Sons, 4th Edition); and Larock's Comprehensive Organic Transformations (VCH Publishers Inc., 1989).

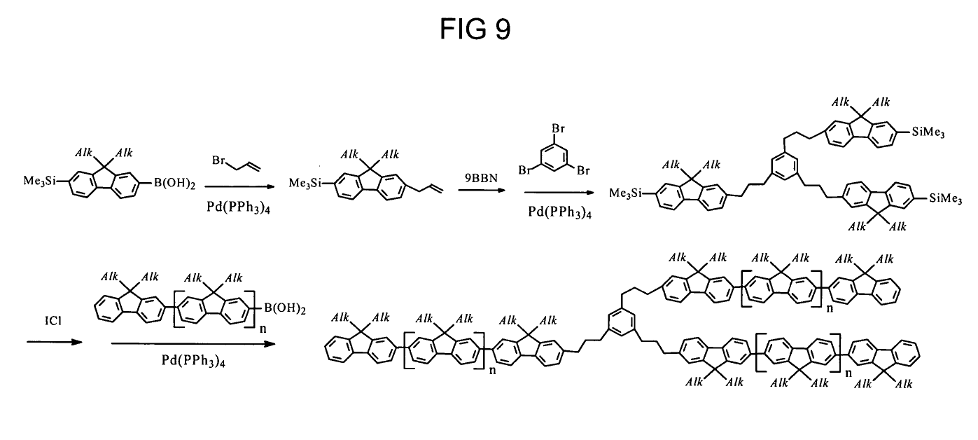

The synthesis of light-emitting glassy liquid crystalline and amorphous materials with an electron-conducting, a hole-conducting, and a non-conducting core can be accomplished following the reaction schemes in FIGS. 6 through 9.

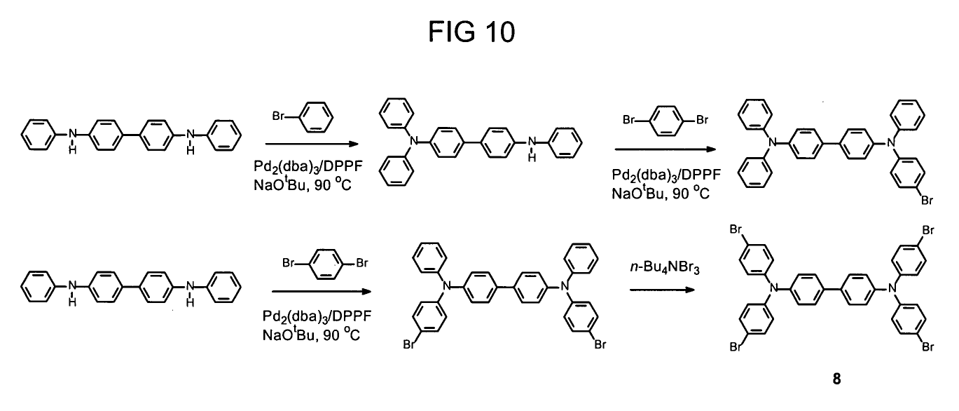

Moreover, the synthesis of a hole-conducting core accepting a variable number of light-emitting pendants can be performed following the reaction scheme in FIG. 10, in which one to four pendants to the core can result in a core content ranging from 20 to 50 mole % in glassy amorphous (n=1) and liquid crystalline (n=3) light-emitting materials.

Devices

The disclosed organic light-emitting materials can be used in organic light emitting devices or diodes (OLEDs), e.g., in display applications or as backlight of, e.g., liquid crystal displays. As such disclosed herein, in a further aspect, are OLEDs comprising the materials disclosed herein. For example, and OLED can comprise one or more emission regions generally sandwiched between a cathode and an anode. Also present in an OLED can be one or more charge transport regions (e.g., either an electron- or hole-transport region or both). By applying an electric voltage electrons and holes as charge carriers move towards the emission region where their recombination leads to the excitation and hence luminescence of the lumophor units contained in the emission region. The disclosed materials can be employed in one or more of the charge transport layers and/or in the emission region, corresponding to their electrical and/or optical properties.

The OLEDs can be fabricated by sequentially forming the desired layers on a suitable substrate using any suitable thin film forming technique. For example, spin coating or deposition can be used. Specific methods for fabrication and operation of OLEDs is disclosed in, for example, U.S. Pat. Nos. 4,539,507 and 4,769,292, and U.S. Published application Nos. 2004/0018383, 2004/0144974, 2004/0031958, 2004/0263071, and 2005/011005, which are incorporated by reference herein at least for their teachings of OLED production.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention which are apparent to one skilled in the art.

Efforts have been made to ensure accuracy with respect to numbers (e.g., amounts, temperature, etc.) but some errors and deviations should be accounted for. Unless indicated otherwise, parts are parts by weight, temperature is in ° C. or is at ambient temperature, and pressure is at or near atmospheric. There are numerous variations and combinations of reaction conditions, e.g., component concentrations, temperatures, pressures and other reaction ranges and conditions that can be used to optimize the product purity and yield obtained from the described process. Only reasonable and routine experimentation will be required to optimize such process conditions.

### Example 1

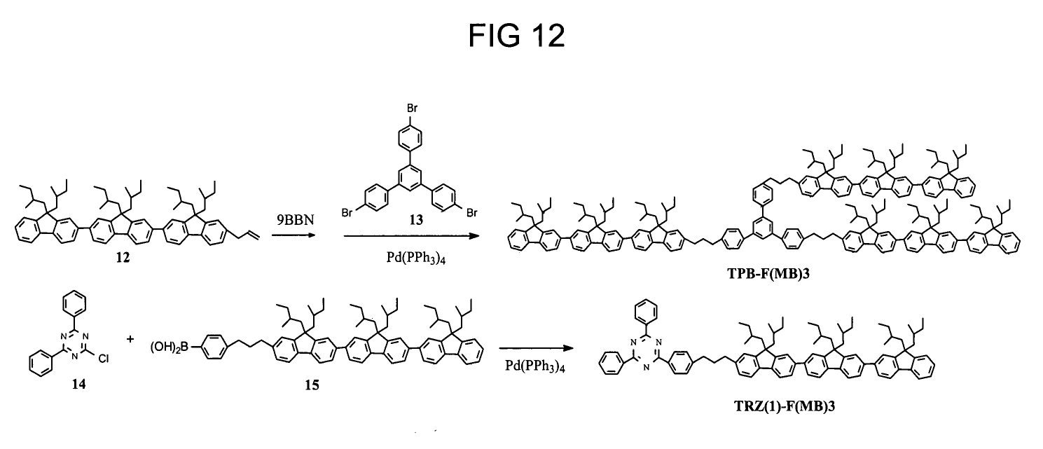

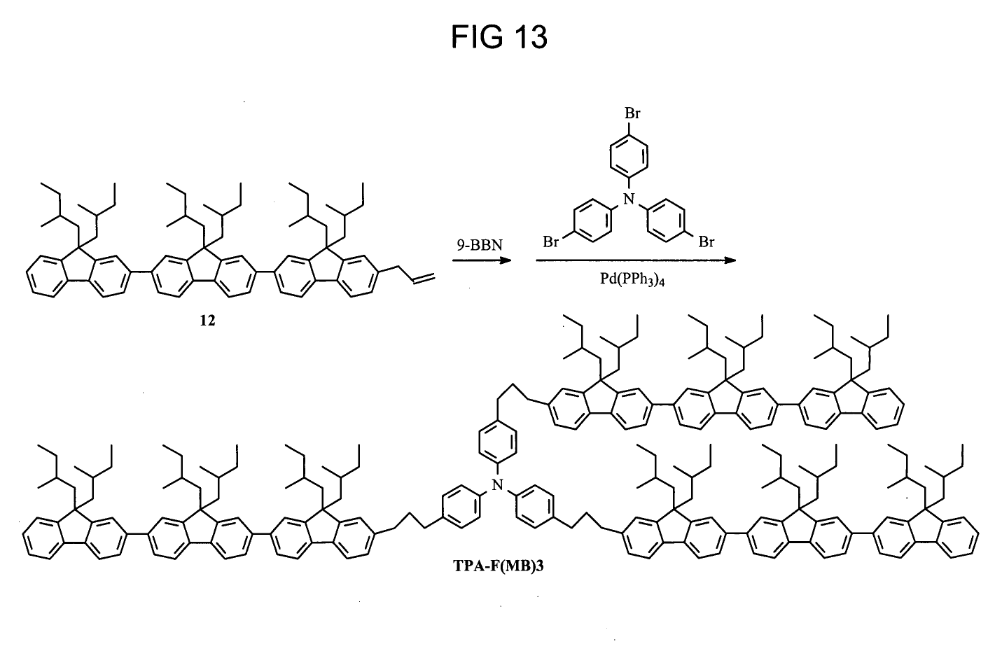

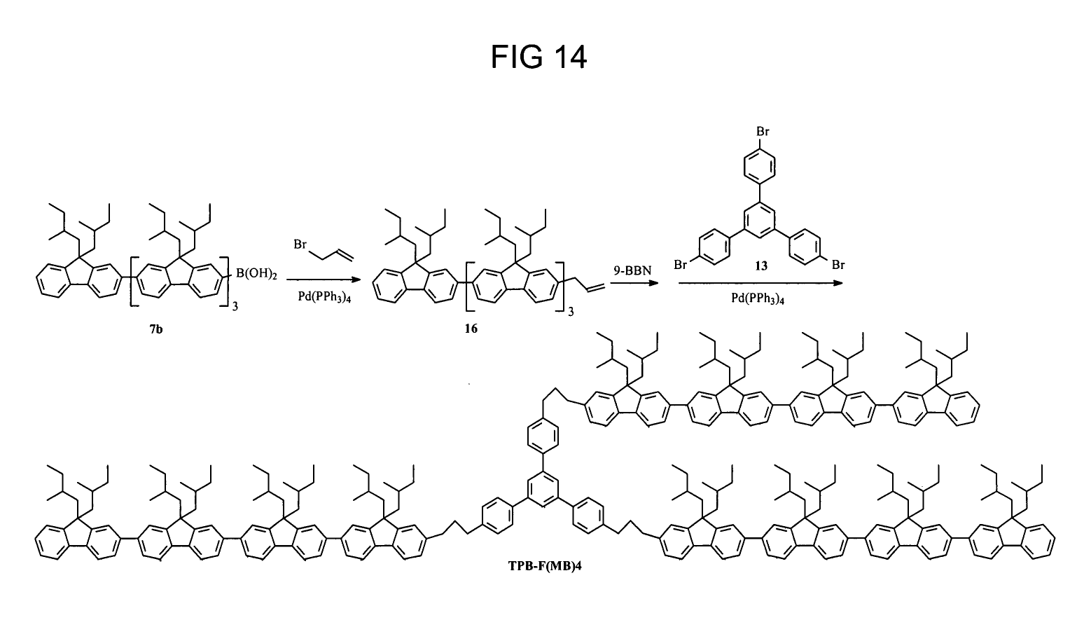

### Material Synthesis and Purification Procedures (Referring to Reaction Schemes in FIGS. 6, 7, 8, 12, 13, and 14)

All chemicals, reagents, and solvents were used as received from commercial sources without further purification except tetrahydrofuran (THF) and toluene that had been distilled over sodium/benzophenone. Synthesis of intermediates 1, 7a, 7b, 8, 9, 10, 11, 13, and 14 has been reported previously (Geng et al., Chem. Mater. 2003, 15:542-549; Huang et al., J. Am. Chem. Soc. 2003, 125:14704-14705; U.S. Pat. No. 5,438,138; and Fink et al., Chem. Mater. 1998, 10:3620-3625).

2-Allyl-7-trimethylsilyl-9,9-bis(2-methylbutyl)fluorene, 2. Into a mixture of 1 (4.20 g, 9.94 mmol), allyl bromide (1.80 g, 14.9 mmol), K₂CO₃ (2.76 g, 20.0 mmol) and Pd(PPh₃)₄ (0.15 g, 0.13 mmol) were added toluene (20 ml) and H₂O (10 ml). The reaction mixture was stirred at 90° C. for 1 day and then cooled to room temperature before adding hexane (30 ml). The organic layer was separated and washed with brine before drying over anhydrous MgSO₄. Upon evaporating off the solvent, the residue was purified with column chromatography on silica gel with hexanes as the eluent to yield 2 (3.78 g, 90%) as colorless oil. ¹H-NMR (400 MHz, CDCl₃): δ (ppm) 7.65 (t, 2H), 7.47-7.54 (m, 2H), 7.14-7.28 (m, 2H), 6.00-6.10 (m, 1H), 5.06-5.09 (m, 2H), 3.47 (d, 2H), 2.08-2.13 (m, 2H), 1.84-1.89 (m, 2H), 0.82-0.93 (m, 4H), 0.56-0.61 (m, 8H), 0.24-0.31 (m, 15H).

4-Bromo-1-(3-(2-trimethylsilyl-9,9-bis(2-methylbutyl)fluoren-7-yl)propyl)-benzene, 3. Into a solution of 2 (3.78 g, 9.03 mmol) in anhydrous THF (2 ml) was added 9-BBN (0.5 M in THF, 18.2 ml, 9.10 mmol) at 0° C. The reaction mixture was stirred at room temperature for 30 min, and then heated to 40° C. for 1 day. Upon cooling to room temperature, it was added to a mixture of 1,4-dibromobenzene (3.53 g, 15.0 mmol) in THF (10 ml), Pd(PPh₃)₄ (0.15 g, 0.13 mmol), and 2.0 M aqueous solution of K₂CO₃ (5.0 ml, 10.0 mmol). The reaction mixture was stirred at 90° C. for 2 days and cooled to room temperature before adding hexanes (30 ml). The organic layer was separated and washed with brine before drying over anhydrous MgSO₄. Upon evaporating off the solvent, the residue was purified with column chromatography on silica gel with hexanes as the eluent to yield 3 (3.62 g, 70%) as colorless oil. ¹H-NMR (400 MHz, CDCl₃): δ (ppm) 7.62-7.67 (m, 2H), 7.41-7.54 (m, 4H), 7.06-7.22 (m, 4H), 2.73 (t, 2H), 2.61 (t, 2H), 1.95-2.11 (m, 2H), 1.95-1.99 (m, 2H), 1.87-1.90 (m, 2H), 0.82-0.93 (m, 4H), 0.57-0.61 (m, 8H), 0.25-0.31 (m, 15H).

(3-(2-Trimethylsilyl-9,9-bis(2-methylbutyl)fluoren-7-yl)propyl)phen-4-yl-boronic acid, 4. Into a solution of 3 (1.51 g, 2.62 mmol) in anhydrous THF was added n-butyl lithium (n-BuLi) (2.5 M in hexane, 1.10 ml, 2.75 mmol) at −78°. The reaction mixture was stirred at −78° C. for 4 h before triisopropyl borate (1.60 g, 8.51 mmol) was added in one portion. The mixture was warmed to room temperature slowly, stirred overnight, and then quenched with HCl (2.0 M, 15 ml) before adding a large amount of water for extraction with ethyl ether. The organic layer was separated and washed with brine before drying over anhydrous MgSO₄. Upon evaporating off the solvent, the residue was purified with column chromatography on silica gel with hexanes:ethyl acetate (4:1) as the eluent to yield 4 (1.12 g, 70%) as colorless powder. ¹H-NMR (400 MHz, CDCl₃): δ (ppm) 8.18 (d, 2H), 7.64-7.69 (m, 2H), 7.47-7.54 (m, 2H), 7.34 (d, 2H), 7.16-7.33 (m, 2H), 2.73-2.79 (m, 4H), 2.61 (t, 2H), 2.04-2.12 (m, 4H), 1.86-1.90 (m, 2H), 0.82-0.93 (m, 4H), 0.58-0.60 (m, 8H), 0.25-0.32 (m, 15H).

2,4,6-Tris [p-(3-(2-trimethylsilyl-9,9-bis(2-methylbutyl)fluoren-7-yl)propyl)phenyl]-triazine, 5. Into a mixture of 4 (3.90 g, 7.21 mmol), cyanuric chloride (0.40 g, 2.2 mmol), Pd(PPh₃)₄ (0.13 g, 0.11 mmol), and Na₂CO₃ (1.80 g, 17.0 mmol) were added toluene (2 ml) and H₂O (0.5 ml). The reaction mixture was stirred at 90° C. for 3 days. Upon cooling to room temperature, methylene chloride (30 ml) was added to the reaction mixture. The organic layer was separated and washed with brine before drying over anhydrous MgSO₄. Upon evaporating off the solvent, the residue was purified with column chromatography on silica gel with hexanes:methylene chloride (2:1) as the eluent to yield 5 (1.98 g, 58%) as a white solid. ¹H-NMR (400 MHz, CDCl₃): δ (ppm) 8.70 (d, 6H), 7.67 (t, 6H), 7.47-7.50 (m, 6H), 7.39 (d, 6H), 7.17-7.23 (m, 6H), 2.78 (t, 12H), 2.07-2.16 (m, 12H), 1.87-1.90 (m, 6H), 0.81-0.94 (m, 12H), 0.56-0.62 (m, 24H), 0.24-0.31 (m, 45H).

2,4,6-Tris[p-(3-(2-iodo-9,9-bis(2-methylbutyl)fluoren-7-yl)propyl)phenyl]-triazine, 6. Into a solution of 5 (0.53 g, 0.34 mmol) in CCl₄ (10 ml) was added ICl (1.0 M in methylene chloride, 1.50 ml, 1.50 mmol) dropwise at 0° C. After stirring at room temperature for 1 h, an aqueous solution of Na₂S₂O₃ (10 wt %, 30 ml) was poured into the reaction mixture with vigorous stirring until discoloration for extraction with methylene chloride (15 ml). The organic layer was separated and washed with brine before drying over anhydrous MgSO₄. Upon evaporating off the solvent, the residue was purified with column chromatography on silica gel with hexanes:methylene chloride (2:1) as the eluent to yield a white solid (0.40 g, 68%). ¹H-NMR (400 MHz, CDCl₃): δ (ppm) 8.70 (d, 6H), 7.60-7.73 (m, 9H), 7.44 (d, 3H), 7.38 (d, 6H), 7.17-7.20 (m, 6H), 2.78 (t, 12H), 2.03-2.09 (m, 12H), 1.81-1.86 (m, 6H), 0.82-0.93 (m, 12H), 0.57-0.65 (m, 24H), 0.25-0.34 (m, 18H).

2,4,6-Tris[p-(3-(ter(9,9-bis(2-methylbutyl)fluoren-7-yl))propyl)phenyl]-triazine, TRZ-F(MB)3. Into the mixture of 6 (0.40 g, 0.23 mmol), 7a (0.90 g, 1.4 mmol), Pd(PPh₃)₄ (20 mg, 0.020 mmol), and Na₂CO₃ (0.29 g, 2.7 mmol) were added toluene (2 ml) and H₂O (0.5 ml). The reaction mixture was stirred at 90° C. for 2 days. Upon cooling to room temperature, methylene chloride (30 ml) was added to the reaction mixture. The organic layer was separated and washed with brine before drying over anhydrous MgSO₄. Upon evaporating off the solvent, the residue was purified with column chromatography on silica gel with hexanes:methylene chloride (2:1) as the eluent to yield TRZ-F(MB)3 (0.45 g, 62%) as a white solid. ¹H-NMR (400 MHz, CDCl₃): δ (ppm) 8.73 (d, 6H), 7.75-7.83 (m, 15H), 7.62-7.70 (m, 27H), 7.35-7.43 (m, 15H), 7.21-7.27 (m, 6H), 2.82 (t, 12H), 2.10-2.25 (m, 24H), 1.94-1.98 (m, 18H), 0.61-1.01 (m, 108H), 0.34-0.40 (m, 54H). Molecular weight calcd for C₂₃₇H₂₈₅N₃: 3175.9. MALD/I TOF MS (DCTB) m/z ([M]⁺): 3173. Anal. Calcd. for C₂₃₇H₂₈₅N₃: C, 89.63; H, 9.05; N, 1.32. Found: C, 89.53; H, 9.00; N, 1.37.

2,4,6-Tris[p-(3-(penta(9,9-bis(2-methylbutyl)fluoren-7-yl))propyl)phenyl]-triazine, TRZ-F(MB)5. The procedure for the synthesis of TRZ-F(MB)3 was followed to prepare TRZ-F(MB)5 from 6 and 7b as a white solid in a 43% yield (70 mg). ¹H-NMR (400 MHz, CDCl₃): δ (ppm) 8.73 (d, 6H), 7.36-7.86 (m, 84H), 7.31-7.43 (m, 15H), 7.21-7.23 (m, 6H), 2.82 (t, 12H), 2.11-2.27 (m, 36H), 1.93-1.97 (m, 30H), 0.63-1.01 (m, 180H), 0.34-0.43 (m, 90H). Molecular weight calcd for C₃₇₅H₄₅₃N₃: 5002.7. MALD/I TOF MS (DCTB) m/z ([M]⁺): 5002. Anal. Calcd. for C₃₇₅H₄₅₃N₃: C, 90.03; H, 9.13; N, 0.84. Found: C, 89.89; H, 8.84; N, 0.74.

N,N,N′,N′-Tetrakis [p-(3-(penta(9,9-bis(2-methylbutyl)fluoren-7-yl))propyl)phenyl]-biphenyl-4,4′-diamine, TPD-F(MB)5. Into a solution of 9 (92 mg, 0.14 mmol) in anhydrous THF (1 ml) was added 9-BBN (0.5 M in THF, 1.25 ml, 0.625 mmol) at 0° C. The reaction mixture was stirred at room temperature for 30 min, and then heated to 40° C. for 1 day. Upon cooling to room temperature, it was added to a mixture of 10 (1.0 g, 0.57 mmol) in THF (3 ml), Pd(PPh₃)₄ (7 mg, 0.006 mmol), and a 2.0 M aqueous solution of K₂CO₃ (2 ml, 4.0 mmol). The reaction mixture was stirred at 90° C. for 2 days. Upon cooling to room temperature, methylene chloride (30 ml) was added. The organic layer was separated and washed with brine before drying over anhydrous MgSO₄. After evaporating off the solvent, the residue was purified with column chromatography on silica gel with hexanes:methylene chloride (2:1) as the eluent to yield TPD-F(MB)5 as a white solid (100 mg, 10%). ¹H-NMR (400 MHz, CDCl₃): δ (ppm) 7.76-7.85 (m, 40H), 7.62-7.68 (m, 64H), 7.31-7.45 (m, 20H), 7.10-7.25 (m, 28H), 2.80 (t, 8H), 2.65 (s, 8H) 2.13-2.27 (m, 48H), 1.91-2.02 (m, 40H), 0.62-1.01 (m, 240H), 0.34-0.40 (m, 120H). Molecular weight calcd for C₅₀₈H₆₁₂N₂: 6746.5. MALD/I TOF MS (DCTB) m/z ([M]⁺): 6746. Anal. Calcd. for C₅₀₈H₆₁₂N₂: C, 90.44; H, 9.14; N, 0.42. Found: C, 90.37; H, 9.09; N, 0.39.

2-Allyl-ter(9,9-bis(2-methylbutyl))fluorene, 12. The procedure for the synthesis of 2 was followed to prepare 12 from 11 as a white solid in a 87% yield (0.61 g). ¹H-NMR (400 MHz, CDCl₃): δ (ppm) 7.84-7.61 (m, 5H), 7.60-7.69 (m, 9H), 7.32-7.43 (m, 3H), 7.18-7.23 (m, 2H), 6.00-6.10 (m, 1H), 5.09 (d, 2H), 3.49 (d, 2H), 2.14-2.29 (m, 6H), 1.88-1.98 (m, 6H), 0.60-0.99 (m, 36H), 0.36-0.42 (m, 18H).

N,N,N′,N′-Tetrakis[p-(3-(ter(9,9-bis(2-methylbutyl)fluoren-7-yl))propyl)phenyl]-biphenyl-4,4′-diamine,TPD-F(MB)3. Into a solution of 12 (0.55 g, 0.58 mmol) in anhydrous THF (1 ml) was added 9-BBN (0.5 M in THF, 1.21 ml, 0.61 mmol) at OC. The reaction mixture was stirred at room temperature for 30 min, and then heated to 40° C. for 1 day. Upon cooling to room temperature, it was added to a mixture of 8 (93 mg, 0.12 mmol) in THF (3 ml), Pd(PPh₃)₄ (6.5 mg, 0.0058 mmol), and a 2.0 M aqueous solution of K₂CO₃ (2 ml, 4 mmol). The reaction mixture was stirred at 90° C. for 2 days. Upon cooling to room temperature, methylene chloride (30 ml) was added to the reaction mixture. The organic layer was separated and washed with brine before drying over MgSO₄. After evaporating off the solvent, the residue was purified with column chromatography on silica gel with hexanes:methylene chloride (2:1) as the eluent to yield TPD-F(MB)3 (0.29 g, 58%) as a white solid. ¹H-NMR (400 MHz, CDCl₃): δ (ppm) 7.76-7.84 (m, 20H), 7.62-7.70 (m, 36H), 7.31-7.41 (m, 16H), 7.10-7.25 (m, 28H), 2.80 (t, 8H), 2.65 (s, 8H) 2.16-2.25 (m, 32H), 1.91-2.04 (m, 24H), 0.65-1.01 (m, 144H), 0.34-0.40 (m, 72H). Molecular weight calcd for C₃₂₄H₃₈₈N₂: 4310.7. Anal. calcd. for C₃₂₄H₃₈₈N₂: C, 90.28; H, 9.07; N, 0.65. Found: C, 90.25; H, 9.10; N, 0.63.

Ter[9,9-bis(2-methylbutyl)fluorene], F(MB)3. ¹H-NMR (400 MHz, CDCl₃): δ (ppm) 7.76-7.84 (m, 5H), 7.62-7.69 (m, 9H), 7.28-7.55 (m, 6H), 2.13-2.25 (m, 6H), 1.89 2.00 (m, 6H), 0.63-0.91 (m, 36H), 0.34-0.39 (m, 18H). Molecular weight calcd for C₆₉H₈₆: 915.4. MALDI/TOF MS (DCTB) m/z [M]⁺): 914.7. Anal. calcd. for C₆₉H₈₆: C, 90.53; H, 9.47. Found: C, 90.42; H, 9.60.

Penta[9,9-bis(2-methylbutyl)fluorene], F(MB)5. ¹H-NMR (400 MHz, CDCl₃): δ (ppm) 7.82-7.87 (m, 6H), 7.82 (d, J=8.10 Hz, 2H), 7.77 (d, J=7.35 Hz, 2H), 7.62-2.74 (m, 16H), 7.30-7.48 (m, 6H), 2.17-2.31 (m, 10H), 1.90-2.01 (m, 10H), 0.55-1.10 (m, 60H), 0.32-0.43 (m, 30H). Molecular weight calcd for C₁₁₅H₁₄₂: 1524.4. MALDI/TOF MS (DCTB) m/z [M]⁺): 1524.1. Anal. calcd. for C₁₁₅H₁₄₂: C, 90.61; H, 9.39. Found: C, 90.56; H, 9.31.

(3-(ter(9,9-bis(2-methylbutyl)fluoren-7-yl))propyl)phen-4-yl-boronic acid, 15. The procedure for the synthesis of 4 was followed to prepare 15 from 12 as a white solid in a 75% yield (0.47 g). ¹H-NMR (400 MHz, CDCl₃): δ (ppm) 8.20 (d, 2H), 7.65-7.86 (m, 14H), 7.28-7.38 (m, 5H), 7.16-7.28 (m, 2H), 2.73-2.85 (m, 4H), 1.88-2.29 (m, 14H), 0.60-0.99 (m, 36H), 0.36-0.42 (m, 18H).

1,3,5-Tris[p-3-(ter(9,9-bis(2-methylbutyl)fluoren-7-yl)propyl)-phenyl)]benzene, TPB-F(MB)3. The procedure for the synthesis of TPD-F(MB)3 was followed to prepare TPB-F(MB)3 from 12 and 13 as a white solid in a 64% yield (0.41 g). ¹H-NMR (400 MHz, CDCl₃): δ (ppm) 7.76-7.84 (m, 18H), 7.61-7.70 (m, 33H), 7.28-7.43 (m, 15H), 7.21-7.25 (m, 6H), 2.73-2.84 (t, 12H), 2.07-2.28 (m, 24H), 1.90-1.98 (m, 18H), 0.81-1.02 (m, 108H), 0.30-0.43 (m, 54H). Molecular weight calcd. for C₂₃₇H₂₈₅N₃: 3172.9. MALD/I TOF MS (DCTB) m/z ([M]⁺): 3170.1. Anal. Calcd. C₂₃₇H₂₈₅N₃: C, 90.85; H, 9.15. Found: C, 90.77; H, 9.08.

2-[p-3-(ter(9,9-b is (2-methylbutyl)fluoren-7-yl)propyl-phenyl]-4,6-diphenyl-triazine, TRZ(1)-F(MB)3. The procedure for the synthesis of TRZ-F(MB)3 was followed to prepare TRZ(1)-F(MB)3 from 14 and 15 as a white solid in a 39% yield (0.18 g). ¹H-NMR (400 MHz, CDCl₃): δ (ppm) 8.80-8.83 (d, 4H), 8.73-8.75 (d, 2H), 7.76-7.84 (m, 5H), 7.59-7.71 (m, 15H), 7.31-7.44 (m, 5H), 7.21-7.27 (m, 2H), 2.80-2.84 (t, 4H), 2.11-2.25 (m, 8H), 1.93-1.98 (m, 6H), 0.60-1.01 (m, 36H), 0.30-0.45 (m, 18H). Molecular weight calcd. for C₂₃₇H₂₈₅N₃: 1264.9. MALD/I TOF MS (DCTB) m/z ([M]⁺): 1264.0. Anal. Calcd. C₂₃₇H₂₈₅N₃: C, 88.31; H, 8.37; N, 3.32. Found: C, 88.11; H, 8.34; N, 3.27.

2-Allyl-tetra(9,9-bis(2-methylbutyl))fluorene, 16. The procedure for the synthesis of 2 was followed to prepare 16 from 7b as a white solid in a 69% yield (0.41 g). ¹H-NMR (400 MHz, CDCl₃): δ (ppm) 7.76-7.87 (m, 7H), 7.59-7.74 (m, 13H), 7.33-7.46 (m, 3H), 7.18-7.24 (m, 2H), 5.96-6.12 (m, 1H), 5.15 (d, 2H), 3.51 (d, 2H), 2.14-2.39 (m, 8H), 1.89-2.09 (m, 8H), 0.63-1.10 (m, 48H), 0.38-0.46 (m, 24H).

N,N,N,-Tris[p-(3-(ter(9,9-bis(2-methylbutyl)fluoren-7-yl))propyl)phenyl]amine, TPA-F(MB)3. The procedure for the synthesis of TPD-F(MB)3 was followed to prepare TPA-F(MB)3 from 12 and tris(4-bromophenyl)amine as a white solid in a 55% yield (0.27 g). ¹H-NMR (400 MHz, CDCl₃): δ (ppm) 7.77-7.86 (m, 15H), 7.61-7.73 (m, 27H), 7.32-7.50 (m, 9H), 7.21-7.27 (m, 6H), 7.05-7.15 (m, 12H), 2.82 (t, 6H), 2.67 (t, 6H) 2.15-2.34 (m, 18H), 1.89-2.08 (m, 24H), 0.63-1.09 (m, 108H), 0.32-0.47 (m, 54H). Molecular weight calcd for C₂₃₄H₂₈₅N: 3111.84. MALDI/TOF MS (DCTB) m/z [M]⁺): 3110.2. Anal. calcd. for C₂₃₄H₂₈₅N: C, 90.32; H, 9.23; N, 0.45. Found: C, 90.25; H, 9.41; N, 0.54.

1,3,5-Tris[p-(3-(tetra(9,9-bis(2-methylbutyl)fluoren-7-yl))propyl)phenyl]-benzene, TPB-F(MB)4. The procedure for the synthesis of TPD-F(MB)3 was followed to prepare TPB-F(MB)4 from 13 and 16 as a white solid in a 50% yield (0.18 g). ¹H-NMR (400 MHz, CDCl₃)**: δ (ppm) 7.62-7.91 (m, 66H), 7.31-7.48 (m, 18H), 7.17-7.26 (m, 6H), 2.85 (t, 6H), 2.75 (t, 6H), 1.91-2.39 (m, 54H), 0.64-1.11 (m, 144H), 0.35-0.49 (m, 72H).

### Example 2

### Molecular Structures, Morphology and Phase Transition Temperatures

¹H-NMR spectra were acquired in CDCl₃ with an Avance-400 spectrometer (400 MHz). Elemental analysis was carried out by Quantitative Technologies, Inc. Molecular weights were measured with a TofSpec2E MALD/I TOF mass spectrometer (Micromass, Inc., UK). Thermal transition temperatures were determined by differential scanning calorimetry (Perkin-Elmer DSC-7) with a continuous N₂ purge at 20 mL/min. Samples were preheated to 260° C. followed by cooling at −20° C./min to −30° C. before taking the reported second heating scans at 20° C./min. Thermotropic properties were characterized with a polarizing optical microscope (DMLM, Leica, FP90 central processor and FP82 hot stage, Mettler Toledo).

### Example 3

### Absorption and Fluorescence Spectra in Dilute Solution

Dilute solutions of oligofluorenes in chloroform were prepared at a concentration of 2×10⁻⁶ M. Absorption spectra were gathered with an HP 8453E UV-vis-NIR diode array spectrophotometer. Fluorescence spectra were collected with a spectrofluorimeter (Quanta Master C-60SE, Photo Technology International) at an excitation wavelength of 360 nm in a 90° orientation.

### Example 4

### Preparation and Characterization of Neat Films

Optically flat fused silica substrates (25.4 mm diameter×3 mm thickness, transparent to 200 nm, Esco Products) were coated with a thin film of a commercial polyimide alignment layer (Nissan SUNEVER) and uniaxially rubbed. Isotropic films were prepared by spin coating from 0.5 wt % solutions in chloroform at 4000 RPM followed by drying in vacuo overnight. For the preparation of monodomain glassy-nematic films, thermal annealing was performed in the nematic fluid temperature range for 20 min with subsequent cooling to room temperature. Polarizing optical microscopy revealed that annealed thin films were defect-free under a magnification factor of 500.

Absorption and linear dichroism of monodomain glassy nematic films were characterized using a UV-Vis-NIR spectrophotometer (Lambda-900, Perkin-Elmer) and linear polarizers (HNP′B, Polaroid). Photoluminescence spectra, with and without polarization analysis, were collected using the spectrofluorimeter with a liquid light guide directing an unpolarized excitation beam at 360 nm onto the sample film at normal incidence. Emitted light normal to the film surface was detected and analyzed. The linearly polarized photoluminescence was characterized by controlling the film's nematic director relative to the two linear polarizers before the detector. First, the film was oriented vertically for gathering its emission spectra with a polarizer placed vertically and horizontally. The procedure was repeated with a horizontal orientation of the film. The results from two film orientations were averaged to minimize error. Experimental error was further reduced by inserting another polarizer at 45° between the first polarizer and the detector for all measurements. Variable angle spectroscopic ellipsometry (J. A. Woollam, V-VASE) was used to determine anisotropic refractive indices and absorption coefficients as well as film thickness following the literature procedures (Schubert et al., J Opt. Soc. Am. A 1996, 13:1930-1940).

As the primary standard for photoluminescence quantum yield (Φ_{PL}), 9,10-diphenylanthracene (99%, Acros Organics) was repeatedly recrystallized from xylenes until pale yellow prism crystals were obtained. Anthracene (99%, Aldrich Chemical Company) was recrystallized from ethanol. Poly(methylmethacrylate) (PMMA, Polysciences) with a weight-average molecular weight of 75,000 was used without further purification. About 5 μm thick PMMA films doped with 9,10-diphenylanthracene and anthracene at 10⁻² M were spin-cast on fused silica substrates followed by drying in vacuo overnight. A low doping level was adopted to avoid concentration quenching. The film lightly doped with 9,10-diphenylanthracene was assigned a widely accepted value, Φ_{PL}=0.83 (Melhuish, J Opt. Soc. Am. 1964, 54:183-186).

The anthracene-containing film was characterized with the following formula (Crosby and Demas, J. Phys. Chem. 1971, 75:991-1024):

$$\frac{{Φ}_{PL , s}}{{Φ}_{PL , r}} = \frac{1 - {10}^{- {A}_{r}}}{1 - {10}^{- {A}_{s}}} \frac{{B}_{s} \overline{{n}_{s}^{2}}}{{B}_{r} \overline{{n}_{r}^{2}}} \qquad ( 1 )$$

where subscripts s and r refer to sample and reference, respectively, A denotes absorbance at the excitation wavelength, B is the integrated intensity across the entire emission spectrum, and n̅²̅ is defined as follows:

$$\overline{{n}^{2}} ≡ \frac{\int I ( λ ) {n}^{2} ( λ ) ⅆ λ}{\int I ( λ ) ⅆ λ} \qquad ( 2 )$$

in which I(λ) stands for emission intensity, and the integration is performed over the entire emission spectrum. A variable angle spectroscopic ellipsometer (V-VASE, J. A. Woollam) was employed to collect data at four incident angles (55, 60, 62, 65° off-normal), and a UV-Vis spectrophotometer (Lambda-900, Perkin-Elmer) to collect transmission spectra at normal incidence. A computer software package was used for the evaluation of film thickness and refractive index dispersion n(λ). The accuracy of the measurements was validated with a spin-coated 550 nm thick PMMA film, whose refractive index profile in the 300-900 nm spectral range was found to agree with refractometric data (Nikolov and Ivanov, Appl. Optics 2000, 39:2067-2070) to within 0.003. The PL quantum yield was measured using the spectrofluorimeter described above with emission detected at 60° off-normal to prevent excitation light from entering the detector. The result for the anthracene-containing PMMA film, Φ_{PL}=0.28±0.03, agrees with the reported value of 0.27 in benzene and ethanol (Crosby and Demas, J. Phys. Chem. 1971, 75: 991-1024), thus validating the experimental procedure. In general, the presently reported Φ_{PL} values are accompanied by an uncertainty of ±10%.

Electrochemical Characterization. Cyclic voltammetry (CV) measurements were conducted using an EC-Epsilon potentiostat (Bioanalytical Systems Inc.). A silver/silver chloride wire (2 mm diameter), a platinum wire (0.5 mm diameter), and a platinum disk (1.6 mm diameter) were used as the reference, counter, and working electrodes, respectively. All the oxidation scans were measured for 2.5×10⁻⁴ M solutions in anhydrous CH₂Cl₂ with 0.1 M tetraethylammonium tetrafluoroborate as the supporting electrolyte, and all the reduction scans were measured for 2.5×10⁻⁴ M solutions in anhydrous THF with tetrabutylammonium perchlorate as the supporting electrolyte. Ferrocene was used as an external standard with an oxidation potential at 0.68 V vs Ag/AgCl in THF and 0.46 V vs Ag/AgCl in CH₂Cl₂. Energy levels were measured relative to the ferrocene's HOMO level of 4.8 eV (Fink et al., Chem. Mater. 1998, 10:3620-3625).

Results

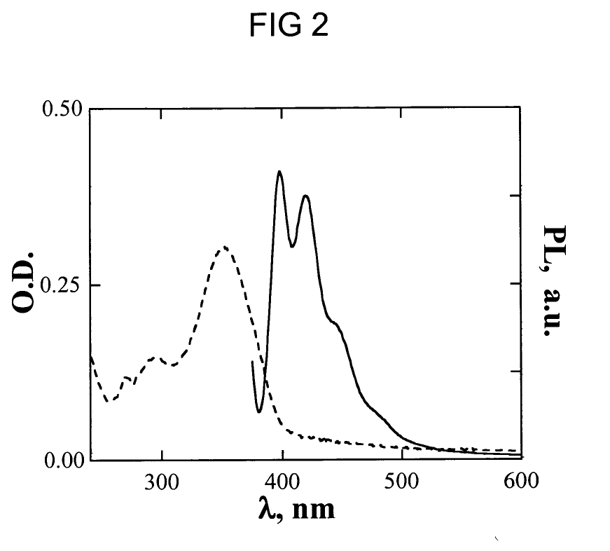

A 50-nm-thick isotropic film of TRZ-F(MB)3 was prepared by spin-coating from a dilute solution with subsequent drying under vacuum. The UV-Vis absorption and fluorescence spectra are shown in FIG. 2. Similar spectra were obtained for TPD-F(MB)3.

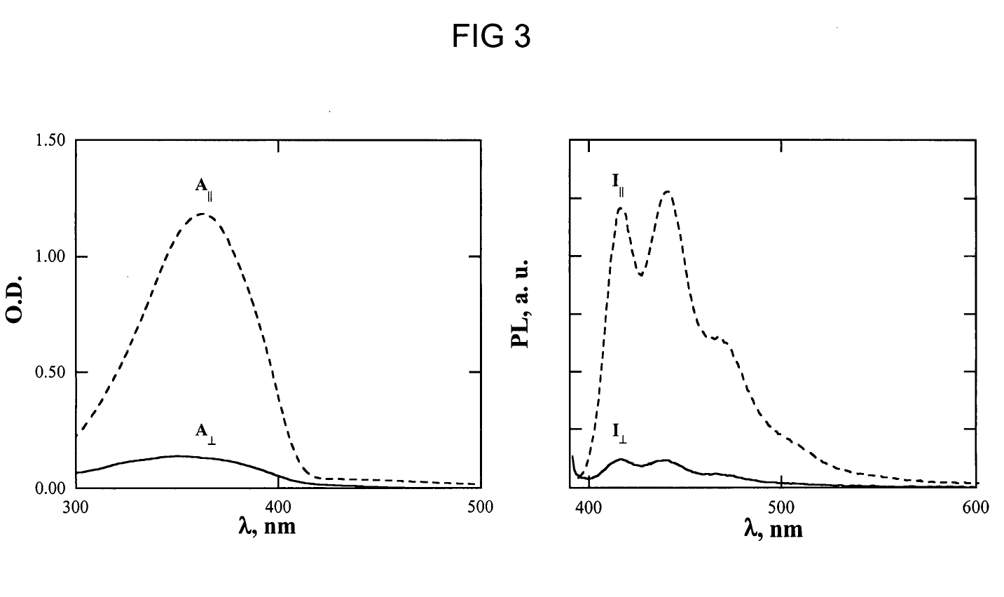

A 50-nm-thick glassy-nematic film of TRZ-F(MB)5 was prepared by spin-coating from a dilute solution onto an alignment-treated fused silica substrate followed by drying under vacuum and thermal annealing. The resultant film was further characterized as monodomain in the absence of disclinations under polarizing optical microscopy. The absorption and fluorescence spectra of the glassy-nematic film are shown in FIG. 3.

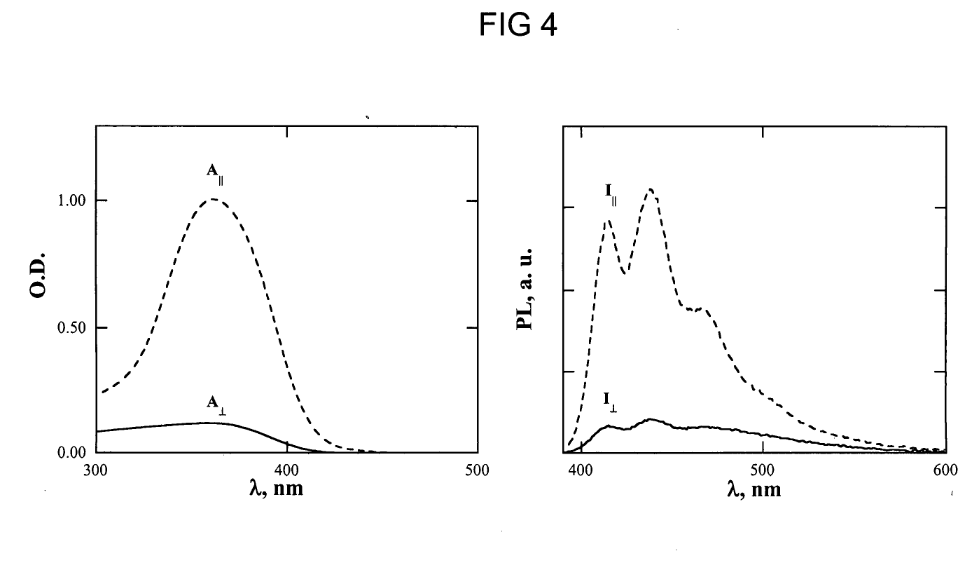

The absorption dichroism yields an orientational order parameter, S=0.75, indicating a high degree of uniaxial alignment adopted by the pentafluorene pendants despite the presence of a trifunctional core. In fact, the observed S value is the same as previously reported stand-alone pentafluorene (Geng et al., Chem. Mater. 2003, 15:542-549). A dichroic ratio of 11.2 at the emission maximum achieved with the glass-liquid-crystalline film of TRZ-F(MB)5 is slightly higher than that of F(MB)5. Shown in FIG. 4 are the polarized absorption and fluorescence spectra of a 50-nm-thick, monodomain glassy-nematic film of TPD-F(MB)5 as an additional example. An orientational order parameter was estimated at S=0.72 on the basis of absorption dichroism.

The 50-nm-thick, glassy-amorphous and -nematic films of the four representative materials were also characterized for photoluminescence quantum yield, Φ_{PL}, with 9,10-diphenylanthracene and anthracene serving as the primary and secondary standard, respectively. The Φ_{PL} values for TRZ-F(MB)3, TRZ-F(MB)5, TPD-F(MB)3, and TPD-F(MB)5 were found to be 42, 51, 15, and 28%, respectively.

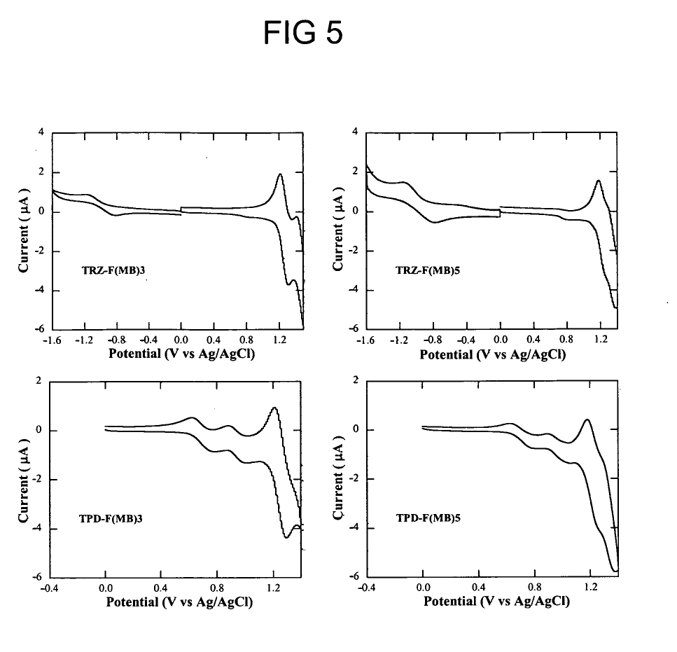

In addition, dilute solutions of the four representative materials were characterized with cyclic voltammetry. The oxidation and reduction scans are presented in FIG. 5, and the key data are summarized in Table 1. For both the TRZ and TPD cores, pendant oligofluorenes' HOMO levels, 5.58±0.03 eV, are identical to stand-alone oligofluorenes' because of the propylene spacer isolating the two structural elements. The optical bandgaps of pendant terfluorene and pentafluorene are estimated at 3.20 and 3.03 eV, respectively, yielding a LUMO level of 2.38 eV for terfluorene and 2.55 eV for pentafluore. The TRZ core's LUMO level of 3.12±0.01 eV and the TPD core's HOMO level of 5.05±0.01 eV are close to those reported for TRZ- and TPD-based materials (Fink et al., Chem. Mater. 1998, 10:3620-3625; Adachi et al., Appl. Phys. Lett. 1995, 66:2679-2681). With a HOMO level at 5.05 eV close to those of PEDOT at 5.1 eV and ITO at 4.7 to 5.0 eV, the TPD core is more receptive to hole injection than stand-alone oligofluorenes. The TRZ core's LUMO level at 3.12 eV is relatively close to the air-stable Mg:Ag cathode at 3.7 eV, and hence is more amenable to electron injection than pendant oligofluorenes. Furthermore, the emission spectra shown in FIGS. 2 through 4 are contributed solely by pendant oligofluorenes (Geng et al., Chem. Mater. 2003, 15:542-549) because of the cores' higher bandgaps than the pendants'. Generally, the disclosed materials comprise cores intended for facile charge injection and transport and pendants designed for efficient full-color emission. Used alone or as mixtures thereof, the new materials are useful for balancing the injection and transport of charges as a strategy to substantially improve OLED device efficiency and lifetime.

TABLE 1
Electrochemical Characterization in Dilute Solutions by Cyclic Voltammetry

| | | E_{1/2}(red)^{a,b} | E_{1/2}(ox)^{a,c} | E_{1/2}(red)^{d} | E_{1/2}(ox)^{d} | | |
|---|---|---|---|---|---|---|---|
| | | vs | vs | vs | vs | | |
| | | Ag/AgCl | Ag/AgCl | Fc | Fc | LUMO^{e} | HOMO^{e} |
| Compound | | (V) | (V) | (V) | (V) | (eV) | (eV) |
| TRZ-F(MB)3 | Core | −1.01 | — | −1.69 | — | 3.11 | — |
| | Pendant | — | 1.27 | — | 0.81 | — | 5.61 |
| TRZ-F(MB)5 | Core | −0.99 | — | −1.67 | — | 3.13 | — |
| | Pendant | — | 1.22 | — | 0.76 | — | 5.56 |
| TPD-F(MB)3 | Core | — | 0.71 | — | 0.25 | — | 5.05 |
| | Pendant | — | 1.25 | — | 0.79 | — | 5.59 |
| TPD-F(MB)5 | Core | — | 0.72 | — | 0.26 | — | 5.06 |
| | Pendant | — | 1.21 | — | 0.75 | — | 5.55 |

^{a}Half potentials, E_{1/2}, determined as the average of forward and reverse reduction or oxidation peaks.
^{b}Reduction scans of 2.5 × 10⁻⁴ M solutions in anhydrous THF with 0.1 M tetrabutylammonium perchlorate as supporting electrolyte.
^{c}Oxidation scans of 2.5 × 10⁻⁴ M solutions in anhydrous CH₂Cl₂ with 0.1 M tetraethylammonium tetrafluoroborate as supporting electrolyte.
^{d}Relative to ferrocene/ferrocenium with an oxidation potential at 0.68 V vs Ag/AgCl in THF and 0.46 V vs Ag/AgCl in CH₂Cl₂ (Fink et al., Chem. Mater. 1998, 10: 3620-3625); (Fc = ferrocene).
^{e}Relative to ferrocene's HOMO level of 4.8 eV (Fink et al., Chem Mater. 1998, 10: 3620-3625).

(a) Half-potentials, E_{1/2}, determined as the average of forward and reverse reduction or oxidation peaks. (b) Reduction scans of 2.5×10⁻⁴ M solutions in anhydrous THF with 0.1 M tetrabutylammonium perchlorate as supporting electrolyte. (c) Oxidation scans of 2.5×10⁻⁴ M solutions in anhydrous CH₂Cl₂ with 0.1 M tetraethylammonium tetrafluoroborate as supporting electrolyte. (d) Relative to ferrocene/ferrocenium with an oxidation potential at 0.68 V vs Ag/AgCl in THF and 0.46 V vs Ag/AgCl in CH₂Cl₂ (Fink et al., Chem. Mater. 1998, 10:3620-3625); (Fc=ferrocene). (e) Relative to ferrocene's HOMO level of 4.8 eV (Fink et al., Chem. Mater. 1998, 10:3620-3625).

### REFERENCES

Tang, C. W.; VanSlyke, S. A. “Organic Electroluminescent Diodes,” Appl. Phys. Lett. 1987, 51:913-915.
Burroughes, J. H.; Bradley, D. D. C.; Brown, A. R.; Marks, R. N.; Mackay, K.; Friend, R. H.; Burns, P. L.; Holmes, A. B. “Light-Emitting Diodes Based on Conjugated Polymers,” Nature 1990, 347:539-541.
Gustafsson, G.; Cao, Y.; Treacy, G. M.; Klavetter, F.; Colaneri, N.; Heeger, A. J. “Flexible Light-Emitting Diodes Made from Soluble Conducting Polymers,” Nature 1992, 357:477-479.
Cao, Y.; Yu, G.; Parker, I. D.; Heeger, A. J. “Ultrathin Layer Alkaline Earth Metals as Stable Electron-Injecting Electrodes for Polymer Light-Emitting Diodes,” J. Appl. Phys. 2000, 3618-3623.
Ego, C.; Grimsdale, A. C.; Uckert, F.; Yu, G.; Srdanov, G.; Müillen, K. “Triphenylamine-Substituted Polyfluorene—a Stable Blue-Emitter with Improved Charge Injection for Light-Emitting Diodes,” Adv. Mater. 2002, 809-811.
Martens, H. C. F.; Huiberts, J. N.; Blom, P. W. M. “Simultaneous Measurement of Electron and Hole Mobilities in Polymer Light-Emitting Diodes,” Appl. Phys. Lett. 2000, 77:1852-1854.
Adachi, C.; Tokito, S.; Tsutsui, T.; Saito, S. “Electroluminescence in Organic Films with Three-Layer Structure,” Jpn. J. Appl. Phys. 1988, 27:L269-L271.
Adachi, C.; Tsutsui, T.; Saito, S. “Organic Electroluminescent Device Having a Hole Conductor as an Emitting Layer,” Appl. Phys. Lett. 1989, 55:1489-1491.
(Brown, A. R.; Bradley, D. D.C.; Burroughes, J. H.; Friend, R. H.; Greenham, N. C.; Burn, P. L.; Holmes, A. B.; Kraft, A. “Poly(p-phenylenevinylene) Light-Emitting Diodes: Enhanced Electroluminescent Efficiency Through Charge Carrier Confinement,” Appl. Phys. Lett. 1992, 61:2793-2795
Yang, Y.; Pei, Q. “Electron Injection Polymer for Polymer Light-Emitting Diodes,” J. Appl. Phys. 1995, 77:4807-4809.
Strukelj, M.; Miller, T. M.; Papadimitrakopoulos, F.; Son, S. “Effects of Polymeric Electron Transporters and the Structure of Poly(p-phenylenevinylene) on the Performance of Light-Emitting Diodes,” J. Am. Chem. Soc. 1995, 117:11976-11983.
Buchwald, E.; Meier, M.; Karg, S.; Poesch, P.; Schmidt, H. W.; Strohriegel, P.; Riess, W.; Schwoerer, M. “Enhanced Efficiency of Polymer Light Emitting Diodes Utilizing Oxadiazole Polymers,” Adv. Mater. 1995, 7:839-842.
Fukuda, T.; Kanbara, T.; Yamamoto, T.; Ishikawa, K.; Takezoe, H.; Fukuda, A. “Polyquinoxaline as an Excellent Electron Injecting Material for Electroluminescent Device,” Appl. Phys. Lett. 1996, 68:2346-2348.
Kim, Y.; Bae, K. H.; Jeong, Y. Y.; Choi, D. K.; Ha, C. S. “An Electronically Active Molecularly Doped Polyimide Hole Injection Layer for an Efficient Hybrid Organic Light-Emitting Device,” Chem. Mater. 2004, 16:5051-5057.
Liew, Y.-F.; Zhu, F.; Chua, S.-J.; Tang, J.-X. “Tris-(8-hydroxyquinoline)aluminum-Modified Indium Tin Oxide for Enhancing the Efficiency and Reliability of Organic Light-Emitting Devices,” Appl. Phys. Lett. 2004, 85:4511-4513.
Liao, C.-H.; Lee, M.-T.; Tsai, C.-H.; Chen, C. H. “Highly Efficient Blue Organic Light-Emitting Devices Incorporating a Composite Hole Transport Layer,” Appl. Phys. Lett. 2005, 86:203507-1-203507-3.
Yi, Y.; Kang, S. J.; Cho, K.; Koo, J. M.; Han, K.; Park, K.; Noh, M.; Whang, C. N.; Jeong, K. “Origin of the Improved Luminance-Voltage Characteristics and Stability in Organic Light-Emitting Device Using CsCl Electron Injection Layer,” Appl. Phys. Lett. 2005, 86:213502-1-213502-3.
Chwang, A. B.; Kwong, R. C.; Brown, J. J. “Graded Mixed-Layer Organic Light-Emitting Devices,” Appl. Phys. Lett. 2002, 80:725-727.
Aziz, H.; Popovic, Z. D.; Hu, N.-X. “Organic Light Emitting Devices with Enhanced Operational Stability at Elevated Temperatures,” Appl. Phys. Lett. 2002, 81:370-372.
Aziz, H.; Popovic, Z. D.; Hu, N.-X.; Hor, A.-M.; Xu, G. “Degradation Mechanism of Small Molecule-Based Organic Light-Emitting Devices,” Science 1999, 283:1900-1902.
Cimrova, V.; Neher, D.; Remmers, M.; Kminek, I. “Blue Light-Emitting Devices Based on Novel Polymer Blends,” Adv. Mater. 1998, 10:676-680.
Naka, S.; Shinno, K.; Okada, H.; Onnagawa, H.; Miyashita, K. “Organic Electroluminescent Devices Using a Mixed Single Layer,” Jpn, J. Appl. Phys. 1994, 33:L1772-L1774.
Cao, Y.; Parker, I. D.; Yu, G.; Zhang, C.; Heeger, A. J. “Improved Quantum Efficiency for Electroluminescence in Semiconducting Polymers,” Nature 1999, 397:414-417.
Vaeth, K. M.; Tang, C. W. “Light-Emitting Diodes Based on Phosphorescent Guest/Polymeric Host Systems,” J. Appl. Phys. 2002, 92:3447-3453.
Gong, X.; Robinson, M. R.; Ostrowski, J. C.; Moses, D.; Bazan, G. C.; Heeger, A. J. “High-Efficiency Polymer-Based Electrophosphorescent Devices,” Adv. Mater. 2002, 14:581-585.
Niu, Y.-H.; Chen, B.; Kim, T.-D.; Liu, M. S.; Jen, A. K.-Y. “Efficient and Stable Blue Light-Emitting Diodes Based on an Anthracene Derivative Doped Poly(N-vinylcarbazole),” Appl. Phys. Lett. 2004, 85:5433-5435.
Yan, H.; Huang, Q.; Scott, B. J.; Marks, T. J. “A Polymer Blend Approach to Fabricating the Hole Transport Layer for Polymer Light-Emitting Diodes,” Appl. Phys. Lett. 2004, 84:3873-3875.
Choong, V.-E.; Shi, S.; Curless, J.; Shieh, C.-L.; Lee, H.-C.; So, F.; Shen, J.; Yang, J. “Organic Light-Emitting Diodes with a Bipolar Transport Layer,” Appl. Phys. Lett. 1999, 75:172-174.
Yan, H.; Scott, B. J.; Huang, Q.; Marks, T. J. “Enhanced Polymer Light-Emitting Diodes Performance Using a Crosslinked-Network Electron-Blocking Interlayer,” Adv. Mater. 2004, 16:1948-1953.
Uchida, M.; Ohmori, Y.; Noguchi, T.; Ohnishi, T.; Yoshino, K. “Color-Variable Light-Emitting Diodes Utilizing Conducting Polymer Containing Fluorescent Dye,” Jpn. J. Appl. Phys. 1993, 32:L921-L924.
Ahn, J. H.; Wang, C.; Pearson, C.; Bryce, M. R.; Petty, M. C. “Organic Light-Emitting Diodes Based on a Blend of Poly[2-(2-ethylhexyloxy)-5-methoxy-1,4-phenylenevinylene] and an Electron Transporting Material,” Appl. Phys. Lett. 2004, 85:1283-1285.
Lee, J.-H.; Wu, C.-I.; Liu, S.-W.; Huang, C.-A.; Chang, Y. “Mixed Host Organic Light-Emitting Devices with Low Driving Voltage and Long Lifetime,” Appl. Phys. Lett. 2005, 86:103506-1-103506-3
Li, X. C.; Cacialli, F.; Giles, M.; Gruener, J.; Friend, R. H.; Holmes, A. B.; Moratti, S. C.; Yong, T. M. “Charge Transport Polymers for Light-Emitting Diodes,” Adv. Mater. 1995, 7:898-900.
Boyd, T. J.; Geerts, Y.; Lee, J.; Fogg, D. E.; Lavoie, G. G.; Schrock, R. R.; Rubner, M. F. “Electroluminescence from New Polynorbornenes that Contain Blue-Light-Emitting and Charge-Transport Side Chains,” Macromolecules 1997, 30:3553-3559.
Grice, A. W.; Tajbakhsh, A.; Burn, P. L.; Bradley, D. D. C. “A Blue-Emitting Triazole-Based Conjugated Polymer,” Adv. Mater. 1997, 9:1174-1178.
Tamoto, N.; Adachi, C.; Nagai, K. “Electroluminescence of 1,3,4-Oxadiazole and Triphenylamine-Containing Molecules as an Emitter in Organic Multilayer Light Emitting Diodes,” Chem. Mater. 1997, 9:1077-1085.
Chan, L.-H.; Lee, R.-H.; Hsieh, C.-F.; Yeh, H.-C.; Chen, C.-T. “Optimization of High-Performance Blue Organic Light-Emitting Diodes Containing Tetraphenylsilane Molecular Glass Materials,” J. Am. Chem. Soc. 2002, 124:6469-6479.
Danel, K.; Huang, T.-H.; Lin, J. T.; Tao, Y.-T.; Chuen, C.-H. “Blue-Emitting Anthracenes with End-Capping Diarylamines,” Chem. Mater. 2002, 14:3860-3865.
Doi, H.; Kinoshita, M.; Okumoto, K.; Shirota, Y. “A Novel Class of Emitting Amorphous Molecular Materials with Bipolar Character for Electroluminescence,” Chem. Mater. 2003, 15:1080-1089.
Thomas, K. R. J.; Lin, J. T.; Velusamy, M.; Tao, Y.-T.; Chuen, C.-H. “Color Tunning in Benzo[1,2,5]thiadiazole-Based Small Molecules by Amino Conjugation/Deconjugation: Bright Red-Light-Emitting Diodes,” Adv. Funct. Mater. 2004, 14:83-90.
Wong, K.-T.; Chen, R.-T.; Fang, F.-C.; Wu, C.-C.; Lin, Y.-T. “4,5-Diazafluorene-Incorporated Ter(9,9-diarylfluorene): A Novel Molecular Doping Strategy for Improving the Electron Injection Property of a Highly Efficient OLED Blue Emitter,” Org. Lett. 2005, 7:1979-1982.
Bao, Z.; Peng, Z.; Galvin, M. E.; Chandross, E. A. “Novel Oxadiazole Side Chain Conjugated Polymers as Single-Layer Light-Emitting Diodes with Improved Quantum Efficiencies,” Chem. Mater. 1998, 10:1201-1204.
Chung, S.-J.; Kwon, K.-Y.; Lee, S.-W.; Jin, J.-I.; Lee, C. H.; Lee, C. E.; Park, Y. “Highly Efficient Light-Emitting Diodes Based on an Organic-Soluble Poly(p-phenylenevinylene) Derivative Carrying the Electron-Transporting PBD Moiety,” Adv. Mater. 1998, 10:1112-1116.
Peng, Z.; Bao, Z.; Galvin, M. E. “Oxadiazole-Containing Conjugated Polymers for Light-Emitting Diodes,” Adv. Mater. 1998, 10:680-684.
Ding, J.; Day, M.; Robertson, G.; Roovers, J. “Synthesis and Characterization of Alternating Copolymers of Fluorene and Oxadiazole,” Macromolecules, 2002, 35:3474-3483.
Huang, W.; Meng, H.; Yu, W.; Gao, J.; Heeger, A. J. “A New Blue Light-Emitting Polymer Containing Substituted Thiophene and an Arylene-1,3,4-oxadiazole Moiety,” Adv. Mater. 1998, 10:593-596.
Peng, Z.; Zhang, J. “New Oxadiazole-Containing Conjugated Polymer for Single-Layer Light-Emitting Diodes,” Chem. Mater. 1999, 11:1138-1143.
Redecker, M.; Bradley, D. D. C.; Inbasekaran, M.; Wu, W. W.; Woo, E. P. “High Mobility Hole Transport Fluorene-Triarylamine Copolymers,” Adv. Mater. 1999, 11:241-246.
Lee, Y.; Chen, X.; Chen, S. A.; Wei, P.; Fann, W. “Soluble Electroluminescent Poly(phenylene vinylene)s with Balanced Electron- and Hole Injections,” J. Am. Chem. Soc. 2001, 123:2296-2307.
Miteva, T.; Meisel, A.; Knoll, W;. Nothofer, H.-G.; Scherf, U.; Müller, D. C.; Meerholz, K.; Yasuda, A.; Neher, D. “Improving the Performance of Polyfluorene-Based Organic Light-Emitting Diodes via Endcapping,” Adv. Mater. 2001, 13:565-570.
Liu, M. S.; Jiang, X.; Herguth, P.; Jen, A. K.-Y. “Efficient Cyano-Containing Electron-Transporting Polymers for Light-Emitting Diodes,” Chem. Mater. 2001, 13:3820-3822.
Wu, F.-I.; Reddy, D. S.; Shu, C.-F.; Liu, M. S.; Jen, A. K.-Y. “Novel Oxadiazole-Containing Polyfluorene with Efficient Blue Electroluminescence,” Chem. Mater. 2003, 15:269-274.
Gong, X.; Ma, W.; Ostrowski, J. C.; Bechgaard, K.; Bazan, G. C.; Heeger, A. J.; Xiao, S.; Moses, D. “End-Capping as a Method for Improving Carrier Injection in Electrophosphorescent Light-Emitting Diodes,” Adv. Funct. Mater. 2004, 14:393-397.
Jin, S.; Kim, M.; Kim, J. Y.; Lee, K.; Gal, Y. “High-Efficiency Poly(p-phenylenevinylene)-Based Copolymers Containing an Oxadiazole Pendant Group for Light-Emitting Diodes,” J. Am. Chem. Soc. 2004, 126:2474-2480.
Yu, L.-S.; Chen, S. A. “Full-Range Tunability of Electron and Hole Carrier Mobilities and Density Ratios via Incorporation of Highly Electron-Deficient Moieties in Poly(phenylene vinylene) Side Chains,” Adv. Mater. 2004, 16:744-748.
Aldred, M. P.; Eastwood, A. J.; Kelly, S. M.; Vlachos, P.; Contoret, A. E. A.; Farrar, S. R.; Mansoor, B.; O'Neill, M.; Tsoi, W. C. “Light-Emitting Fluorene Photoreactive Liquid Crystals for Organic Electroluminescence,” Chem. Mater. 2004, 16:4928-4936.
Kwon, T. W.; Alam, M. M.; Jenekhe, S. A. “n-Type Conjugated Dendrimers: Convergent Synthesis, Photophysics, Electroluminescence, and Use as Electron-Transport Materials for Light-Emitting Diodes,” Chem. Mater. 2004, 16:4657-4666
Brown, T. M.; Kim, J. S.; Friend, R. H.; Cacialli, F.; Daik, R.; Feast, W. J. “Built-in Field Electroabsorption Spectroscopy of Polymer Light-Emitting Diodes Incorporating a Doped Poly(3,4-ethylene dioxythiophene) Hole Injection Layer,” Appl. Phys. Lett. 1999, 75:1679-1681.
de Jong, M. P.; van Ijzendoorn, L. J.; de Voigt, M. J. A. “Stability of the Interface Between Indium-Tin-Oxide and Poly(3,4-ethylele dioxythiophene)/Poly(styrenesulfonate) in Polymer Light-Emitting Diodes,” Appl. Phys. Lett. 2000, 77:2255-2257.
Gong, X.; Moses, D.; Heeger, A. J.; Liu, S.; Jen, A. K.-Y. “High-Performance Polymer Light-Emitting Diodes Fabricated with a Polymer Hole Injection Layer,” Appl. Phys. Lett. 2003, 83:183-185.
Yan, H.; Huang, Q.; Cui, J.; Veinot, J. G. C.; Kern, M. M.; Marks, T. J. “High-Brightness Blue Light-Emitting Polymer Diodes via Anode Modification Using a Self-Assembled Monolayers,” Adv. Mater. 2003, 15:835-838.
Geng, Y.; Culligan, S. W.; Trajkovska, A.; Wallace, J. U.; Chen, S. H. “Monodisperse Oligofluorenes Forming Glassy-Nematic Films for Linearly Polarized Blue Emission,” Chem. Mater. 2003, 15:542-549.
Culligan, S. W.; Geng, Y.; Chen, S. H.; Klubek, K.; Vaeth, K. M.; Tang, C. W. “Strongly Polarized and Efficient Blue Organic Light-Emitting Diodes Using Monodisperse Glassy-Nematic Oligo(fluorene)s,” Adv. Mater. 2003, 15:1176-1180.
Geng, Y.; Chen, A. C. A.; Ou, J. J.; Chen, S. H.; Klubek, K.; Vaeth, K. M.; Tang, C. W. “Monodisperse Glassy-Nematic Conjugated Oligomers with Chemically Tunable Polarized Light Emission,” Chem. Mater. 2003, 15:4352-4360.
Chen, A. C. A.; Culligan, S. W.; Geng, Y.; Chen, S. H.; Klubek, K.; Vaeth, K. M.; Tang, C. W. “Organic Polarized Light-Emitting Diodes via Förster Energy Transfer Using Monodisperse Conjugated Oligomers,” Adv. Mater. 2004, 16:783-788.
Chen, S. H.; Shi, H.; Conger, B. M.; Mastrangelo, J. C.; Tsutsui, T. “Novel Vitrifiable Liquid Crystals as Optical Materials,” Adv. Mater. 1996, 8:998-1001.
Chen, S. H.; Katsis, D.; Schmid, A. W.; Mastrangelo, J. C.; Tsutsui, T.; Blanton, T. N. “Circularly Polarized Light Generated by Photoexcitation of Luminophores in Glassy Liquid-Crystal Films,” Nature 1999, 397:506-508.
Fan, F. Y.; Culligan, S. W.; Mastrangelo, J. C.; Katsis, D.; Chen, S. H.; Blanton, T. N. “Novel Glass-Forming Liquid Crystals. 6. High-Temperature Glassy Nematics,” Chem. Mater. 2001, 13:4584-4594.
Katsis, D.; Chen, H. P.; Mastrangelo, J. C.; Chen, S. H.; Blanton, T. N. “Vitrified Chiral-Nematic Liquid Crystalline Films for Selective Reflection and Circular Polarization,” Chem. Mater. 1999, 11:1590-1596.
Chen, H. P.; Katsis, D.; Mastrangelo, J. C.; Chen, S. H.; Jacobs, S. D.; Hood, P. J. “Glassy Liquid-Crystal Films with Opposite Chirality as High-Performance Optical Notch Filters and Reflectors,” Adv. Mater. 2000, 12:1283-1286.
Chen, H. M. P.; Katsis, D.; Chen, S. H. “Deterministic Synthesis and Optical Properties of Glassy Chiral-Nematic Liquid Crystals,” Chem. Mater. 2003, 15:2534-2542.
Chen, S. H.; Mastrangelo, J. C.; Jin, R. J. “Glassy Liquid Crystal Films as Broadband Polarizers and Reflectors via Spatially Modulated Photoracemization,” Adv. Mater. 1999, 11:1183-1186.
Chen, S. H.; Chen, H. M. P.; Geng, Y.; Jacobs, S. D.; Marshall, K. L.; Blanton, T. N. “Novel Glassy Nematic Liquid Crystals for Non-Destructive Rewritable Optical Memory and Photonic Switching,” Adv. Mater. 2003, 15:1061-1065.
Strohriegl, P.; Grazulevicius, J. V. “Charge-Transporting Molecular Glasses,” Adv. Mater. 2002, 14:1439-1452.
Getautis, V.; Paliulis, O.; Gaidelis, V.; Jankauskas, V.; Sidaravi\check{c}ius, J. “Hole-Drift Mobility in Phenylenediamine Derivatives Possessing Methyl Substituents,” J Photochem. Photobiol. A 2002, 151:39-43.
Yasuda, T.; Yamaguchi, Y.; Zou, D.-C.; Tsutsui, T. “Carrier Mobilities in Organic Electron Transport Materials Determined from Space Charge Limited Current,” Jpn. J. Appl. Phys. 2002, 41:5626-5629.
Ishi-i, T.; Yaguma, K.; Thiemann, T.; Yashima, M.; Ueno, K.; Mataka, S. “High Electron Drift Mobility in an Amorphous Film of 2,4,6,-Tris[4-(1-naphthyl)phenyl]-1,3,5-triazine,” Chem. Lett. 2004, 33:1244-1246.
Kido, J.; Ohtaki, C.; Hongawa, K.; Okuyama, K.; Nagai, K. “1,2,4-Triazole Derivative as an Electron Transport Layer in Organic Electroluminescent Device,” Jpn. J. Appl. Phys. 1993, 32:L917-L920.
Sainova, D.; Miteva, T.; Nothofer, H. G.; Scherf, U.; Glowacki, I.; Ulanski, J.; Fujikawa, H.; Neher, D. “Control of Color and Efficiency of Light-Emitting Diodes Based on Polyfluorenes Blended with Hole-Transporting Molecules,” Appl. Phys. Lett. 2000, 76:1810-1812.
Tao, S.; Hong, Z.; Peng, Z.; Ju, W.; Zhang, X.; Wang, P.; Wu, S.; Lee, S. “Anthracene Derivative for a Non-Doped Blue-Emitting Organic Electroluminescence Device with Both Excellent Color Purity and High Efficiency,” Chem. Phys. Lett. 2004, 397:1-4.
Kulkami, A. P.; Tonzola, C. J.; Babel, A.; Jenekhe, S. A. “Electron Transport Materials for Organic Light-Emitting Diodes,” Chem. Mater. 2004, 16:4556-4573.
Fink, R.; Heischkel, Y.; Thelakkat, M.; Schmidt, H.-W.; Jonda, C.; Hüippauff, M. “Synthesis and Application of Dimeric 1,3,5-Triazine Ethers as Hole-Blocking Materials in Electroluminescent Devices,” Chem. Mater. 1998, 10:3620-3625.
Adachi, C.; Nagai, K.; Tamoto, N. “Molecular Design of Hole Transport Materials for Obtaining High Durability in Organic Electroluminescent Diodes,” Appl. Phys. Lett. 1995, 66:2679-2681.
Huang, Q.; Evmenenko, G.; Dutta, P.; Marks, T. J. “Molecularly Engineered Anode Adsorbates for Probing OLED Interfacial Structure-Charge Injection/Luminance Relationships: Large, Structure-Dependent Effects,” J. Am. Chem. Soc. 2003, 125:14704-14705.
Schubert, M.; Rheinländer, B.; Cramer, C.; Schmiedel, H.; Woollam, J. A.; Herzinger, C. M.; Johs, B. “Generalized Transmission Ellipsometry for Twisted Biaxial Dielectric Media: Application to Chiral Liquid Crystals,” J Opt. Soc. Am. A 1996, 13:1930-1940.
Melhuish, W. H. “Measurement of Quantum Efficiencies of Fluorescence and Phosphorescence and Some Suggested Luminescence Standards,” J Opt. Soc. Am. 1964, 54:183-186.
Crosby, G. A.; Demas, J. N. “Measurement of Photoluminescence Quantum Yields. Review,” J. Phys. Chem. 1971, 75:991-1024.
Nikolov, I. D.; Ivanov, C. D. “Optical Plastic Refractive Measurements in the Visible and Near-Infrared Regions,” Appl. Optics 2000, 39:2067-2070.
Dawson, W. R.; Windsor, M. W. “Fluorescence Yields of Aromatic Compounds,” J. Phys. Chem. 1968, 72:3251-60.

What is claimed is:

1. A material comprising the formula 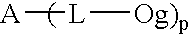
wherein Og is a conjugated oligomer; A is a hole-conducting core, an electron-conducting core, or a non-conducting core; L is an aliphatic linker, and p is from 1 to 10.

2. The material of claim 1, wherein the conjugated oligomer emits full-color unpolarized light.

3. The material of claim 1, wherein the conjugated oligomer emits full-color polarized light.

4. The material of claim 1, wherein the conjugated oligomer comprises: 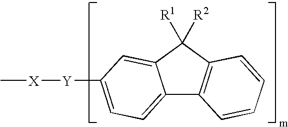
wherein X and Y are, independently of one another, alkyl, alkoxy, alkenyl, alkynyl, aryl, or heteroaryl; R¹ and R² are, independently of one another, hydrogen, alkyl, alkoxy, alkenyl, alkynyl, aryl, heteroaryl, hydroxy, ketone, nitro, or silyl; and m is from 1 to 25.

5. The material of claim 4, wherein X comprises —CH₂—, —O—, or —C(O)—, Y comprises —(CH₂)ₙ— or —(CH₂O)ₙ—, where n is from 1 to 25; and R¹ and R² are alkyl.

6. The material of claim 4, wherein R¹ and R² are both sec-pentyl.

7. The material of claim 4, wherein R¹ and R² are both propyl.

8. The material of claim 4, wherein R¹ and R² are both 2-ethyl-hexyl.

9. The material of claim 4, wherein m is 3.

10. The material of claim 4, wherein m is 5.

11. The material of claim 1, wherein the conjugated oligomer comprises: 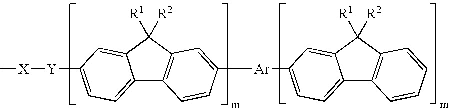
wherein X and Y are, independently of one another, alkyl, alkoxy, alkenyl, alkynyl, aryl, or heteroaryl; R¹ and R² are, independently of one another, hydrogen, alkyl, alkoxy, alkenyl, alkynyl, aryl, heteroaryl, hydroxy, ketone, nitro, or silyl; m is from 1 to 25; and Ar comprises one or more of: 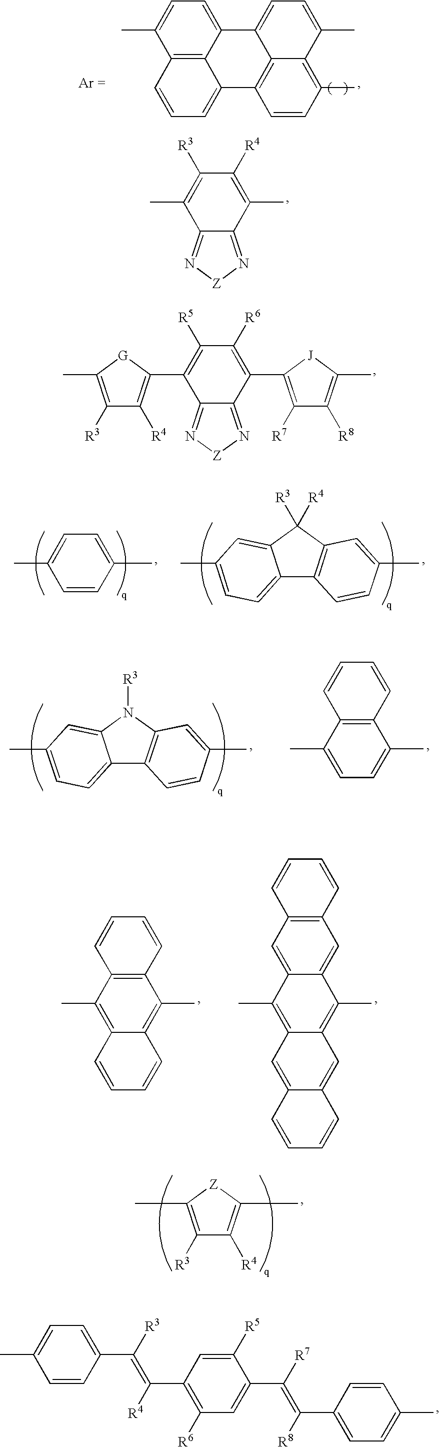 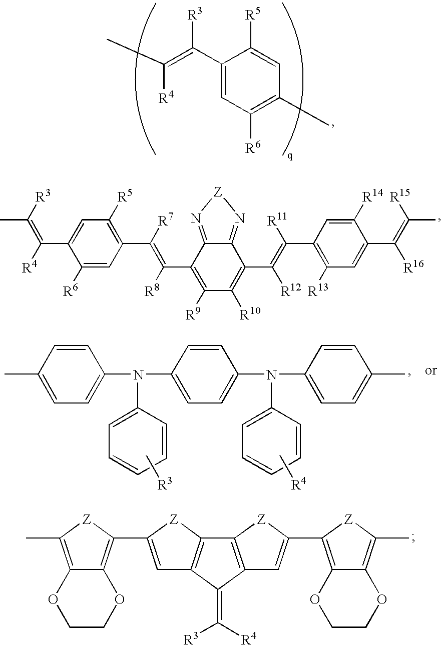
wherein R³, R⁴, R⁵, R⁶, R⁷, R⁸, R⁹, R¹⁰, R¹¹, R¹², R¹³, R¹⁴, R¹⁵, and R¹⁶ are, independently of one another, hydrogen, alkyl, alkoxy, alkenyl, alkynyl, aryl, heteroaryl, or CN; Z, G, and J are, independently of one another, O, S, or N; and q is from 1 to 10.

12. The material of claim 11, wherein X comprises —CH₂—, —, or —C(O)O—; Y comprises —(CH₂)ₙ— or —(CH₂O)ₙ—, where n is from 1 to 25; R¹ and R² are alkyl; and R³⁻¹⁶ are, independently of one another, hydrogen, CN, CₖH₂ₖ₊₁, —OCₖH₂₊₁, or —O(CH₂CH₂)ₖCH₃, where k is from 1 to 10.

13. The material of claim 11, wherein X comprises —CH₂—, Y comprises —(CH₂)₂—, and Ar comprises: 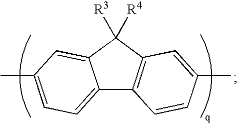
R¹, R², R³, and R⁴ are, independently of one another, sec-pentyl, propyl, or 2-ethyl-hexyl; q is from 1 to 10, and m is 1.

14. The material of claim 11, wherein X comprises —CH₂—, Y comprises —(CH₂)₂—, R¹ and R² are alkyl, and Ar comprises:

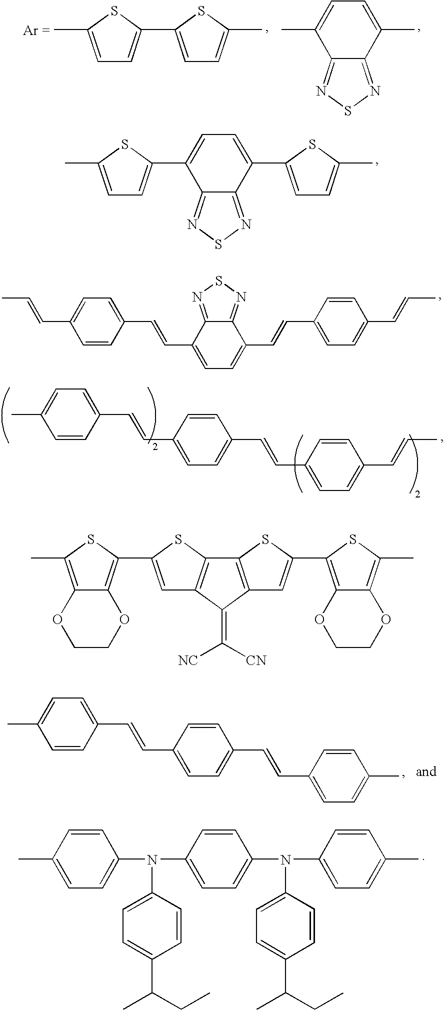

15. The material of claim 1, wherein the conjugated oligomer comprises: 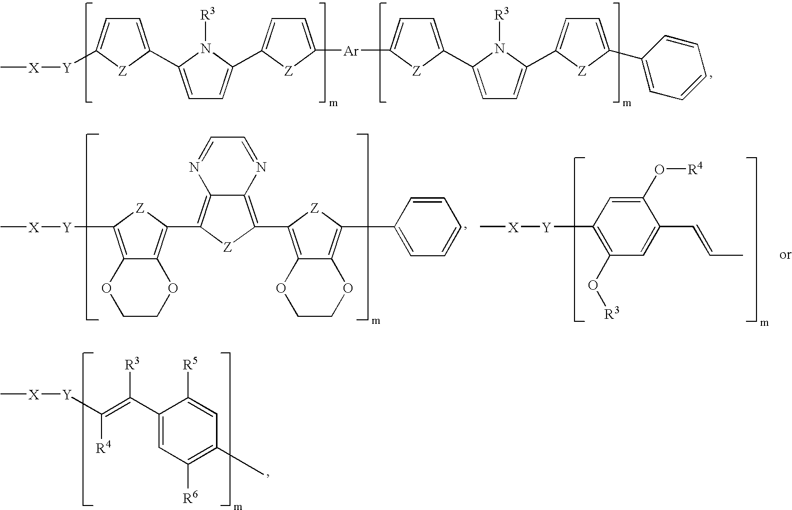
wherein X and Y are, independently of one another, alkyl, alkoxy, alkenyl, alkynyl, aryl, or heteroaryl; R³, R⁴, R⁵, R⁶, are, independently of one another, hydrogen, alkyl, alkoxy, alkenyl, alkynyl, aryl, heteroaryl, or CN; Z is O, S, or N; m is from 1 to 25; and Ar comprises one or more of: 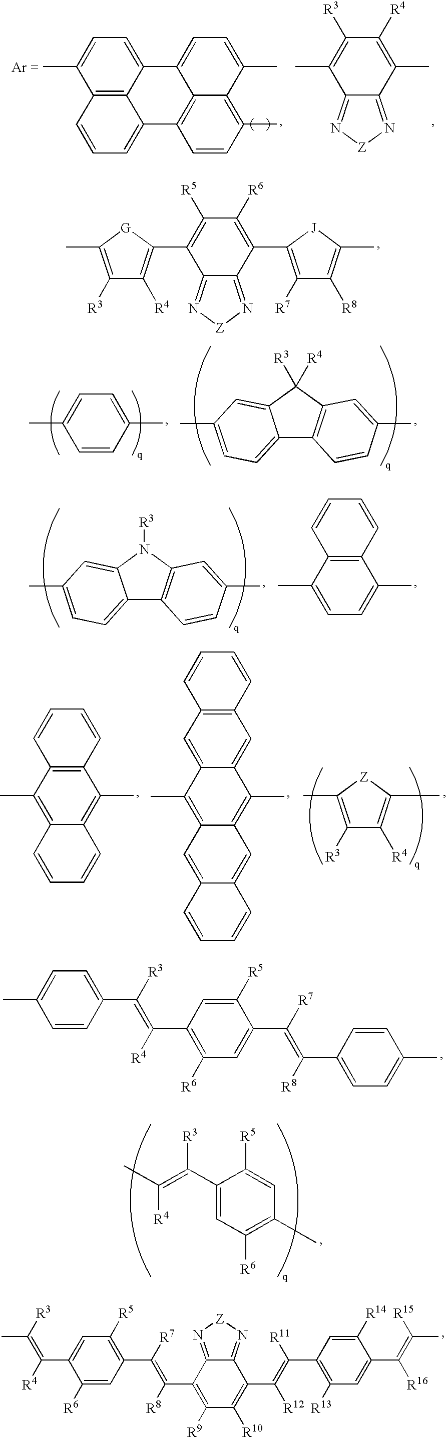 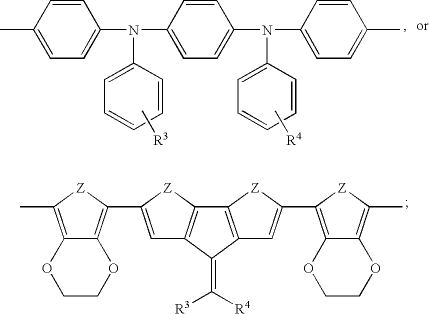
wherein R³, R⁴, R⁵, R⁶, R⁷, R⁸, R⁹, R¹⁰, R¹¹, R¹², R¹³, R¹⁴, and R¹⁵ are, independently of one another, hydrogen, alkyl, alkoxy, alkenyl, alkynyl, aryl, heteroaryl, or CN; Z, G, and J are, independently of one another, O, S, or N; and q is from 1 to 10.

16. The material of claim 15, wherein the conjugated oligomer comprises: 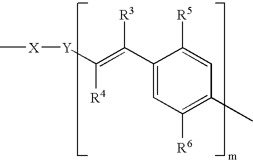
wherein R³ and R⁴ are, independently of one another, hydrogen, CN, and R⁵ and R⁶ are, independently of one another, hydrogen, CN, or alkoxy.

17. The material of claim 1, wherein the aliphatic linker is C₁-C₃ alkyl.

18. The material of claim 1, wherein the core A is a hole-conducting core.

19. The material of claim 18, wherein the hole-conducting core comprises:

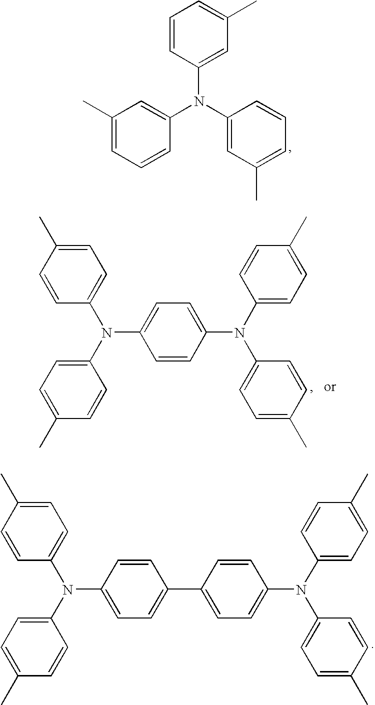

20. The material of claim 1, wherein the core A is an electron-conducting core.

21. The material of claim 20, wherein the electron-conducting core comprises:

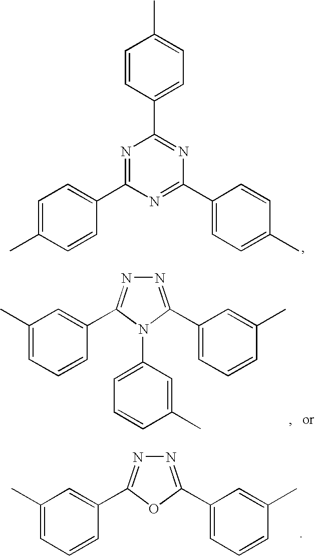

22. The material of claim 1, wherein the core A is a non-conducting core.

23. The material of claim 22, wherein the non-conducting core comprises:

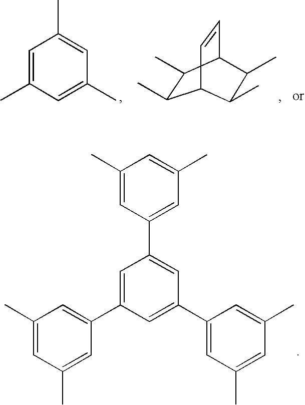

24. The material of claim 1, wherein the material comprises: 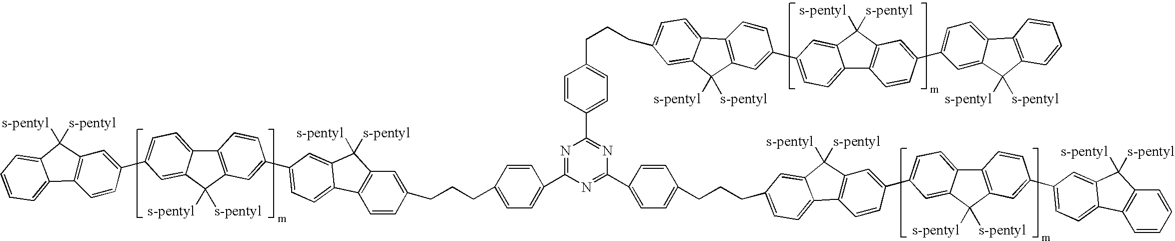
where m is 1, 2, or 3.

25. The material of claim 1, wherein the composition comprises: 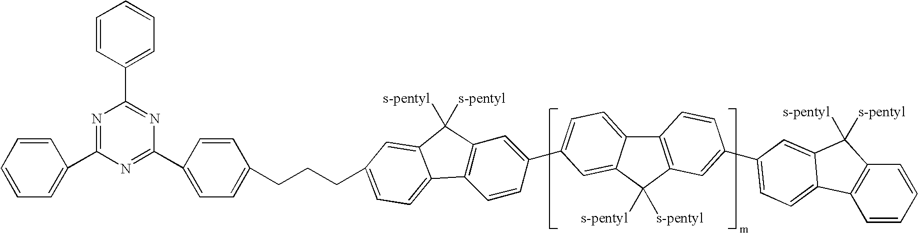
where mis 1, 2, or 3.

26. The material of claim 1, wherein the material comprises:

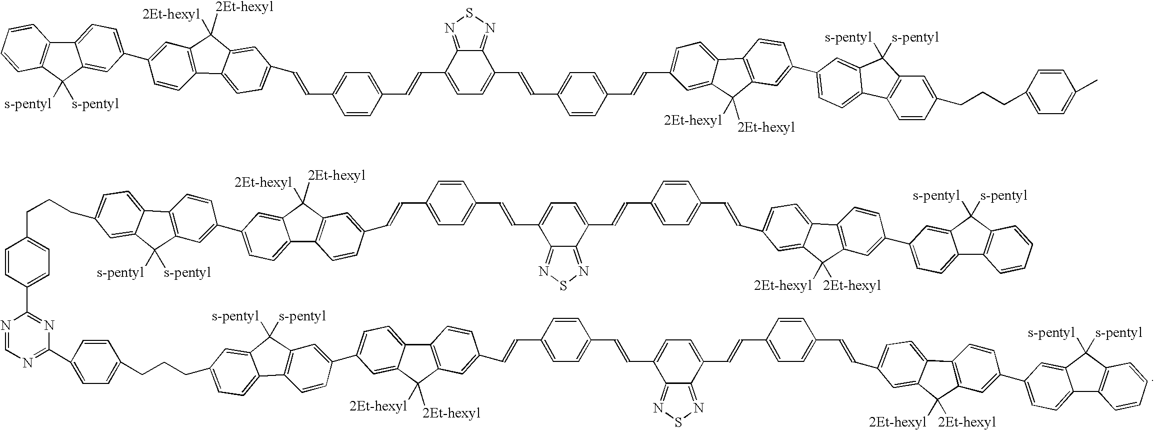

27. The material of claim 1, wherein the material comprises:

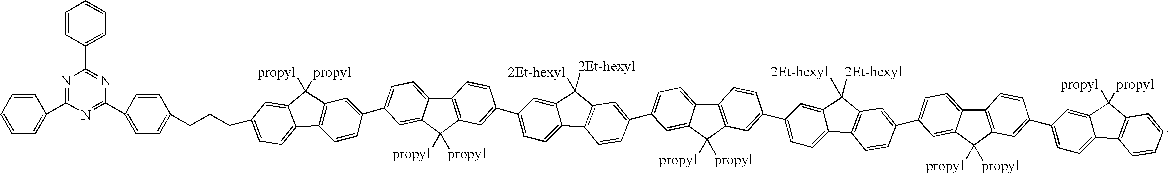

28. The material of claim 1, wherein the material comprises: 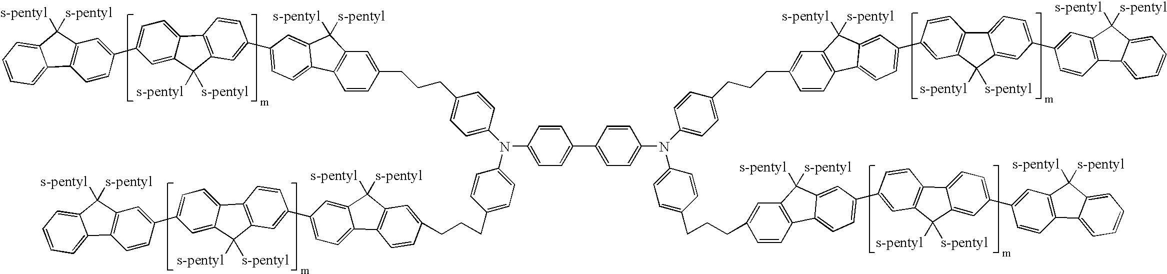
where m is 1, 2, or 3.

29. The material of claim 1, wherein the material comprises: 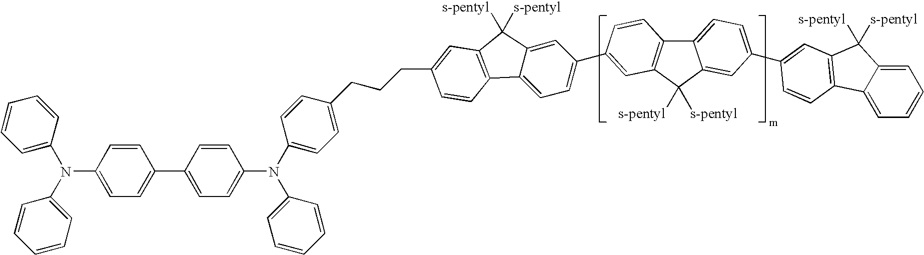
where m is 1, 2, or 3.

30. The material of claim 1, wherein the material comprises: 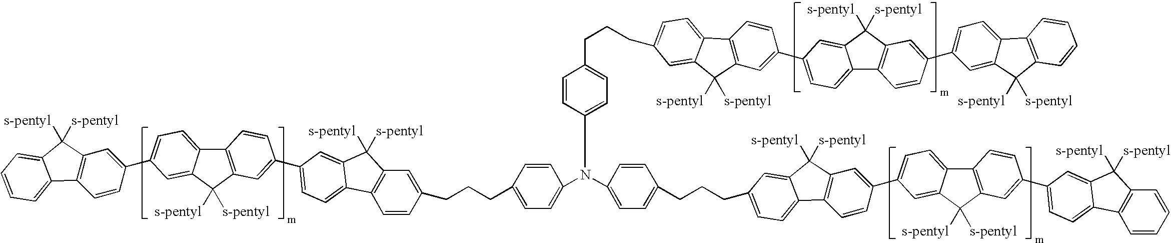
where m is 1, 2, or 3.

31. The material of claim 1, wherein the material comprises:

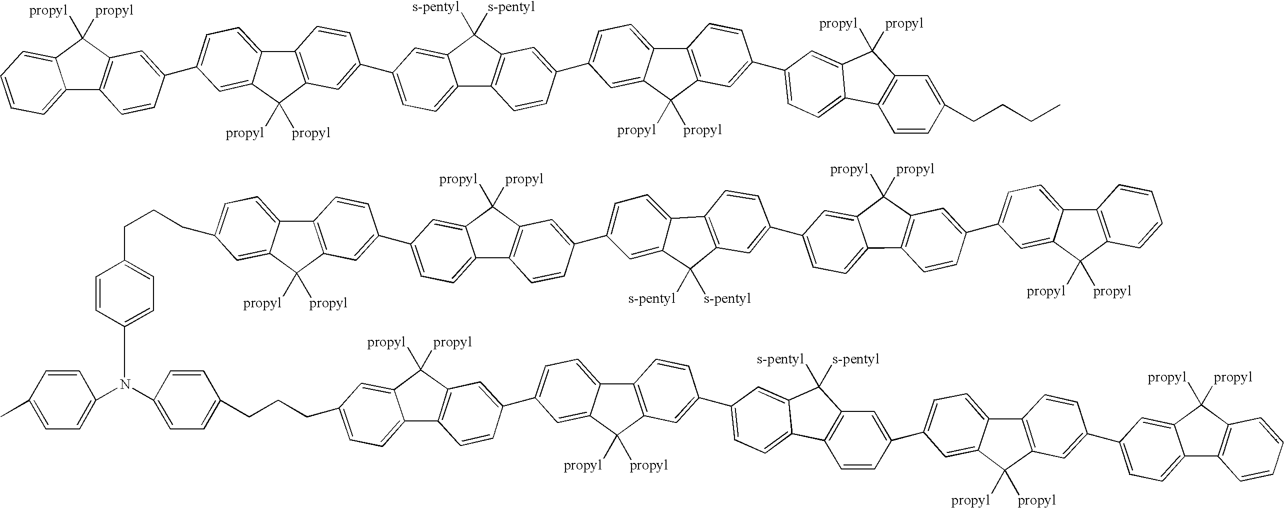

32. The material of claim 1, wherein the material comprises:

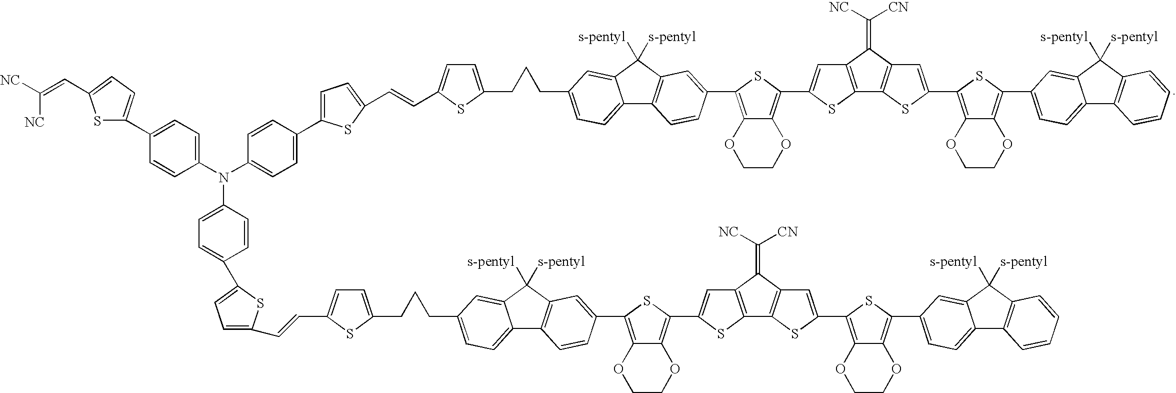

33. The material of claim 1, wherein the material comprises:

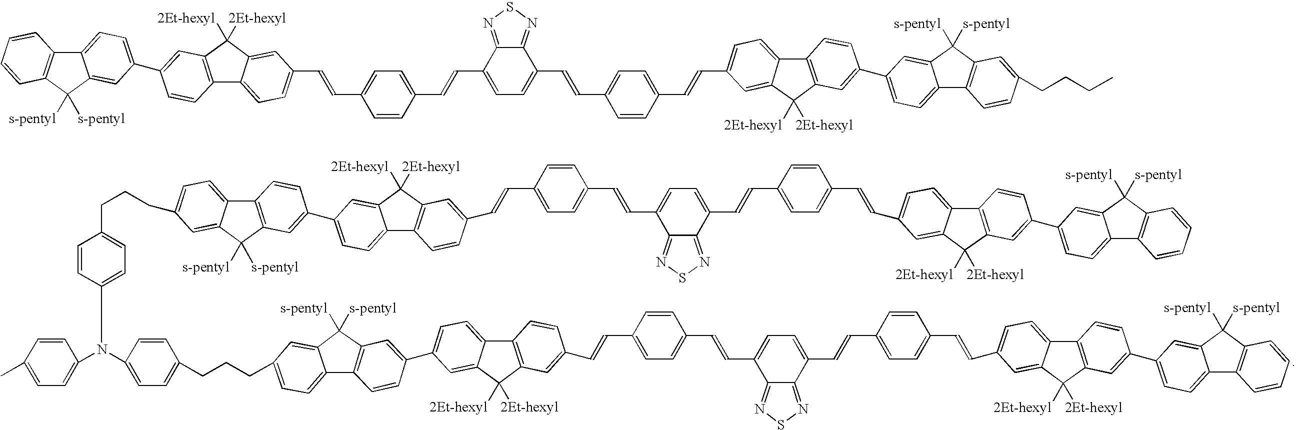

34. The material of claim 1, wherein the material comprises: 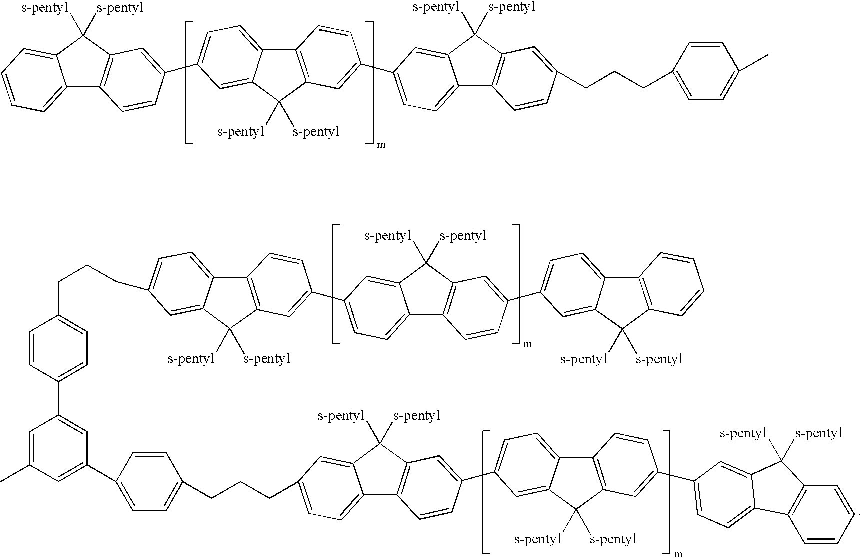
where m is 1, 2, or 3.

35. The material of claim 1, wherein the material comprises:

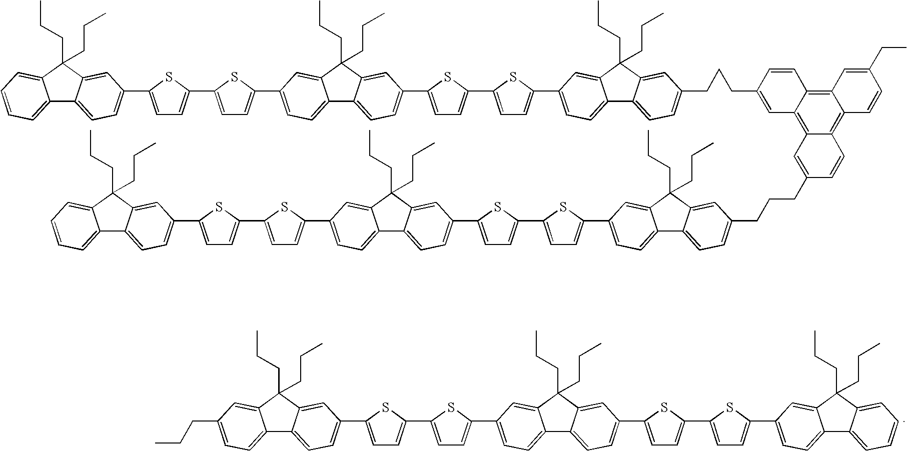

36. The material of claim 1, wherein the material comprises:

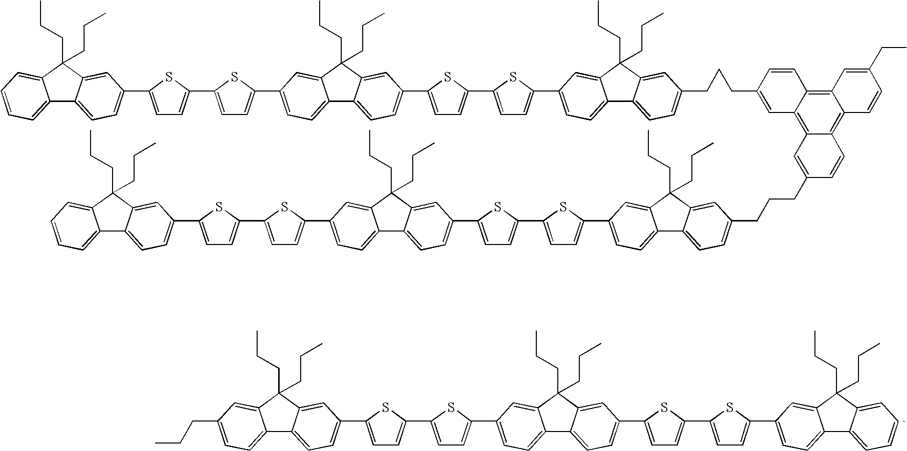

37. The material of claim 1, wherein the material comprises:

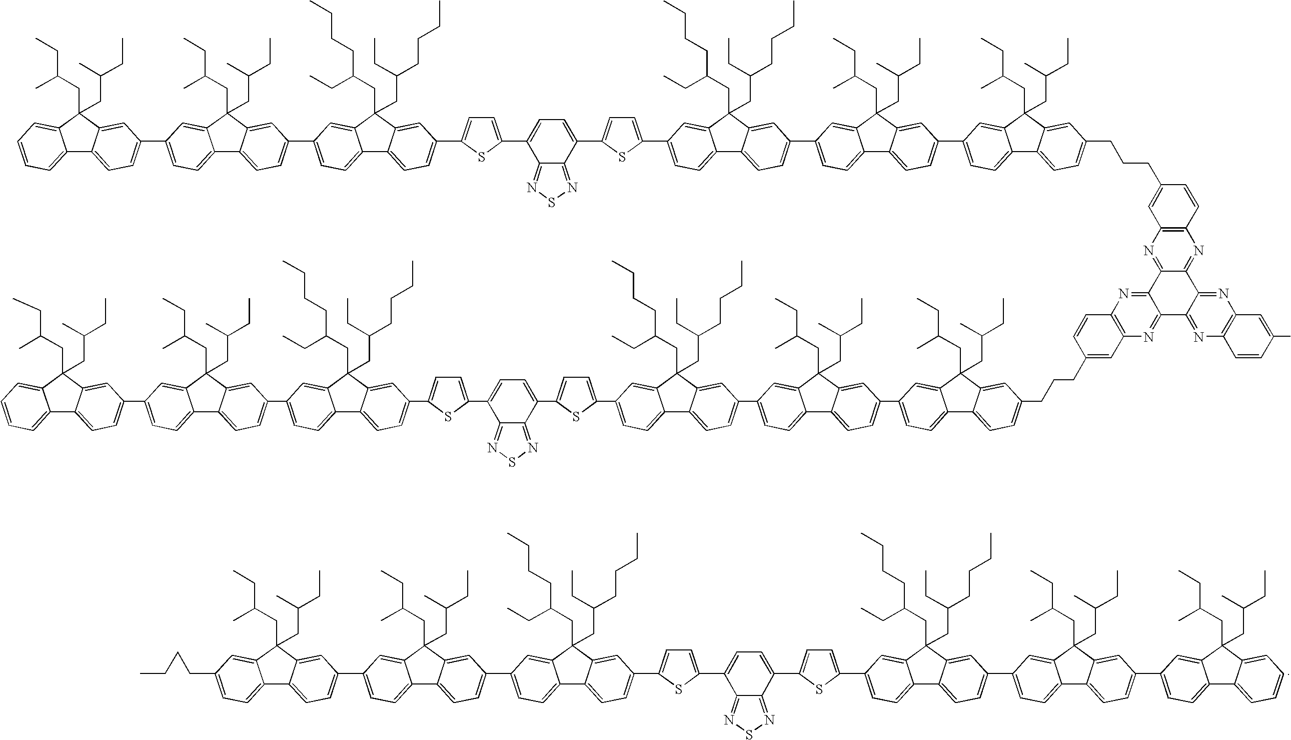

38. The material of claim 1, wherein the material comprises:

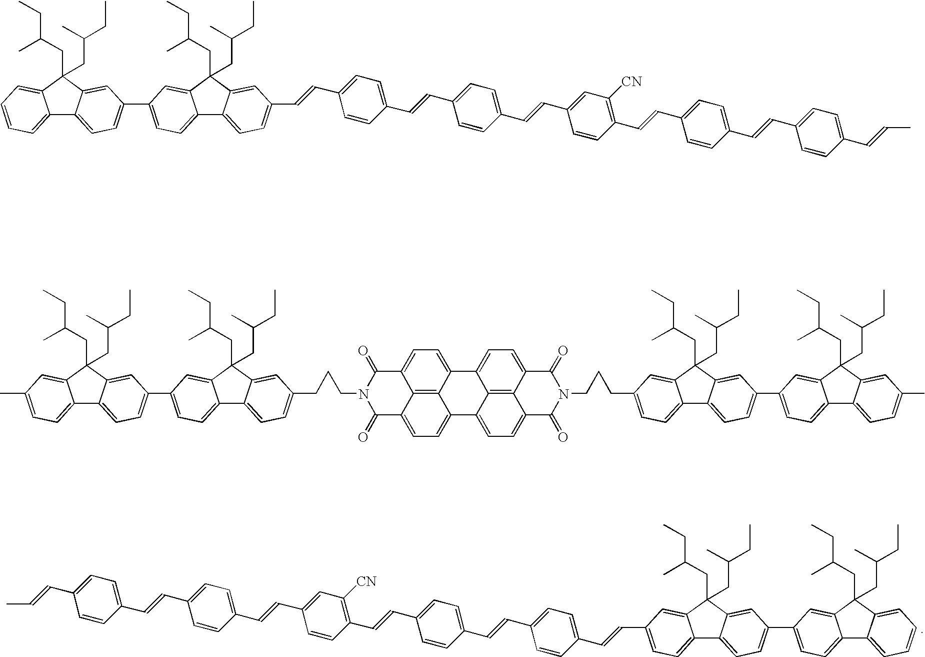

39. The material of claim 1, wherein the material comprises:

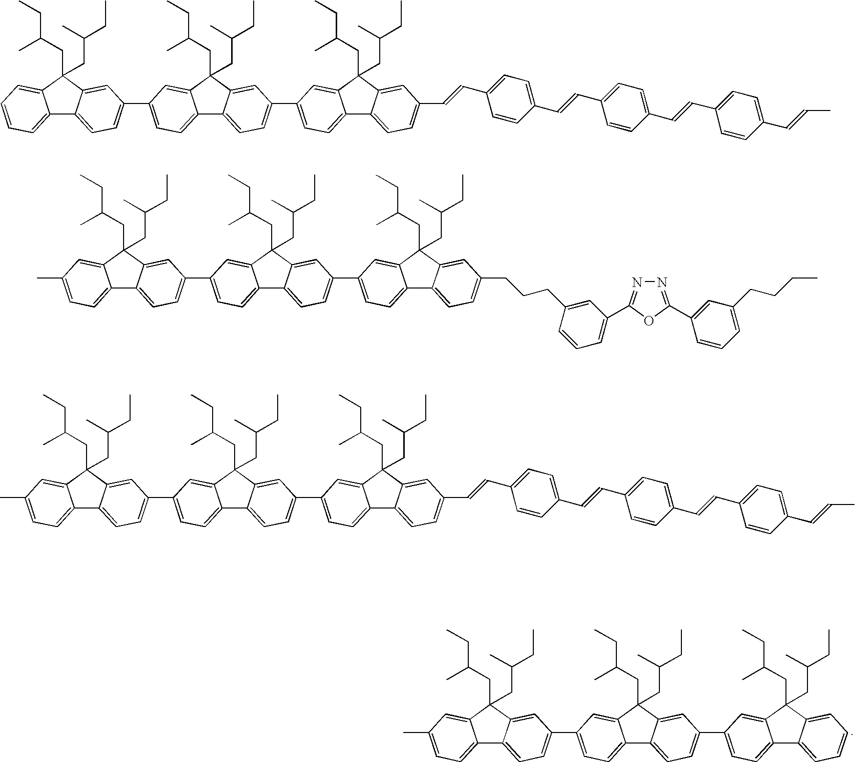

40. The material of claim 1, wherein the material comprises:

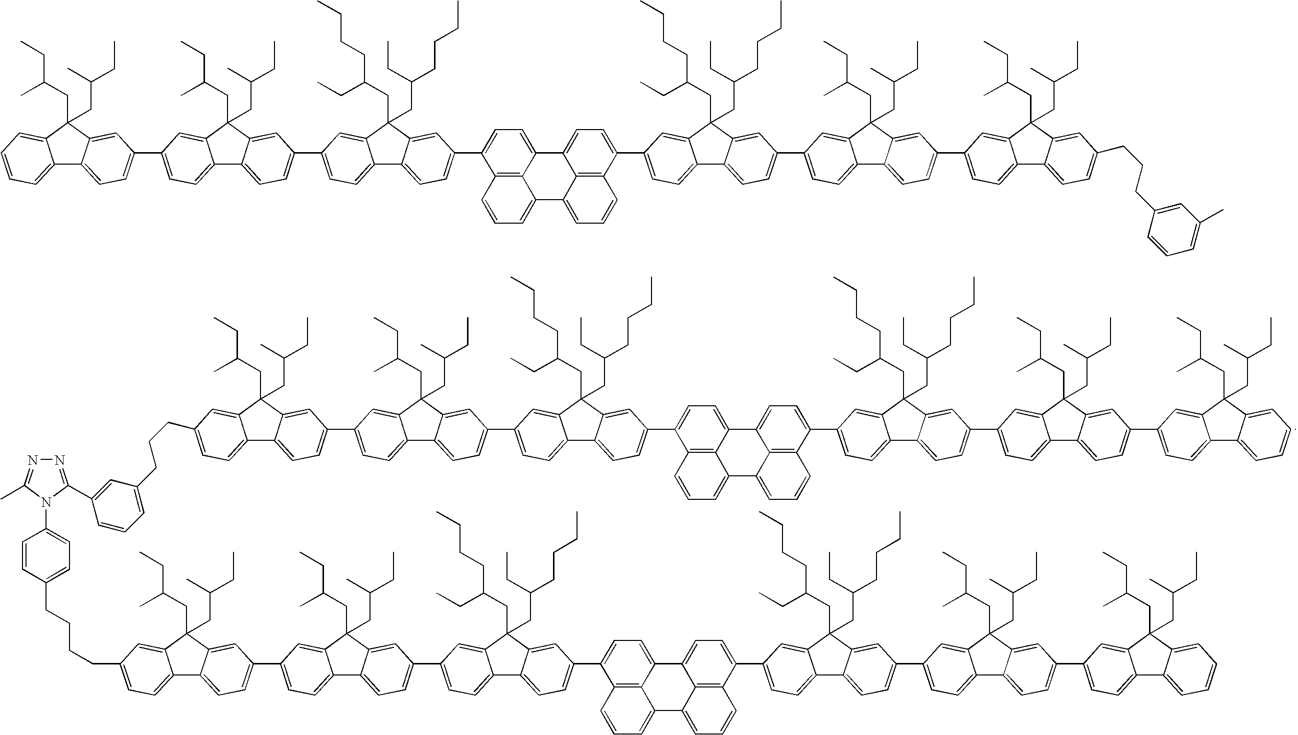

41. The material of claim 1, wherein the material comprises:

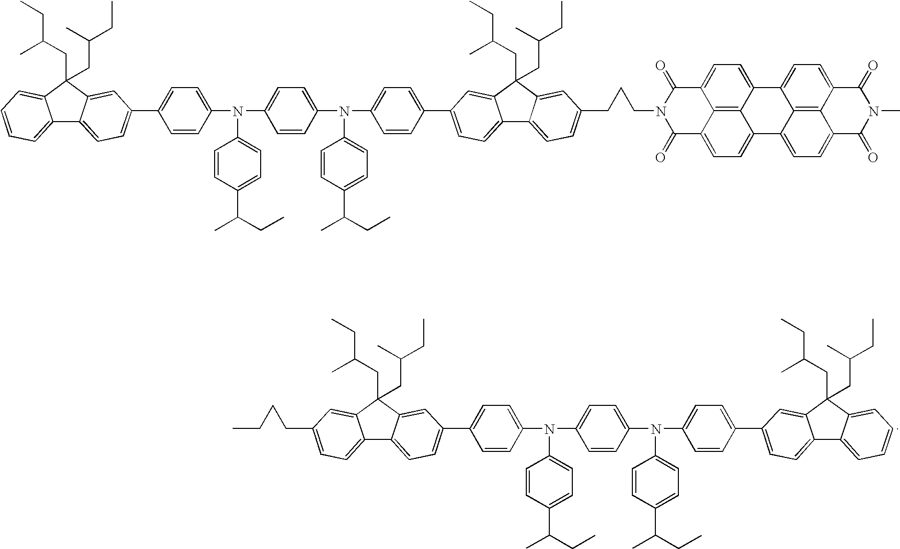

42. The material of claim 1, wherein the material comprises:

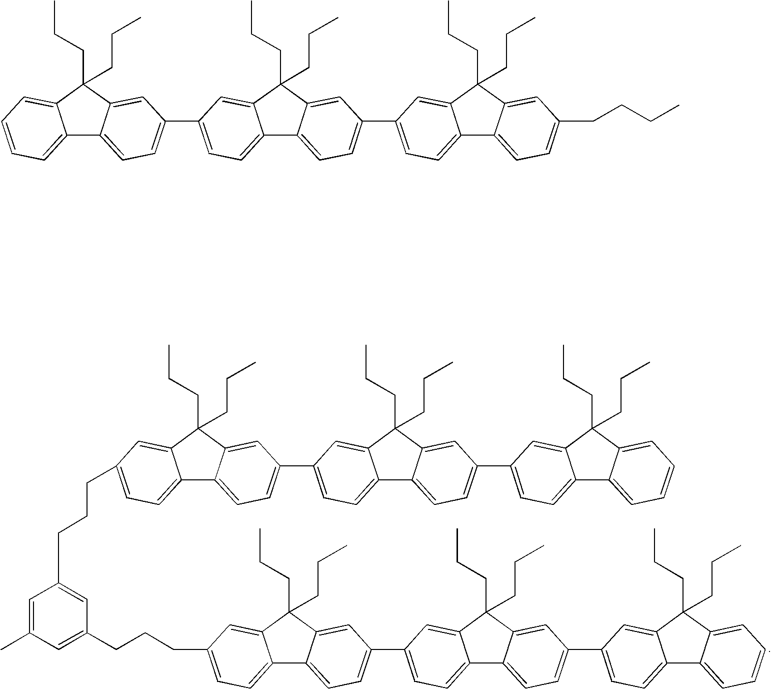

43. The material of claim 1, wherein the material comprises:

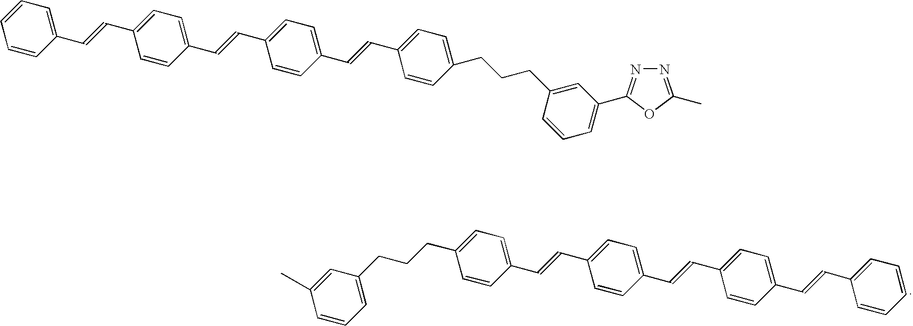

44. The material of claim 1, wherein the material comprises:

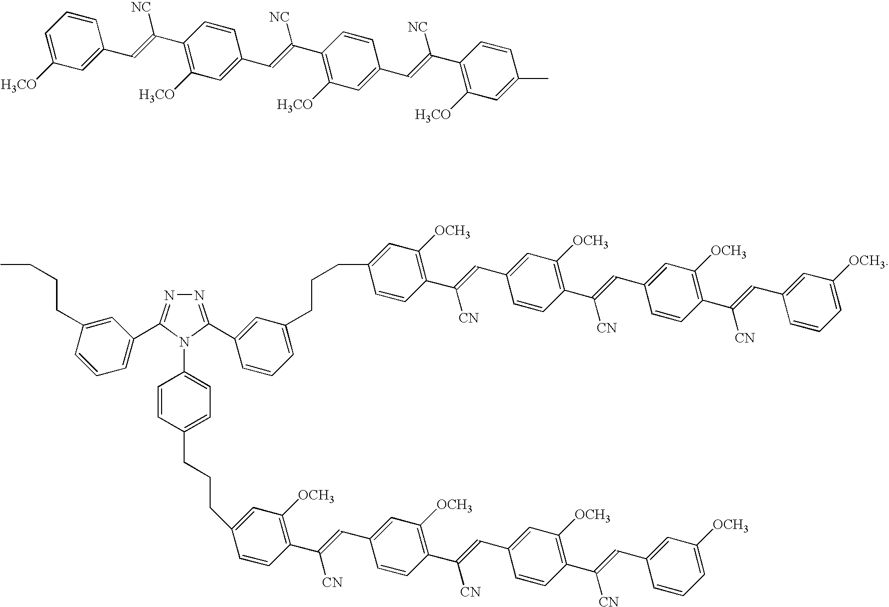

45. The material of claim 1, wherein the material comprises:

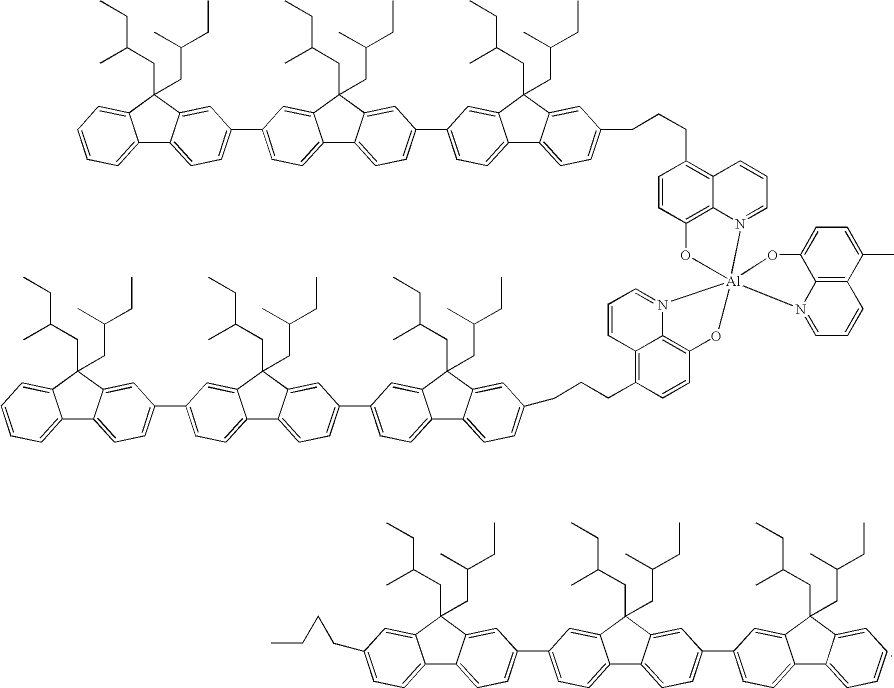

46. The material of claim 1, wherein the material comprises:

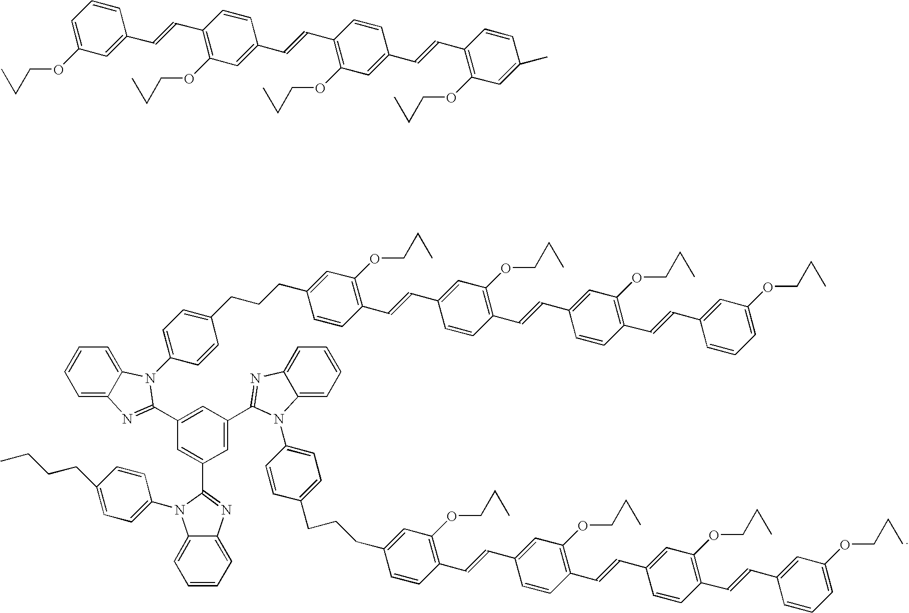

47. The material of claim 1, wherein the material comprises:

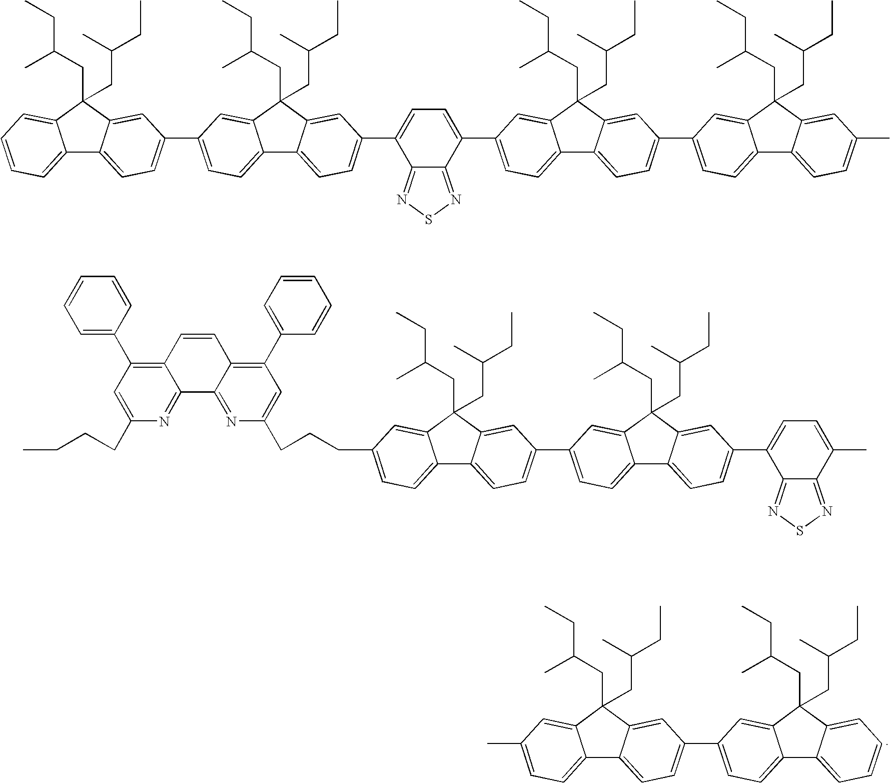

48. The material of claim 1, wherein the material comprises:

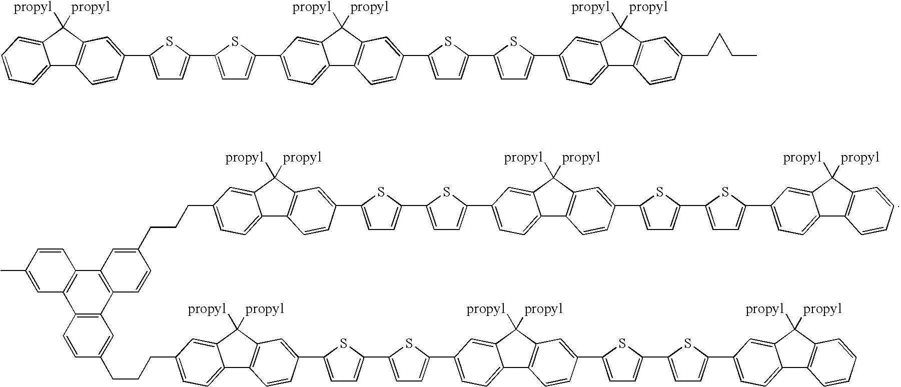

49. The material of claim 1, wherein the material comprises:

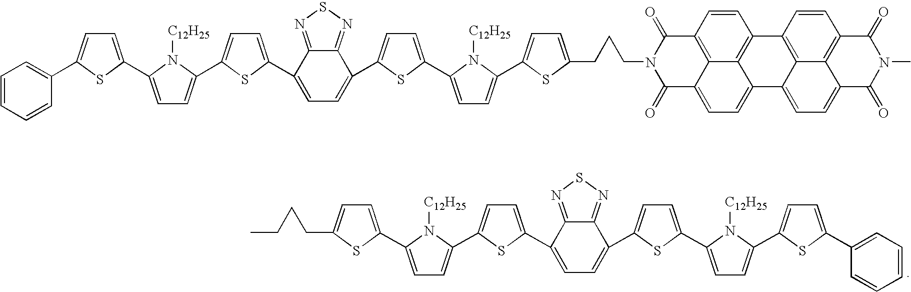

50. The material of claim 1, wherein the material comprises:

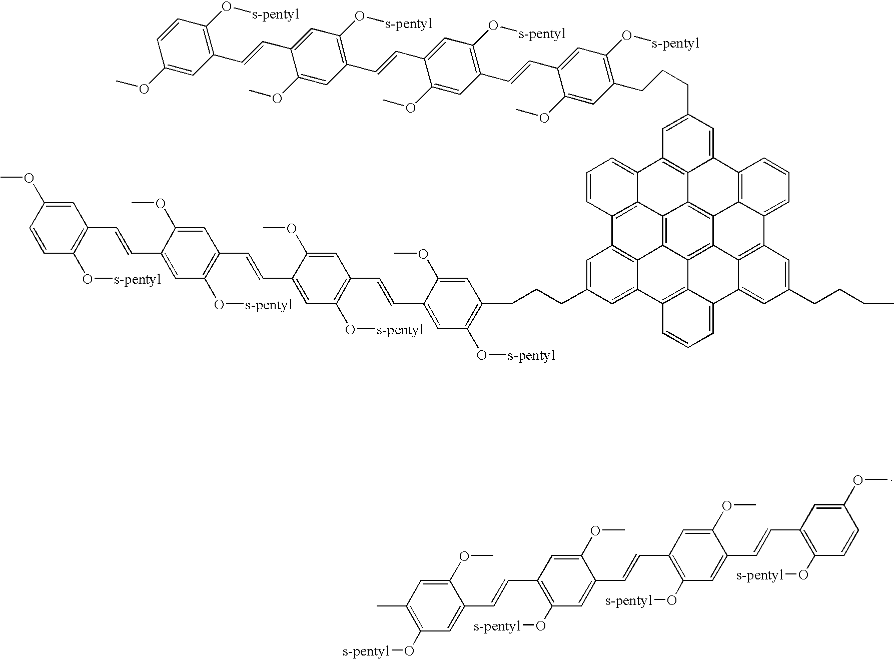

51. An OLED comprising an anode, a cathode, and one or more of the materials of any of claim 1, between the anode and cathode.
